(19) United States
(12) Patent Application Publication
(10) Pub. No.: US 2024/0158427 A1
(43) Pub. Date: May 16, 2024

(54) RED-LIGHT IRIDIUM COMPLEX AND USE THEREOF

(71) Applicants: Phichem Corporation, Shanghai (CN); Shanghai Chuanqin New Material Co Ltd, Shanghai (CN)

(72) Inventors: Kunpeng YU, Shanghai (CN); Jinhai HUANG, Shanghai (CN); Yu LIU, Shanghai (CN); Yifan WANG, Shanghai (CN); Zhipeng ZHANG, Shanghai (CN); Zhiwu YANG, Shanghai (CN); Ping CHI, Shanghai (CN)

(73) Assignees: Phichem Corporation, Shanghai (CN); Shanghai Chuanqin New Material Co Ltd, Shanghai (CN)

(21) Appl. No.: 18/378,684

(22) Filed: Oct. 11, 2023

(30) Foreign Application Priority Data
Oct. 13, 2022 (CN) 202211253396.1

(51) Int. Cl. C07F 15/00; C09K 11/06; H10K 50/11; H10K 85/30

(52) U.S. Cl. CPC C07F 15/0033; C09K 11/06; H10K 50/11; H10K 85/342; C09K 2211/185

(57) ABSTRACT

An iridium complex for an organic light-emitting device includes the chemical structural formula shown below, where the ring A is selected from C₁₂-C₃₀ polycyclic groups formed by fusing three or more monocyclic groups with each other, and the precondition is that the ring A at least includes the structure of general formula II:

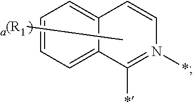

R₁-R₅ are the same or different, and each independently is H, deuterium, halogen, —CF₃, CN, amino, substituted or unsubstituted C₁-C₁₀ alkoxyl, or substituted or unsubstituted C₁-C₃₀ alkyl, hydrogens on the alkyl chain of the C₁-C₁₀ alkoxyl and C₁-C₃₀ alkyl may each be independently substituted by deuterium, halogen, —CF₃ or CN, where the halogen is selected from fluorine, chlorine, bromine or iodine; Rₓ and R_{y} are the same or different, and each independently includes saturated aliphatic ring structure. The iridium complex has excellent red-light saturation, luminous efficiency and thermal stability.

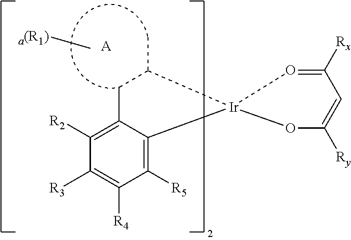

### CROSS-REFERENCE TO RELATED APPLICATIONS

This application claims the benefit of Chinese Application No. 202211253396.1, filed Oct. 13, 2022, the contents of which is incorporated by reference herein.

### TECHNICAL FIELD

The present invention relates to the technical field of organic light-emitting, particularly to a fused-ring and naphthenic red-light iridium complex and use thereof on the organic light-emitting device.

### BACKGROUND

Organic light-emitting devices (OLEDs) are devices prepared by spin coating or vacuum evaporation deposition of a layer of organic material between two metal electrodes. As early as 1963, Pope et al. published an article on the electroluminescence of anthracene single crystals. However, due to the high driving voltage (>300 V) required, the research on anthracene single crystals is still at the basic research level and cannot be used in commercial electronic devices. By 1987, Tang and Van Slyke from Kodak in the United States had developed a sandwich structured organic light-emitting devices, using 8-hydroxyquinoline aluminum (Alq3) as the electron transport layer and luminescent layer, and aromatic diamines as the hole transport layer. The working voltage of the device is less than 10 V, and the brightness exceeds 1000 cd m⁻² (Tang, C. W., VanSlyke, S. A. (1989). Organic Electroluminescent Diodes. In: Shionoya, S., Kobayashi, H. (eds) Electroluminescence. Springer Proceedings in Physics, vol 38. Springer, Berlin, Heidelberg.). This breakthrough research has sparked a milestone in the development of OLED. At this point, organic light emitting devices have been widely used in flat panel displays such as mobile phones and computers due to their simple structure, fast response speed, power saving, wide color gamut, and high contrast.

The classic three-layer organic light-emitting device includes a hole transport layer, a luminescent layer, and an electron transport layer. The holes generated by the anode pass through the hole transport layer and are combined with the electrons generated by the cathode through the electron transport layer to form excitons in the luminescent layer, and then emit light. Organic light-emitting devices can be adjusted to emit various required light by changing the material of the luminescent layer as needed.

Due to the injected charge carriers being semi spin particles, the spin multiplicity of the excited states generated by recombination is determined by spin-statistics, with 25% of excitons being singlet excited state and 75% being triplet excited state. The radiative transition pathways corresponding to these two excitons are singlet fluorescence and triplet phosphorescence, respectively. The earliest fluorescent OLEDs relied only on 25% singlet excitons, while 75% of triplet excitons were wasted.

In 1998, S. Forrest and M. Baldo et al. applied metal complexes as luminescent materials to OLEDs for the first time, breaking the limit of internal quantum efficiency of fluorescent materials below 25%, attempting to achieve 100% internal quantum efficiency, thereby improving the efficiency of the device. Therefore, the research on high-efficiency phosphorescent organic light-emitting devices has provided an important driving force for the development of the flat panel and portable display industry.

Iridium has a large atomic number, which can generate strong spin orbit coupling in the complex and facilitate phosphorescence emission. The d-orbital energy level in iridium metal ions splits greatly, avoiding the interaction with the MLCT state of the complex and the reduction of the phosphorescence emission efficiency. The trivalent ions of iridium can form very stable neutral molecules with ligands, which is beneficial for preparing devices through vacuum evaporation or solution processing. In addition, the color of the emitted light from the complex can cover the entire visible spectrum, and the complex has good stability and other characteristics, and meets the requirements of light-emitting materials, which make iridium complexes a research focus of organic light-emitting phosphorescent materials.

However, due to the narrow energy gap of the red-light iridium complex, the match of the energy levels between the red-light material and the carrier transport layer is difficult to achieve and concentration quenching is easy to occur, resulting in unsatisfactory overall performance of the red-light device and affecting the overall color saturation of the device. Therefore, the study of red-light iridium complexes and devices thereof is particularly important for device performance (for example, in aspects of efficiency, voltage, service life, and the like). Auxiliary ligand of iridium complex can be used to fine tune the luminescence wavelength, improve sublimation properties, thermal stability, and improve material efficiency. The existing acetylacetone ligands, especially those with branched alkyl chains, have achieved some results in the above properties, but there are still some shortcomings in luminescence efficiency and service life.

Therefore, further improvements on color saturation, luminescence efficiency, and service life of the device are needed in this field.

### SUMMARY OF THE INVENTION

An object of the present invention is to provide an iridium complex, which can further improve the color saturation (red saturation), luminous efficiency and service life of the device by adjusting the structural combination of the main ligand and auxiliary ligand.

Another object of the present invention is to provide a synthetic method of the above iridium complex.

A further object of the present invention is to provide a device using the above iridium complex as red-light dopant material.

### Technical Solutions

In order to accomplish the above objects of the present invention, the present invention provides an iridium complex represented by general formula I:

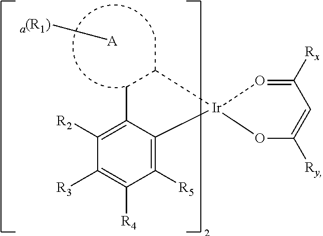

wherein,
ring A is selected from C₁₂-C₃₀ polycyclic groups formed by fusing three or more monocyclic groups with each other, and the precondition is that the C₁₂-C₃₀ polycyclic groups represented by the ring A at least comprise the structure of general formula II:

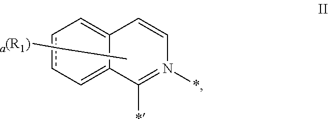

wherein, * represents a binding site of general formula II to iridium (Ir), *′ represents a binding site of general formula II to benzene ring in general formula I;
a is selected from an integer of 0 to 20, when a represents an integer that is ≥2, R₁ may be the same or different and the positions of R₁ may be the same or different;
R₁, R₂, R₃, R₄ and R₅ are the same or different, and each independently is H, deuterium, halogen, —CF₃, CN, amino, substituted or unsubstituted C₁-C₁₀ alkoxyl, or substituted or unsubstituted C₁-C₃₀ alkyl, hydrogens on the alkyl chain of the C₁-C₁₀ alkoxyl and C₁-C₃₀ alkyl may each be independently substituted by deuterium, halogen, —CF₃ or CN, wherein, the halogen is selected from fluorine, chlorine, bromine or iodine; and
Rₓ and R_{y} are the same or different, and each independently includes saturated aliphatic ring structure.

In some embodiments of the present invention, ring A is a group formed by fusing the general formula II with 1 to 3 five-membered rings or six-membered rings.

In some embodiments of the present invention, ring A is a group formed by fusing the general formula II with 1 to 3 aromatic rings.

In specific, the more the aromatic ring structures are fused with the structure of general formula II of the present invention, the higher the energy difference between the ground state and the excited state. This further improves the luminescence efficiency and can improve the color saturation of the device's red light at the same time. However, the number of fused rings should not be too large. When the number of fused rings exceeds 3, the stability of the compound will decrease, which leads to a decrease in service life and possibly causes the device's emission wavelength to exceed the visible light range and emit infrared light.

In some embodiments of the present invention, the aromatic ring is benzene ring.

In some embodiments of the present invention, ring A is a group formed by fusing general formula II with one aromatic ring.

In some embodiments of the present invention, ring A is a group formed by fusing general formula II with one benzene ring.

In some embodiments of the present invention, the structure of ring A is selected from any one of general formulae RD-1 to RD-3:

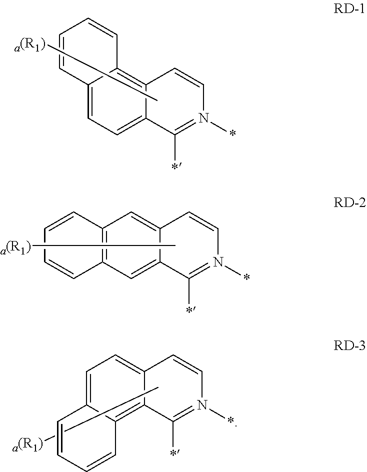

In specific, fusing one benzene ring on the basis of general Formula II helps to improve the color saturation of the device while providing high luminous efficiency, and the structure has better thermal stability, which helps to improve the service life of the device.

In some embodiments of the present invention, in any one structure of RD-1 to RD-3, a represents any integer of 0 to 8, specifically, a may be 0, 1, 2, 3, 4, 5, 6, 7 or 8; when a represent an integer that is ≥2, R₁ may be the same or different and each is independently selected from H, deuterium, halogen, —CF₃, CN, amino, substituted or unsubstituted C₁-C₁₀ alkoxyl, or substituted or unsubstituted C₁-C₃₀ alkyl.

In some embodiments of the present invention, hydrogens on the alkyl may each be independently substituted by deuterium, halogen, —CF₃ or CN.

In some embodiments of the present invention, halogen comprises fluorine, chlorine, bromine or iodine.

In some embodiments of the present invention, alkyl comprises linear alkyl or branched alkyl.

In some preferred embodiments of the present invention, when a represents an integer that is ≥2, R₁ may be the same or different and each is independently selected from H, deuterium, halogen, —CF₃, CN or amino.

In some preferred embodiments of the present invention, when a represents an integer that is ≥2, R₁ may be the same or different and each is independently selected from substituted or unsubstituted C₁-C₁₀ alkoxyl.

In some preferred embodiments of the present invention, when a represents an integer that is ≥2, R₁ may be the same or different and each is independently selected from substituted or unsubstituted C₁-C₄ alkoxyl.

In some preferred embodiments of the present invention, alkoxyl is selected from methoxy, ethoxy, or propoxy.

In some preferred embodiments of the present invention, when a represents an integer that is ≥2, R₁ may be the same or different and each is independently selected from substituted or unsubstituted C₁-C₂₀ alkyl.

In some preferred embodiments of the present invention, when a represents an integer that is ≥2, R₁ may be the same or different and each is independently selected from substituted or unsubstituted C₁-C₁₀ alkyl.

In some preferred embodiments of the present invention, when a represents an integer that is ≥2, R₁ may be the same or different and each is independently selected from substituted or unsubstituted C₁-C₄ alkyl.

In some preferred embodiments of the present invention, alkyl is selected from methyl, ethyl, propyl, isopropyl, n-butyl, sec-butyl, isobutyl, tert-butyl, n-pentyl, n-hexyl, n-heptyl, n-octyl, n-nonyl, n-decyl, n-undecyl, n-dodecyl, n-tridecyl, n-tetradecyl, n-pentadecyl, n-hexadecyl, n-heptadecyl, n-octadecyl, neopentyl, 1-methylpentyl, 2-methylpentyl, 1-pentylhexyl, 1-butylpentyl, 1-heptyloctyl, or 3-methylpentyl.

In some preferred embodiments of the present invention, alkyl is selected from methyl, ethyl, propyl, isopropyl, butyl and isobutyl.

In some embodiments of the present invention, general formula RD-1 includes 8 substitutable sites (i.e., a may be any integer of 0 to 8), and the substituents on the 8 substitutable sites are represented by T₁₁, T₁₂, T₁₃, T₁₄, T₁₅, T₁₆, T₁₇ and T₁₈, respectively:

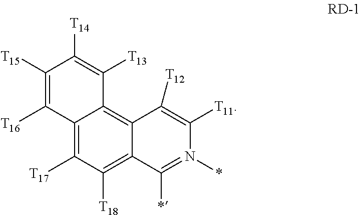

In some preferred embodiments of the present invention, at least one of T₁₁-T₁₈ in general formula RD-1 is not hydrogen and at most three of T₁₁-T₁₈ in general formula RD-1 are not hydrogen.

In some preferred embodiments of the present invention, one of T₁₁-T₁₈ in general formula RD-1 is not hydrogen.

In some preferred embodiments of the present invention, any one of T₁₄, T₁₅, T₁₇ and T₁₈ in general formula RD-1 is not hydrogen. The corresponding positions of T₁₄, T₁₅, T₁₇ and T₁₈ in general formula RD-1 can be substituted so that the prepared iridium complex can provide higher luminous efficiency and stability for the device.

In some preferred embodiments of the present invention, any non-hydrogen substituent of T₁₁-T₁₈ is selected from deuterium, halogen, —CF₃, CN, amino, substituted or unsubstituted C₁-C₁₀ alkoxyl, or substituted or unsubstituted C₁-C₄ alkyl, hydrogens on the alkyl chain of C₁-C₁₀ alkoxyl and C₁-C₄ alkyl can each be independently substituted by deuterium, halogen, —CF₃ or CN.

In some preferred embodiments of the present invention, any non-hydrogen substituent of T₁₃-T₁₆ is selected from deuterium, fluorine, —CF₃, amino, CN or C₁-C₄ alkyl.

In some preferred embodiments of the present invention, C₁-C₄ alkyl is selected from any one of methyl, ethyl, propyl, isopropyl, n-butyl, sec-butyl, isobutyl, and tert-butyl.

In some preferred embodiments of the present invention, any two of T₁₁-T₁₈ in general formula RD-1 are not hydrogen.

In some preferred embodiments of the present invention, any two of T₁₃-T₁₆ in general formula RD-1 are not hydrogen.

In some preferred embodiments of the present invention, the two non-hydrogen substituents in general formula RD-1 comprise T₁₄ and/or T₁₆.

In some preferred embodiments of the present invention, any two of T₁₃, T₁₄ and T₁₆ in general formula RD-1 are not hydrogen.

In some preferred embodiments of the present invention, any two non-hydrogen substituents of T₁₁-T₁₈ in general formula RD-1 are each independently selected from deuterium, halogen, —CF₃, amino, CN, or substituted or unsubstituted C₁-C₄ alkyl, hydrogens on the alkyl chain of C₁-C₄ alkyl can each be independently substituted by deuterium, halogen, —CF₃ or CN.

In some preferred embodiments of the present invention, C₁-C₄ alkyl is selected from methyl, ethyl, propyl, isopropyl, n-butyl, sec-butyl, isobutyl or tert-butyl.

In some preferred embodiments of the present invention, at least one of T₁₁-T₁₈ in general formula RD-1 is selected from F, amino or —CF₃.

In some preferred embodiments of the present invention, at least one of T₁₃, T₁₄ and T₁₆ in general formula RD-1 is selected from F, amino or —CF₃.

In specific, when the substituent comprises F or —CF₃, the luminous efficiency can be further improved.

In some preferred embodiments of the present invention, any three of T₁₁-T₁₈ in general formula RD-1 are not hydrogen.

In some preferred embodiments of the present invention, any three of T₁₃-T₁₈ in general formula RD-1 are not hydrogen.

In some preferred embodiments of the present invention, any three non-hydrogen substituents of T₁₁-T₁₈ in general formula RD-1 are each independently selected from deuterium, halogen, —CF₃, amino, CN, or substituted or unsubstituted C₁-C₄ alkyl, hydrogens on the alkyl chain of C₁-C₄ alkyl can each be independently substituted by deuterium, halogen, —CF₃ or CN.

In some preferred embodiments of the present invention, at least one of T₁₁-T₁₈ in general formula RD-1 is selected from F, amino or —CF₃.

In some preferred embodiments of the present invention, at least one of T₁₁-T₁₈ in general formula RD-1 is selected from F or —CF₃.

In some preferred embodiments of the present invention, at least one of T₁₃-T₁₈ in general formula RD-1 is selected from F, amino or —CF₃.

In some preferred embodiments of the present invention, at least one of T₁₃-T₁₆ in general formula RD-1 is selected from F, amino or —CF₃.

In some preferred embodiments of the present invention, at least one of T₁₃-T₁₈ in general formula RD-1 is selected from F or —CF₃.

In some preferred embodiments of the present invention, when the number of non-hydrogen substituent of T₁₁-T₁₈ in general formula RD-1 is ≥2, any two or more substituent can connect to each other to form a carbocyclic group.

In some preferred embodiments of the present invention, the carbocyclic group can be C₅-C₂₀ carbocyclic group.

Wherein, hydrogens on C₅-C₂₀ carbocyclic group can each be independently substituted by a substituent selected from deuterium, halogen, —CF₃, CN, or substituted or unsubstituted C₁-C₄ alkyl.

In some embodiments of the present invention, general formula RD-2 includes 8 substitutable sites (i.e., a may be any integer of 0 to 8), and the substituents on the 8 substitutable sites are represented by T₂₁, T₂₂, T₂₃, T₂₄, T₂₅, T₂₆, T₂₇ and T₂₈, respectively:

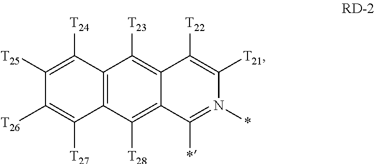

In some preferred embodiments of the present invention, at least one of T₂₁-T₂₈ in general formula RD-2 is not hydrogen and at most three of T₂₁-T₂₈ in general formula RD-2 are not hydrogen.

In some preferred embodiments of the present invention, one of T₂₁-T₂₈ in general formula RD-2 is not hydrogen.

In some preferred embodiments of the present invention, any one of T₂₃ or T₂₈ in general formula RD-2 is not hydrogen. The corresponding positions of T₂₃ or T₂₈ in general formula RD-2 can be substituted so that the prepared iridium complex can provide higher luminous efficiency and stability for the device.

In some preferred embodiments of the present invention, any non-hydrogen substituent of T₂₁-T₂₈ is selected from deuterium, halogen, —CF₃, CN, amino, substituted or unsubstituted C₁-C₁₀ alkoxyl, or substituted or unsubstituted C₁-C₄ alkyl, hydrogens on the alkyl chain of C₁-C₁₀ alkoxyl and C₁-C₄ alkyl can each be independently substituted by deuterium, halogen, —CF₃ or CN.

In some preferred embodiments of the present invention, any non-hydrogen substituent of T₂₁-T₂₈ is selected from deuterium, fluorine, —CF₃, CN, C₁-C₄ alkyl or Ci-C4 alkoxyl.

In some preferred embodiments of the present invention, C₁-C₄ alkyl is selected from any one of methyl, ethyl, propyl, isopropyl, n-butyl, sec-butyl, isobutyl or tert-butyl.

In some preferred embodiments of the present invention, any two of T₂₁-T₂₈ in general formula RD-2 are not hydrogen.

In some preferred embodiments of the present invention, any two of T₂₃-T₂₈ in general formula RD-2 are not hydrogen.

In some preferred embodiments of the present invention, the two non-hydrogen substituents in general formula RD-2 comprise T₂₃ and/or T₂₈.

In some preferred embodiments of the present invention, any two non-hydrogen substituents of T₂₁-T₂₈ in general formula RD-2 are each independently selected from deuterium, halogen, —CF₃, CN, or substituted or unsubstituted C₁-C₄ alkyl or alkoxyl, hydrogens on the alkyl chain of C₁-C₄ alkyl can each be independently substituted by deuterium, halogen, —CF₃ or CN.

In some preferred embodiments of the present invention, C₁-C₄ alkyl is selected from methyl, ethyl, propyl, isopropyl, n-butyl, sec-butyl, isobutyl or tert-butyl.

In some preferred embodiments of the present invention, at least one of T₂₁-T₂₈ in general formula RD-2 is selected from F, C₁-C₄ alkoxyl or —CF₃.

In some preferred embodiments of the present invention, at least one of T₂₁-T₂₈ in general formula RD-2 is selected from F or —CF₃.

In some preferred embodiments of the present invention, at least one of T₂₃-T₂₈ in general formula RD-2 is selected from F, C₁-C₄ alkoxyl or —CF₃, such that the luminous efficiency of the device can be further improved.

In some preferred embodiments of the present invention, at least one of T₂₃-T₂₈ in general formula RD-2 is selected from F or —CF₃, such that the luminous efficiency of the device can be further improved.

In some preferred embodiments of the present invention, any three of T₂₁-T₂₈ in general formula RD-2 are not hydrogen.

In some preferred embodiments of the present invention, any three of T₂₃-T₂₈ in general formula RD-2 are not hydrogen.

In some preferred embodiments of the present invention, any three non-hydrogen substituents of T₂₁-T₂₈ in general formula RD-2 are each independently selected from deuterium, halogen, —CF₃, CN, or substituted or unsubstituted C₁-C₄ alkyl, hydrogens on the alkyl chain of C₁-C₄ alkyl can each be independently substituted by deuterium, halogen, —CF₃ or CN.

In some preferred embodiments of the present invention, at least one of T₂₁-T₂₈ in general formula RD-2 is selected from F, —OCH₃ or —CF₃.

In some preferred embodiments of the present invention, at least one of T₂₁-T₂₈ in general formula RD-2 is selected from F or —CF₃.

In some preferred embodiments of the present invention, at least one of T₂₃-T₂₈ in general formula RD-2 is selected from F, —OCH₃ or —CF₃.

In some preferred embodiments of the present invention, at least one of T₂₃-T₂₈ in general formula RD-2 is selected from F or —CF₃.

In some preferred embodiments of the present invention, when the number of non-hydrogen substituent of T₂₁-T₂₈ in general formula RD-2 is ≥2, any two or more substituent can connect to each other to form a carbocyclic group.

In some preferred embodiments of the present invention, the carbocyclic group can be C₅-C₂₀ carbocyclic group.

Wherein, hydrogens on C₅-C₂₀ carbocyclic group can each be independently substituted by a substituent selected from deuterium, halogen, —CF₃, CN, or substituted or unsubstituted C₁-C₄ alkyl.

In some embodiments of the present invention, general formula RD-3 includes 8 substitutable sites (i.e., a may be any integer of 0 to 8), and the substituents on the 8 substitutable sites are represented by T₃₁, T₃₂, T₃₃, T₃₄, T₃₅, T₃₆, T₃₇ and T_{38,} respectively:

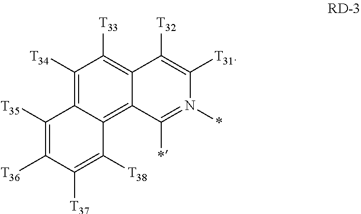

In some preferred embodiments of the present invention, at least one of T₃₁-T₃₈ in general formula RD-3 is not hydrogen and at most three of T₃₁-T₃₈ in general formula RD-3 are not hydrogen.

In some preferred embodiments of the present invention, one of T₃₁-T₃₈ in general formula RD-3 is not hydrogen.

In some preferred embodiments of the present invention, any one of T₃₃-T₃₈ in general formula RD-3 is not hydrogen. The corresponding positions of T₃₃-T₃₈ in general formula RD-3 can be substituted so that the prepared iridium complex can provide higher luminous efficiency and stability for the device.

In some preferred embodiments of the present invention, any non-hydrogen substituent of T₃₁-T₃₈ is selected from deuterium, halogen, —CF₃, CN, amino, substituted or unsubstituted C₁-C₁₀ alkoxyl, or substituted or unsubstituted C₁-C₄ alkyl, hydrogens on the alkyl chain of C₁-C₁₀ alkoxyl and C₁-C₄ alkyl can each be independently substituted by deuterium, halogen, —CF₃ or CN.

In some preferred embodiments of the present invention, any non-hydrogen substituent of T₃₁-T₃₈ is selected from deuterium, fluorine, —CF₃, CN, C₁-C₄ alkyl or C₁-C₄ alkoxyl.

In some preferred embodiments of the present invention, C₁-C₄ alkyl is selected from any one of methyl, ethyl, propyl, isopropyl, n-butyl, sec-butyl, isobutyl or tert-butyl.

In some preferred embodiments of the present invention, any two of T₃₁-T₃₈ in general formula RD-3 are not hydrogen.

In some preferred embodiments of the present invention, any two of T₃₄-T₃₇ in general formula RD-3 are not hydrogen.

In some preferred embodiments of the present invention, any two of T_{35,} T₃₇ and T₃₈ in general formula RD-3 are not hydrogen.

In some preferred embodiments of the present invention, the two non-hydrogen substituents in general formula RD-3 comprise T₃₅ and/or T₃₇.

In some preferred embodiments of the present invention, any two non-hydrogen substituents of T₃₁-T₃₈ in general formula RD-3 are each independently selected from deuterium, halogen, —CF₃, CN, or substituted or unsubstituted C₁-C₄ alkyl or alkoxyl, hydrogens on the alkyl chain of C₁-C₄ alkyl can each be independently substituted by deuterium, halogen, —CF₃ or CN.

In some preferred embodiments of the present invention, C₁-C₄ alkyl is selected from methyl, ethyl, propyl, isopropyl, n-butyl, sec-butyl, isobutyl or tert-butyl.

In some preferred embodiments of the present invention, at least one of T₃₁-T₃₈ in general formula RD-3 is selected from F, C₁-C₄ alkyl or alkoxyl, or —CF₃.

In some preferred embodiments of the present invention, at least one of T_{35,} T₃₇ or T₃₈ in general formula RD-3 is selected from F, C₁-C₄ alkyl or alkoxyl, or —CF₃, such that the luminous efficiency of the device can be further improved.

In some preferred embodiments of the present invention, any three of T₃₁-T₃₈ in general formula RD-3 are not hydrogen.

In some preferred embodiments of the present invention, any three of T₃₂, T₃₄ and T₃₅-T₃₈ in general formula RD-3 are not hydrogen.

In some preferred embodiments of the present invention, any three non-hydrogen substituents of T₃₁-T₃₈ in general formula RD-3 are each independently selected from deuterium, halogen, —CF₃, CN, or substituted or unsubstituted C₁-C₄ alkyl or alkoxyl, hydrogens on the alkyl chain of C₁-C₄ alkyl can each be independently substituted by deuterium, halogen, —CF₃, C₁-C₄ alkyl or alkoxyl, or CN.

In some preferred embodiments of the present invention, at least one of T₃₁-T₃₈ in general formula RD-3 is selected from F, C₁-C₄ alkyl or alkoxyl, or —CF₃.

In some preferred embodiments of the present invention, at least one of T₃₄-T₃₇in general formula RD-3 is selected from F, C₁-C₄ alkyl or alkoxyl, or —CF₃.

In some preferred embodiments of the present invention, at least one of T₃₂, T₃₄ and T₃₅-T₃₈ in general formula RD-3 is selected from F, C₁-C₄ alkyl or alkoxyl, or —CF₃.

In some preferred embodiments of the present invention, when the number of non-hydrogen substituent of T₃₁-T₃₈ in general formula RD-3 is ≥2, any two or more substituent can connect to each other to form a carbocyclic group.

In some preferred embodiments of the present invention, the carbocyclic group can be C₅-C₂₀ carbocyclic group.

Wherein, hydrogens on C₅-C₂₀ carbocyclic group can each be independently substituted by a substituent selected from deuterium, halogen, —CF₃, CN, or substituted or unsubstituted C₁-C₄ alkyl.

In some embodiments of the present invention, ring A is a group formed by fusing general formula II with 2 aromatic rings.

In some embodiments of the present invention, the structure formed by fusing general formula II with 2 benzene rings is selected from any one of RD-4 to RD-12:

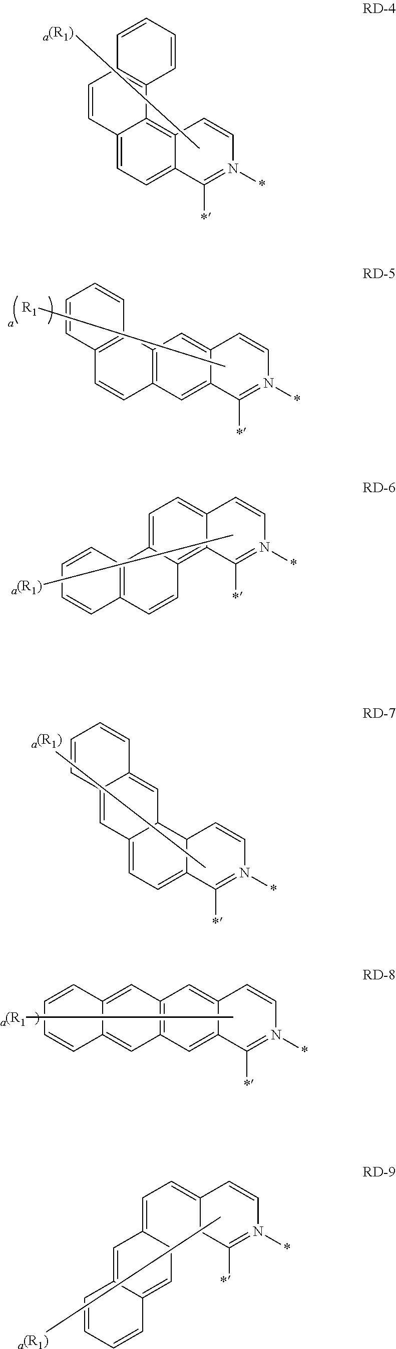

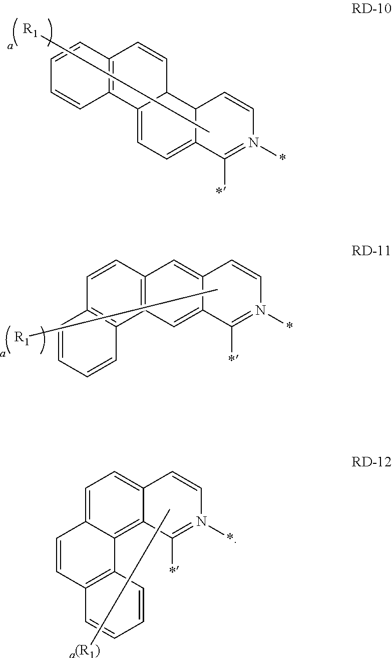

In some embodiments of the present invention, ring A may be a group formed by fusing general formula II with 3 aromatic rings.

In some embodiments of the present invention, the structure formed by fusing general formula II with 3 benzene rings is preferably selected from RD-13:

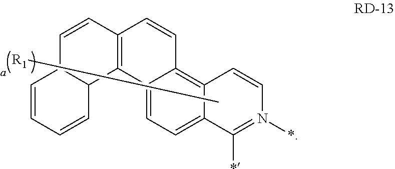

In some embodiments of the present invention, ring A may be a group formed by fusing general formula II with saturated or unsaturated five-membered rings.

In some embodiments of the present invention, the group formed by fusing general formula II with saturated or unsaturated five-membered rings can be any one of RD-14 to RD-18:

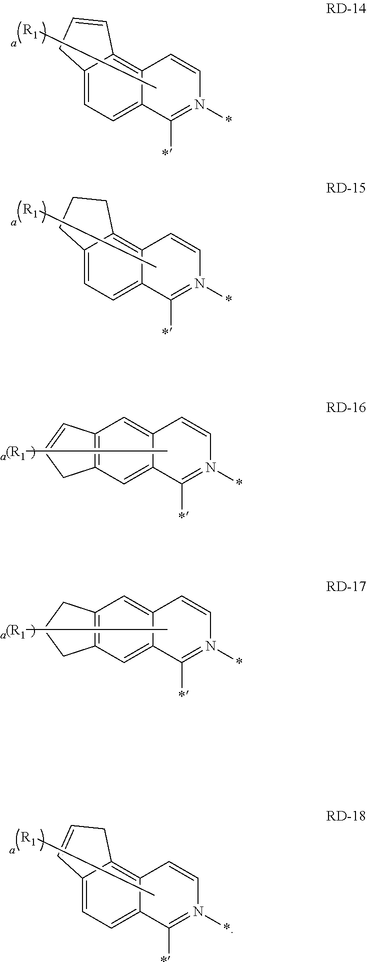

In some embodiments of the present invention, ring A may be a group formed by fusing general formula II with five- or six-membered rings containing N, O or S.

In some embodiments of the present invention, the group formed by fusing general formula II with five- or six-membered rings containing N, O or S can be any one of RD-19 to RD-27:

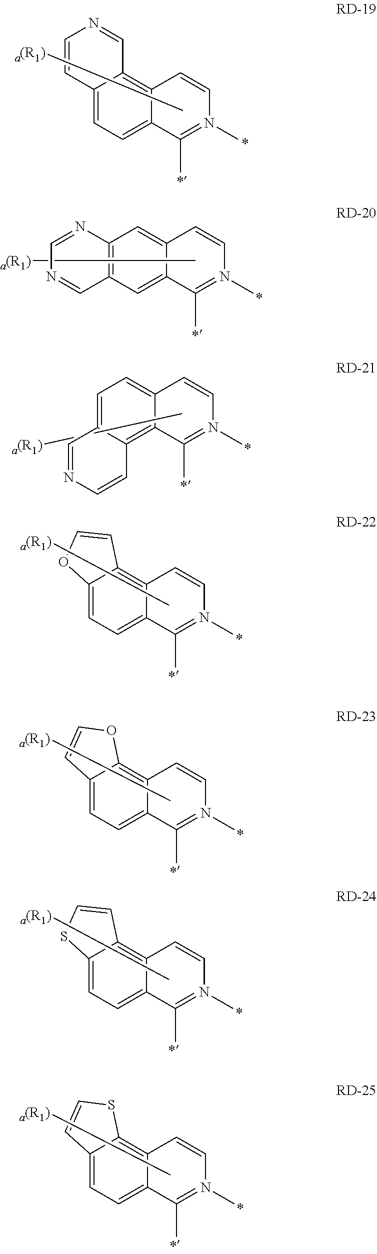

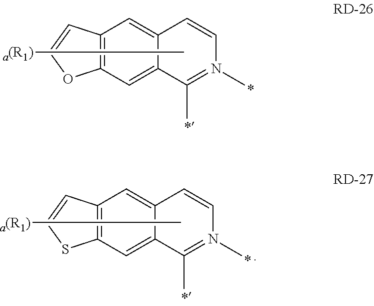

In some embodiments of the present invention, ring A may be a group formed by fusing general formula II with benzene ring via one five-membered ring, wherein the unfused carbon atoms in the five-membered ring can be substituted by N, O or S.

In some embodiments of the present invention, the group formed by fusing general formula II with benzene ring via one five-membered ring can be any one of RD-28 to RD-42:

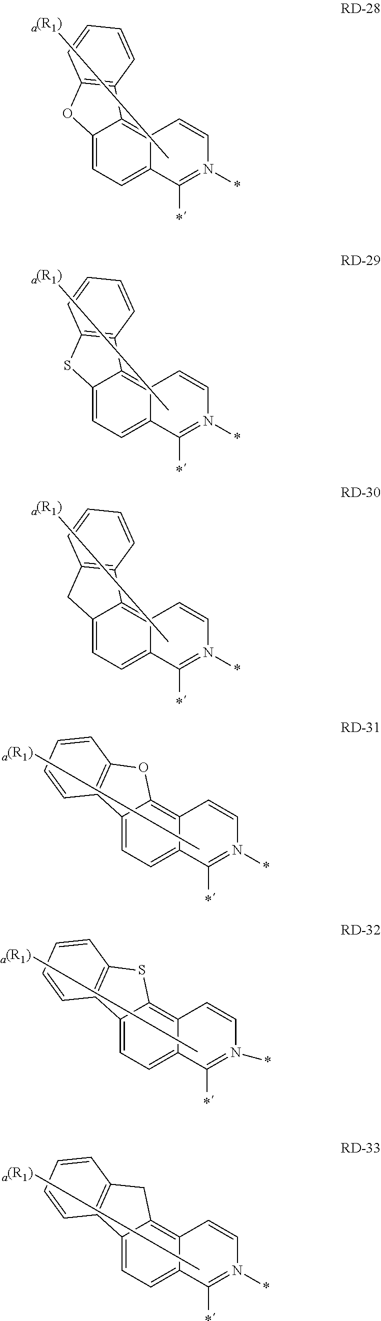

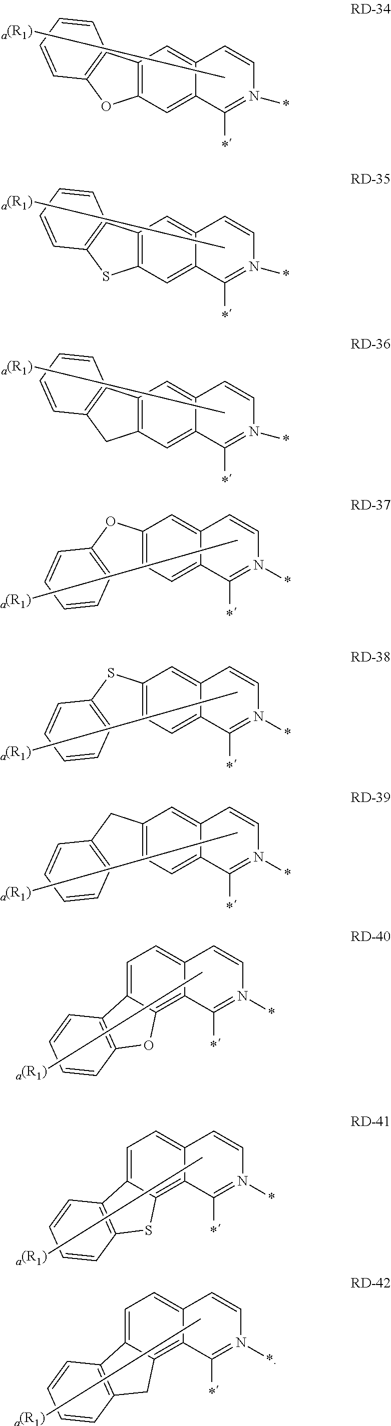

In some embodiments of the present invention, the substituents on the substitutable sites of general formulae RD-4 to RD-42 are represented by Pₙ, wherein n is an integer that is greater than 0, the number of substituents on the same substitutable site is represented by m, m is 0, 1 or 2; ring A can be any one of the following general formulae:

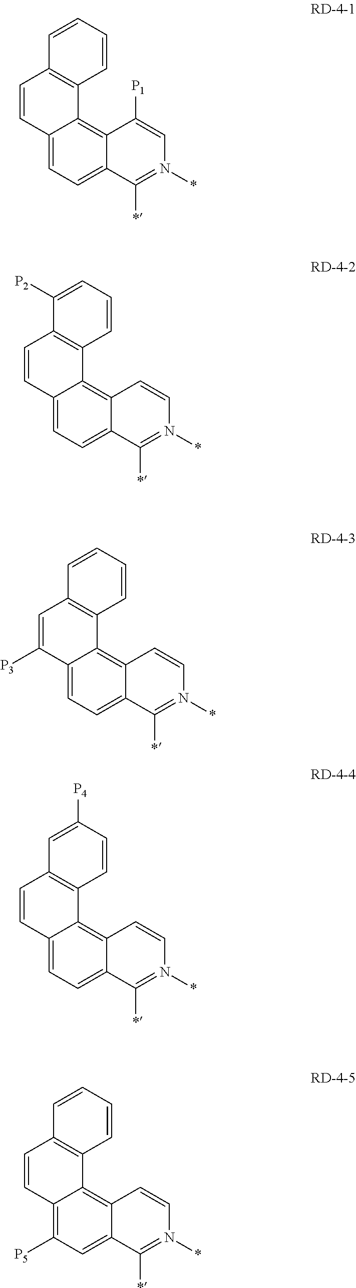

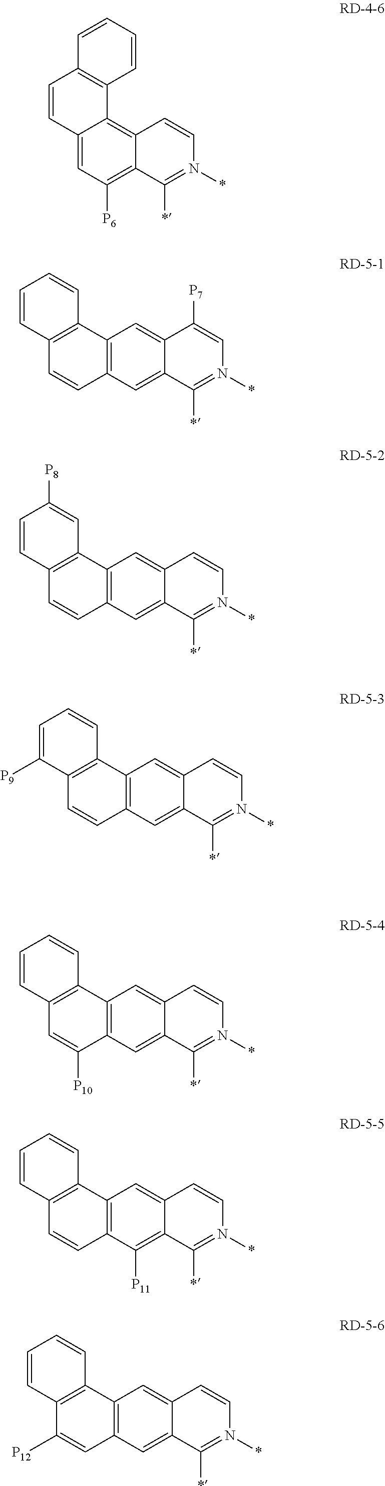

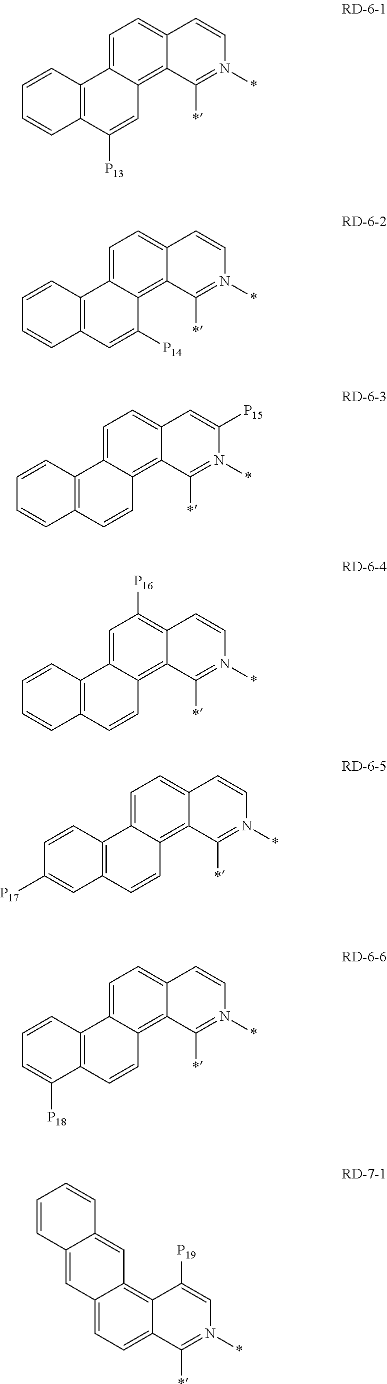

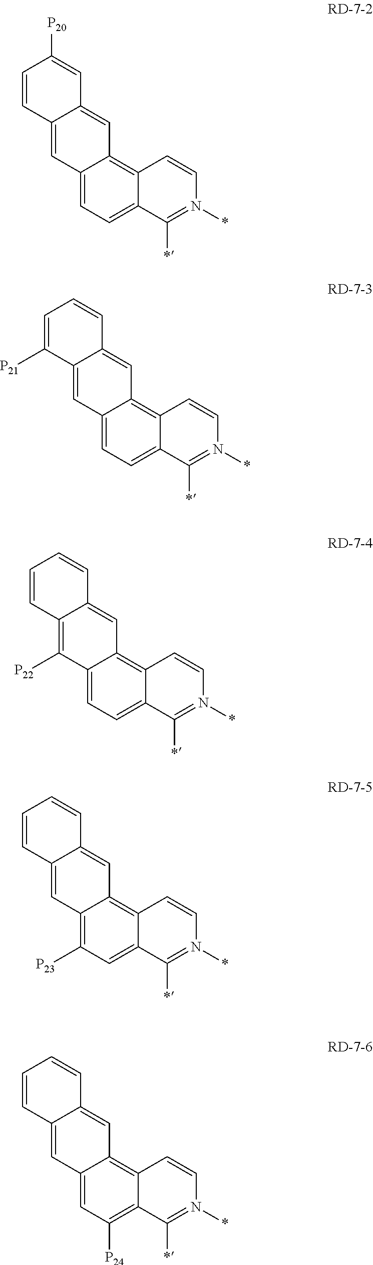

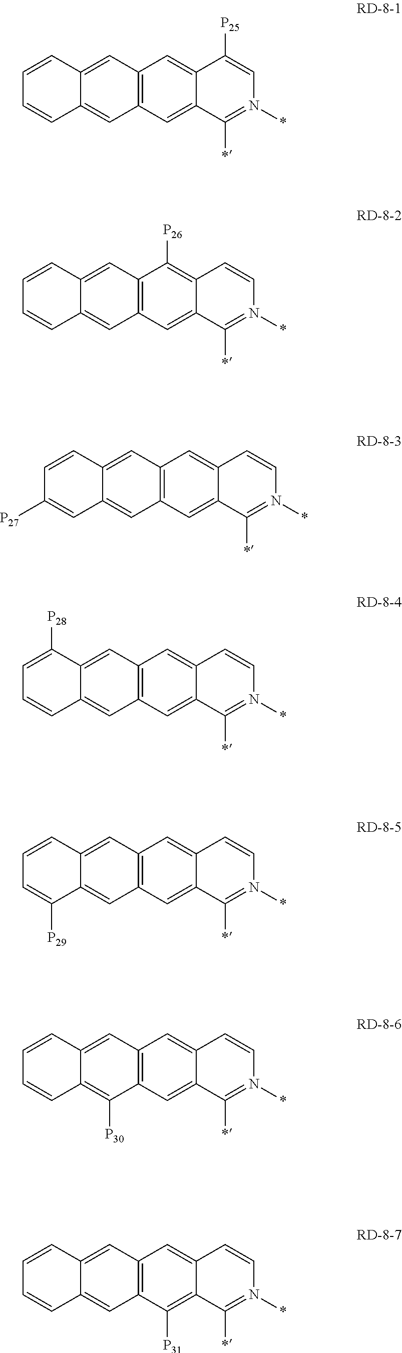

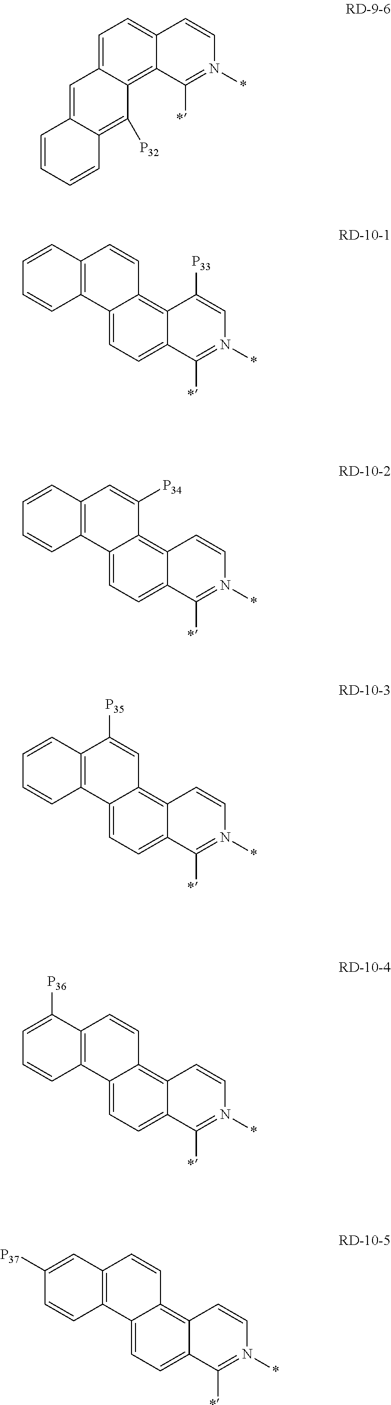

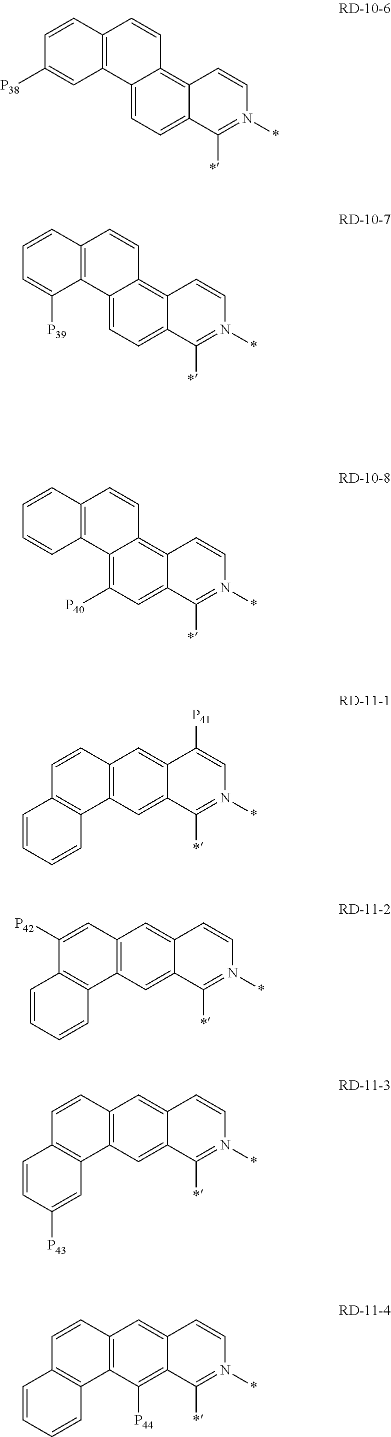

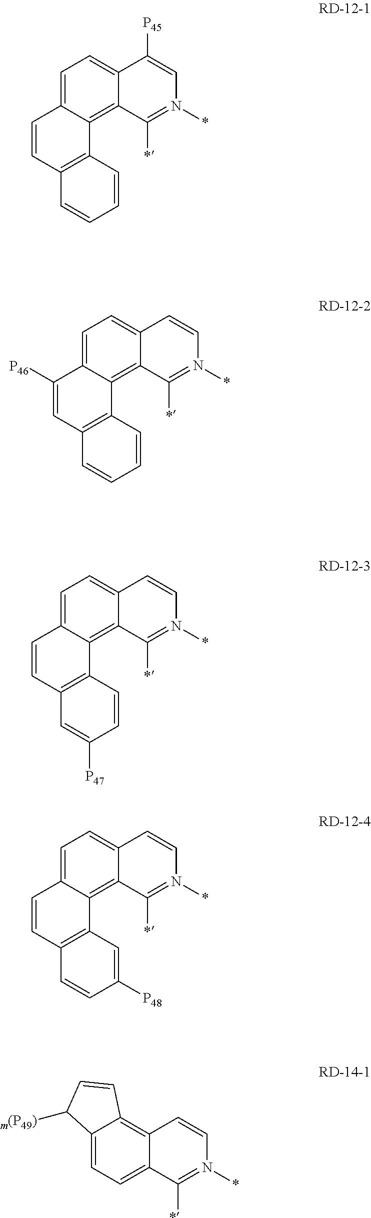

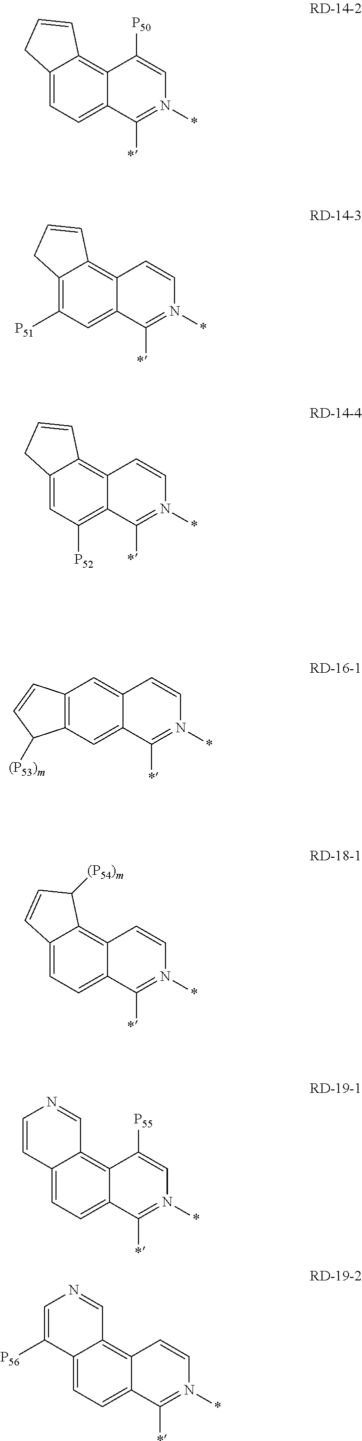

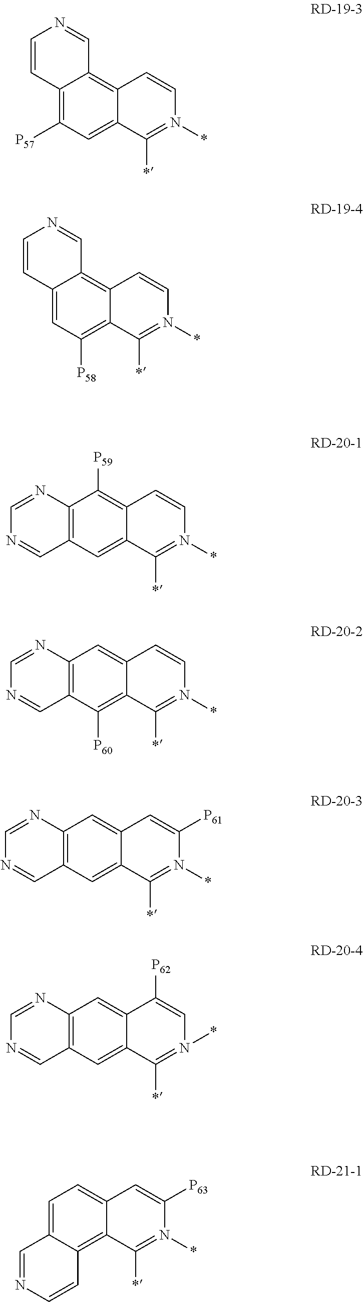

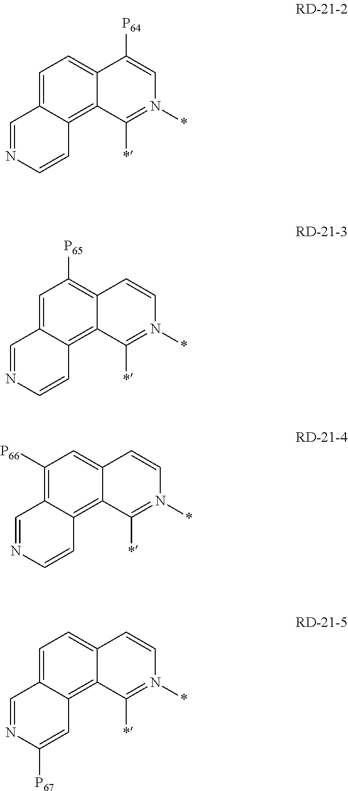

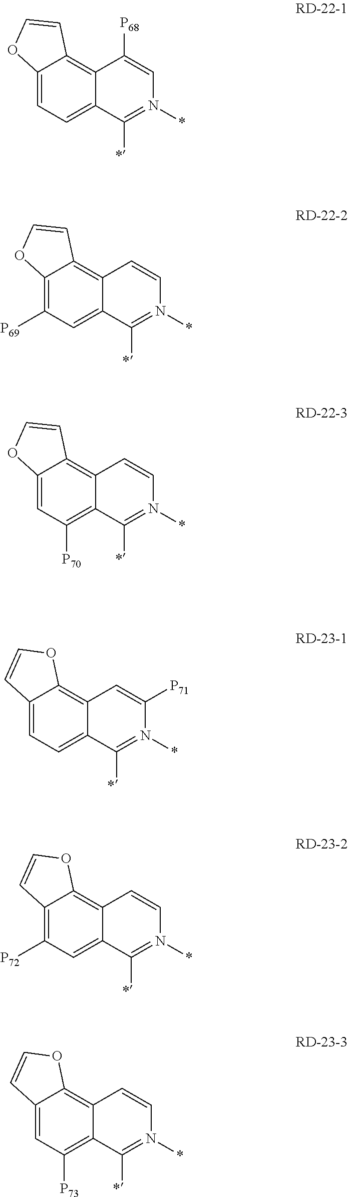

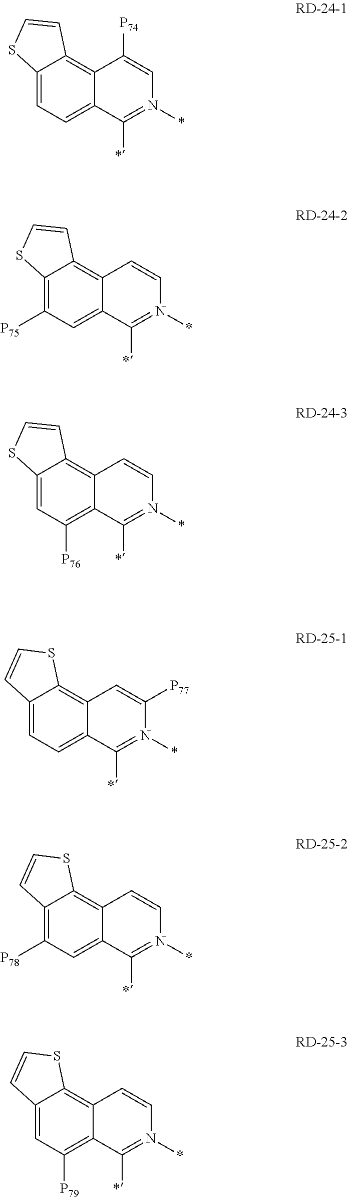

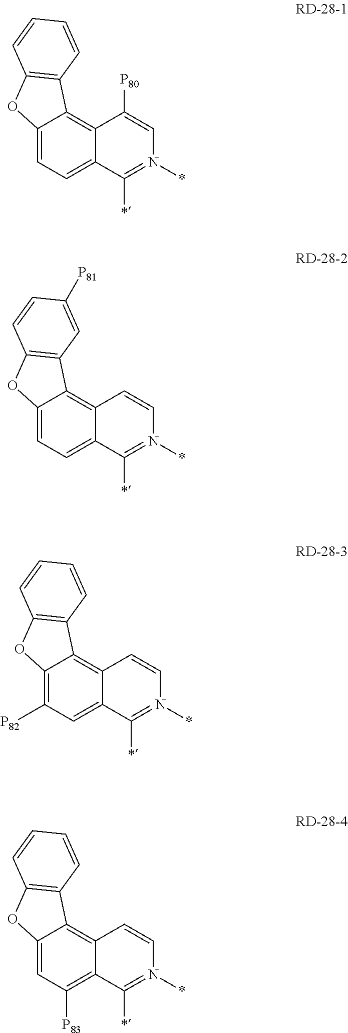

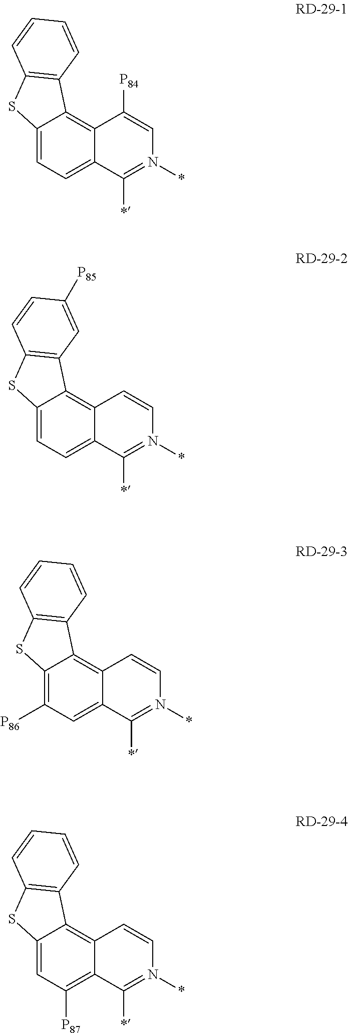

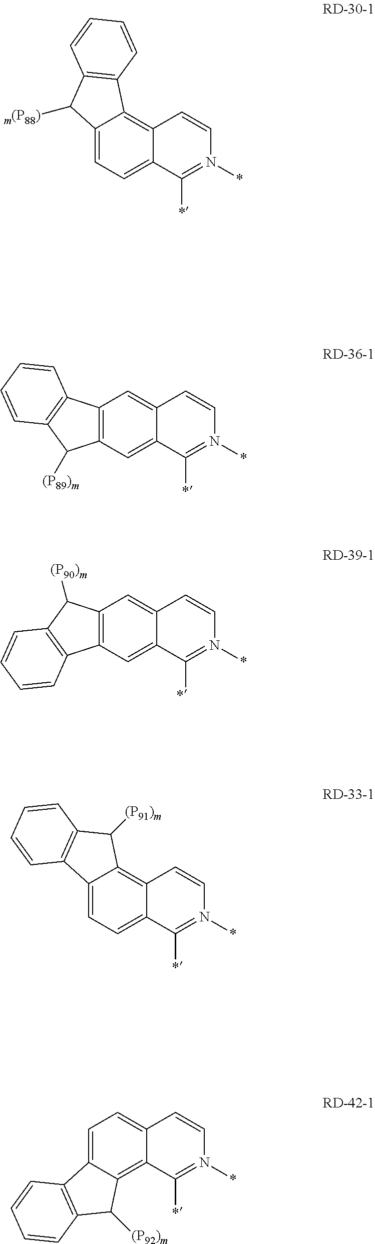

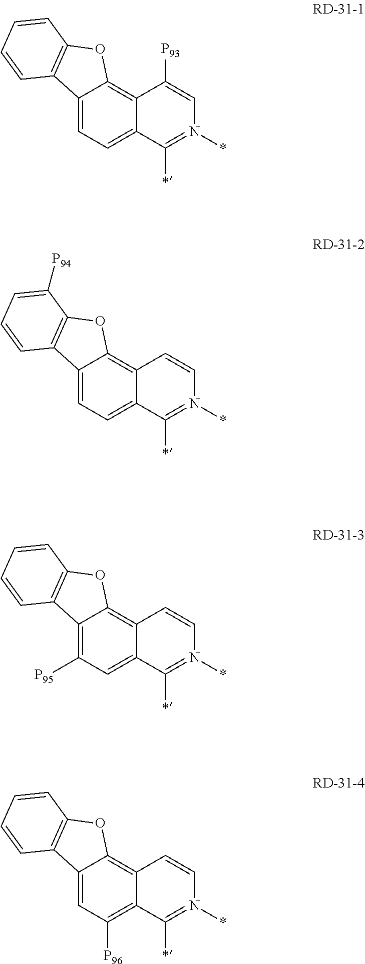

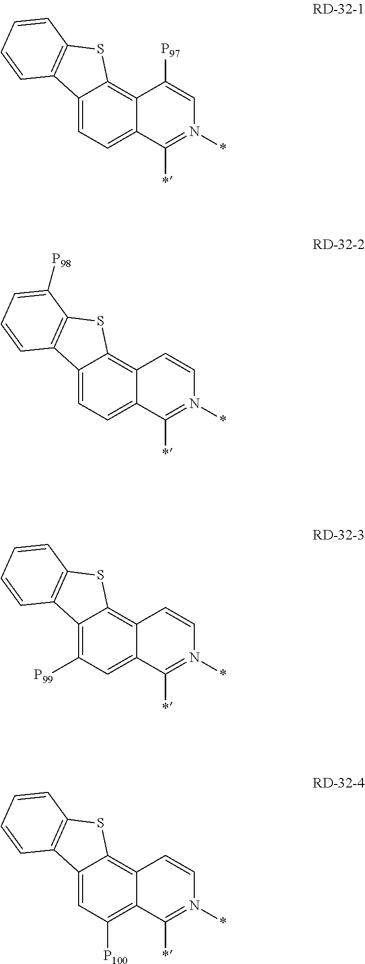

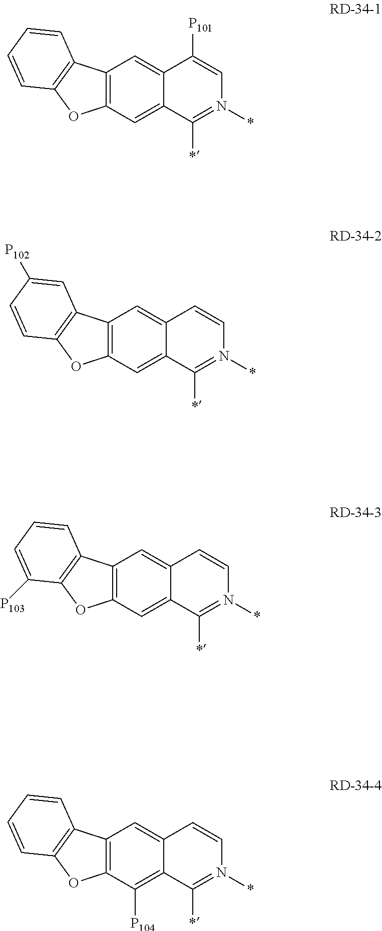

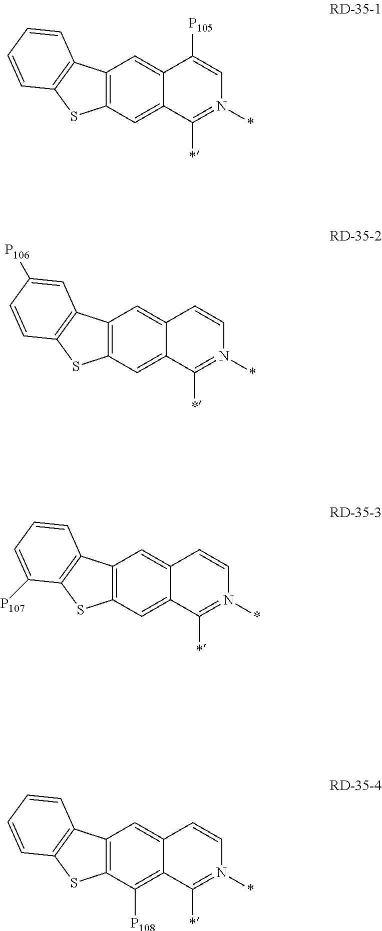

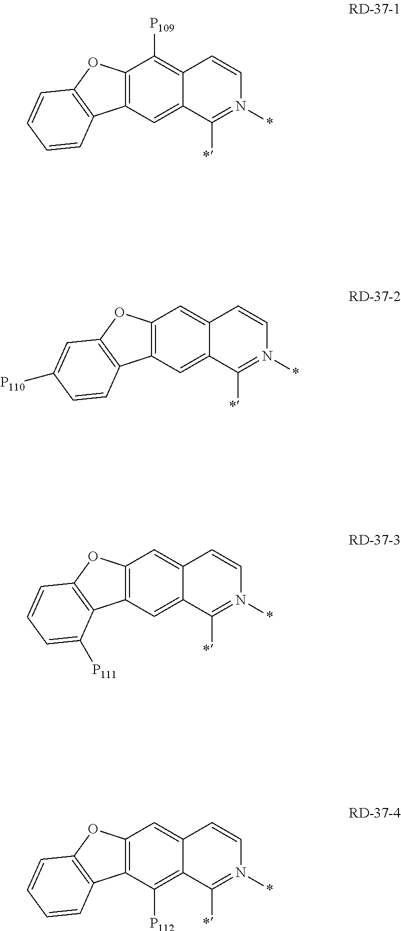

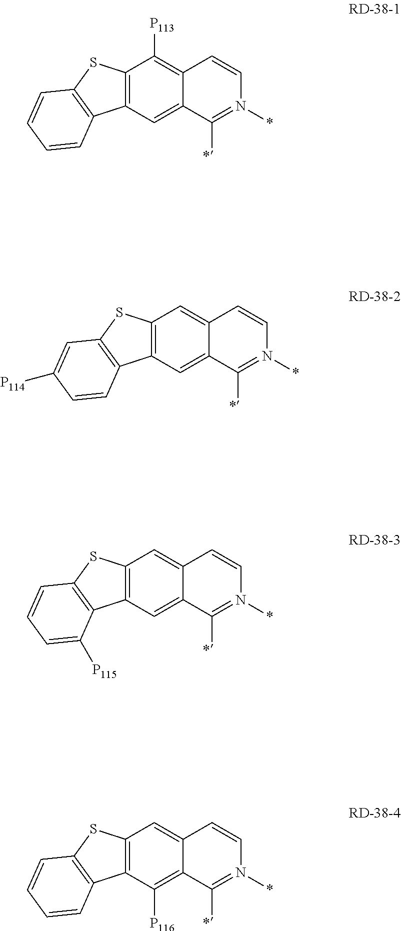

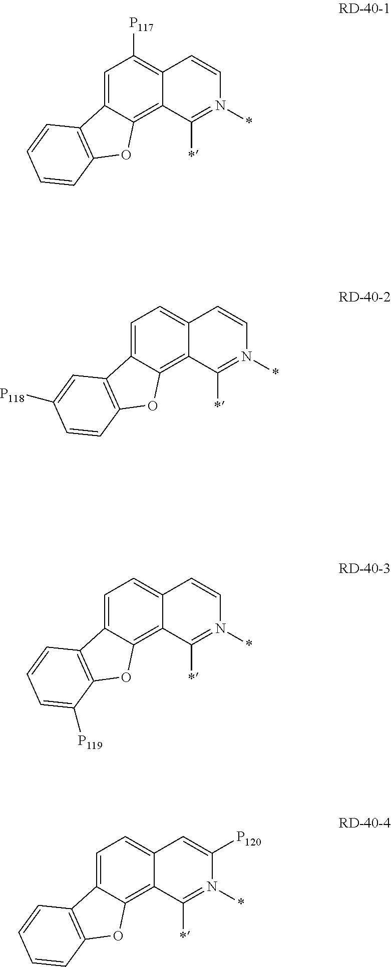

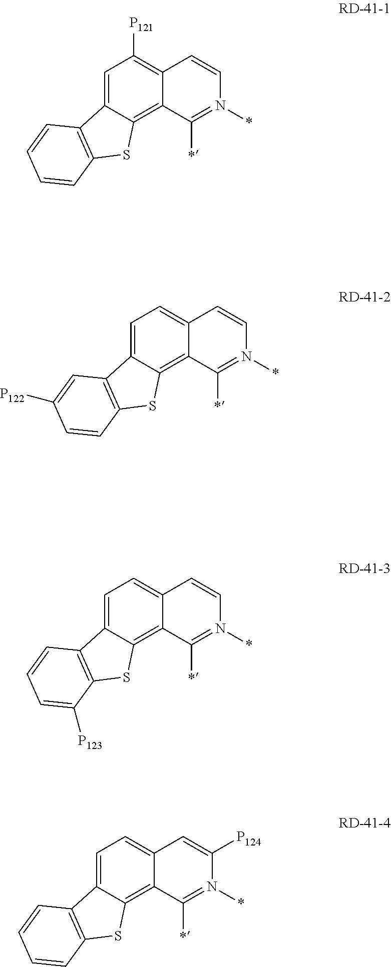

wherein, P₁-P₁₂₄ each is independently selected from a group consisting of H, deuterium, halogen, —CF₃, CN, amino, substituted or unsubstituted C₁-C₁₀ alkoxyl, or substituted or unsubstituted C₁-C₃₀ alkyl, hydrogens on the alkyl chain of C₁-C₁₀ alkoxyl and C₁-C₃₀ alkyl can each be independently substituted by deuterium, halogen, —CF₃ or CN, wherein halogen is selected from fluorine, chlorine, bromine or iodine.

In some embodiments of the present invention, when m is 2, P₄₉, P₅₃, P₅₄ and P₈₈-P₉₂ may be the same or different.

In some embodiments of the present invention, P₁-P₁₂₄ each independently is deuterium, halogen, —CF₃, CN or substituted or unsubstituted C₁-C₁₀ alkyl, C₁-C₁₀ alkyl may be substituted by deuterium, halogen, —CF₃ or CN, m is an integer of 0 to 2; halogen includes fluorine, chlorine, bromine or iodine.

In some preferred embodiments of the present invention, P₁-P₁₂₄ each is independently selected from substituted or unsubstituted C₁-C₂₀ alkyl.

In some preferred embodiments of the present invention, P₁-P₁₂₄ each is independently selected from substituted or unsubstituted C₁-C₁₀ alkyl.

In some preferred embodiments of the present invention, P₁-P₁₂₄ each is independently selected from substituted or unsubstituted C₁-C₄ alkyl.

In some preferred embodiments of the present invention, alkyl is selected from methyl, ethyl, propyl, isopropyl, n-butyl, sec-butyl, isobutyl, tert-butyl, n-pentyl, n-hexyl, n-heptyl, n-octyl, n-nonyl, n-decyl, n-undecyl, n-dodecyl, n-tridecyl, n-tetradecyl, n-pentadecyl, n-hexadecyl, n-heptadecyl, n-octadecyl, neopentyl, 1-methylpentyl, 2-methylpentyl, 1-pentylhexyl, 1-butylpentyl, 1-heptyloctyl or 3-methylpentyl.

In some preferred embodiments of the present invention, alkyl is selected from methyl, ethyl, propyl, isopropyl, butyl or isobutyl.

In some preferred embodiments of the present invention, in general formula I, R₂, R₃, R₄ and R₅ are the same or different and each is independently selected from H or C₁-C10 alkyl.

In some preferred embodiments of the present invention, in general formula I, R₂, R₃, R₄ and R₅ are the same or different and each is independently selected from H or C₁-C₄ alkyl.

In specific, C₁-C₁₀ alkyl is selected from methyl, ethyl, propyl, isopropyl, n-butyl, sec-butyl, isobutyl, tert-butyl, n-pentyl, n-hexyl, n-heptyl, n-octyl, n-nonyl or n-decyl. C₁-C₄ alkyl is selected from methyl, ethyl, propyl, isopropyl, n-butyl, sec-butyl, isobutyl or tert-butyl.

In some preferred embodiments of the present invention, one or more of R₂, R₃, R₄ and R₅ are not hydrogen.

In some preferred embodiments of the present invention, any one of R₂, R₃, R₄ and R₅ is not hydrogen.

In some preferred embodiments of the present invention, any two of R₂, R₃, R₄ and R₅ are not hydrogen.

In some preferred embodiments of the present invention, R₂ and R₃ are not hydrogen.

In some preferred embodiments of the present invention, R₃ and R₄ are not hydrogen.

In some preferred embodiments of the present invention, R₄ and R₅ are not hydrogen.

In some preferred embodiments of the present invention, R₃ and R₅ are not hydrogen.

In some preferred embodiments of the present invention, any three of R₂, R₃, R₄ and R₅ are not hydrogen.

In some preferred embodiments of the present invention, R₂, R₃ and R₄ are not hydrogen.

In some preferred embodiments of the present invention, R₂, R₃ and R₅ are not hydrogen.

In some preferred embodiments of the present invention, R₃, R₄ and R₅ are not hydrogen.

In some embodiments of the present invention, in the auxiliary ligand portion of general formula I, Rₓ and R_{y} may be the same or different and each independently includes saturated aliphatic ring structure. The saturated aliphatic ring structure has a higher thermal stability, such that the thermal stability of the iridium complex of general formula I is improved.

In some preferred embodiments of the present invention, Rₓ and R_{y} each independently includes saturated C₃-C₈ monocyclic ring.

In some preferred embodiments of the present invention, the saturated C₃-C₈ monocyclic ring included in Rₓ and R_{y} is selected from any one of the following ring structures:

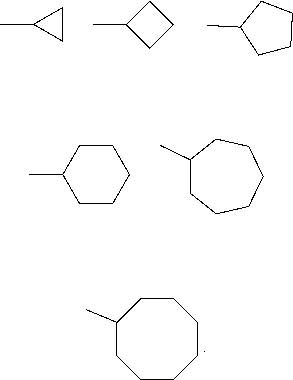

In some preferred embodiments of the present invention, Rₓ and R_{y} each independently includes saturated C₅-C₆ monocyclic ring.

In specific, the following structures are the specific examples of C₅-C₆ monocyclic ring:

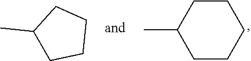

when the number of carbon atoms of the monocyclic ring is 5 to 6, the ring strain thereof is lower, such that the thermal stability of the iridium complex of general formula I can be further improved, and the service life of the device is further improved.

In some preferred embodiments of the present invention, Rₓ and R_{y} each independently includes C₇-C₁₅ spiro ring or bridged cyclic ring.

In some preferred embodiments of the present invention, the saturated C₇-C₁₅ spiro ring or bridged cyclic ring included in Rₓ and R_{y} is selected from any one of the following ring structures:

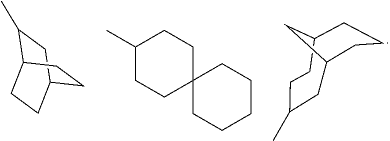

In specific, the above C₇-C₁₅ spiro rings or bridged cyclic rings have appropriate ring strain, such that the thermal stability of the iridium complex of general formula I can be further improved, and the service life of the device is further improved.

In some preferred embodiments of the present invention, Rₓ and R_{y} each is independently a ring structure formed by connecting two or more saturated aliphatic rings (for examples, saturated C₃-C₈ monocyclic rings, saturated C₇-C₁₅ spiro rings and saturated C₇-C₁₅ bridged cyclic rings) via single bonds.

In some preferred embodiments of the present invention, Rₓ and R_{y} each may independently be a ring structure formed by connecting two or more C₃-C₈ monocyclic rings via single bonds.

In some preferred embodiments of the present invention, Rₓ and R_{y} each may independently be a ring structure formed by connecting two or more C₇-C₁₅ spiro rings via single bonds.

In some preferred embodiments of the present invention, Rₓ and R_{y} each may independently be a ring structure formed by connecting two or more C₇-C₁₅ bridged cyclic rings via single bonds.

In some preferred embodiments of the present invention, Rₓ and R_{y} each may independently be a ring structure formed by connecting one or more C₇-C₁₅ spiro rings with one or more C₃-C₈ monocyclic rings via single bonds.

In some preferred embodiments of the present invention, Rₓ and R_{y} each may independently be a ring structure formed by connecting one or more C₇-C₁₅ bridged cyclic rings with one or more C₃-C₈ monocyclic rings via single bonds.

In some preferred embodiments of the present invention, one or more hydrogens on the ring structure included in Rₓ and R_{y} can each be independently substituted by a substituent selected from deuterium, halogen, —CF₃, —CN or C₁-C₄ alkyl. The substitution may be single substitution or multiple substitution, may be the substitution of one hydrogen on the same carbon atom or the substitution of two hydrogens on the same carbon atom, and the number of substitutions does not exceed the number of substitutable sites on the ring. The substituents may be the same or different and each is independently selected from deuterium, halogen, —CF₃, —CN or C₁-C₄ alkyl.

In specific, halogen is selected from fluorine, chlorine, bromine or iodine; C₁-C₄ alkyl is selected from methyl, ethyl, propyl, isopropyl, n-butyl, sec-butyl, isobutyl or tert-butyl.

In some preferred embodiments of the present invention, the structure of the auxiliary ligand in general formula I is selected from any one of RP-1 to RP-21:

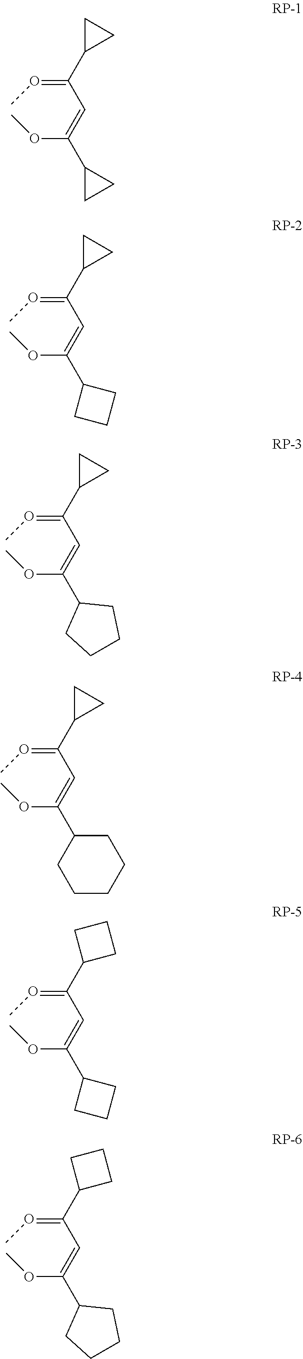

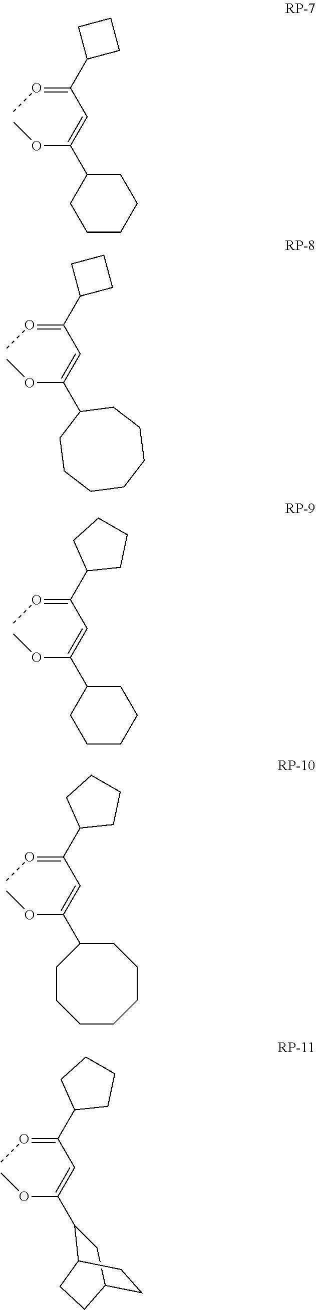

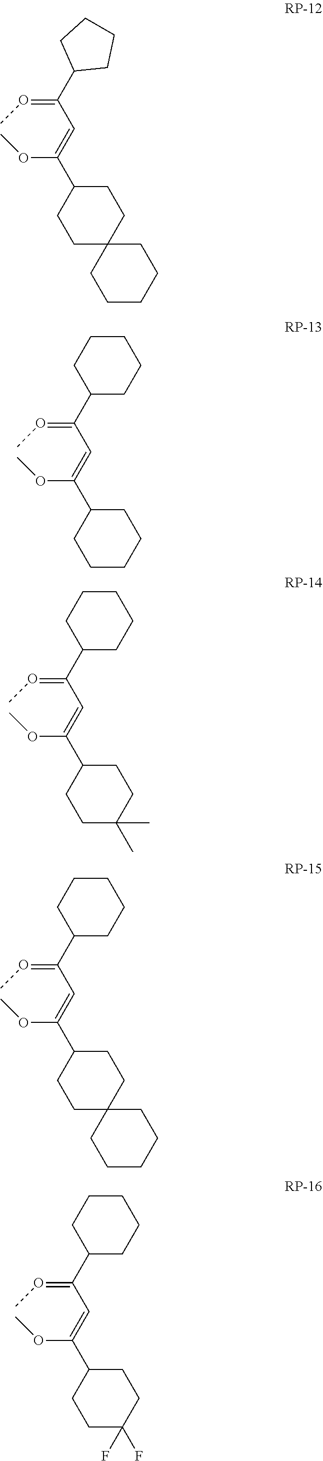

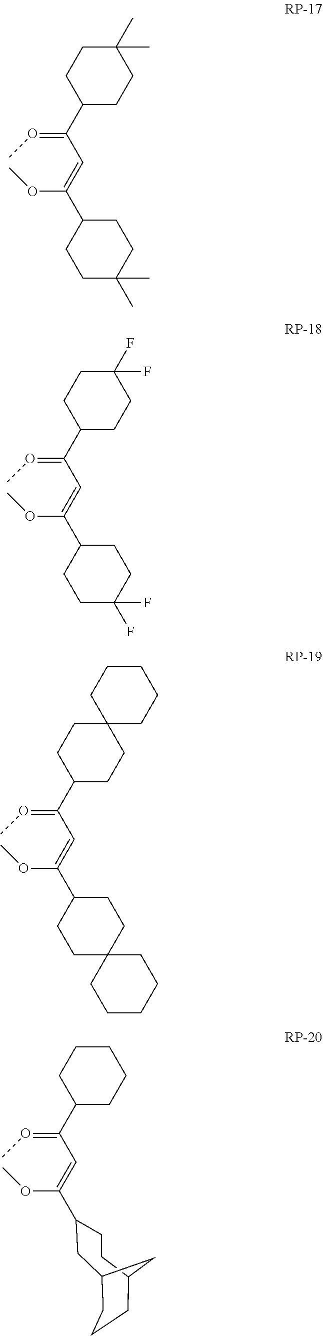

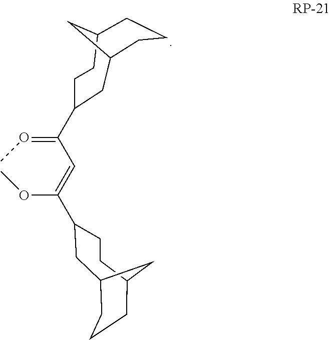

In some preferred embodiments of the present invention, the main ligand of general formula I includes any one of general formulae RD-1 to RD-42.

In some preferred embodiments of the present invention, the main ligand of general formula I includes any one of general formulae RD-1 to RD-18.

In some preferred embodiments of the present invention, the main ligand of general formula I includes any one of general formulae RD-1 to RD-13.

In some preferred embodiments of the present invention, the main ligand of general formula I includes any one of general formulae RD-1 to RD-3.

In the still further preferred embodiments of the present invention, the main ligand of general formula I is selected from any one of the followings:

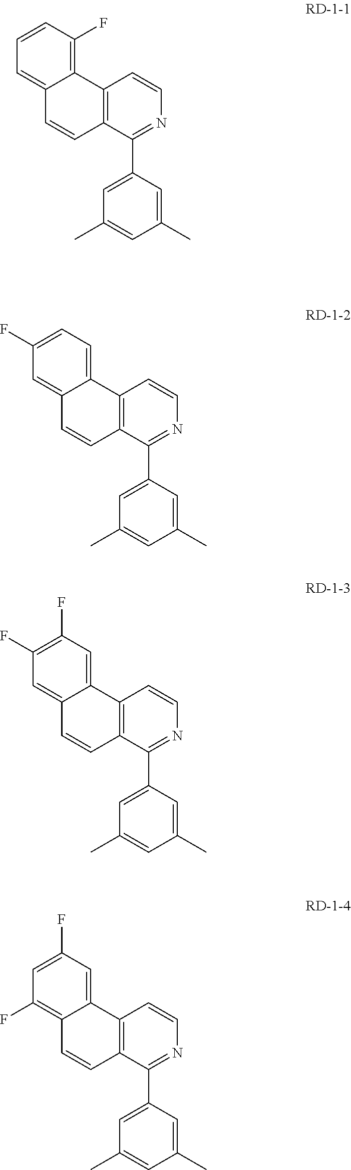

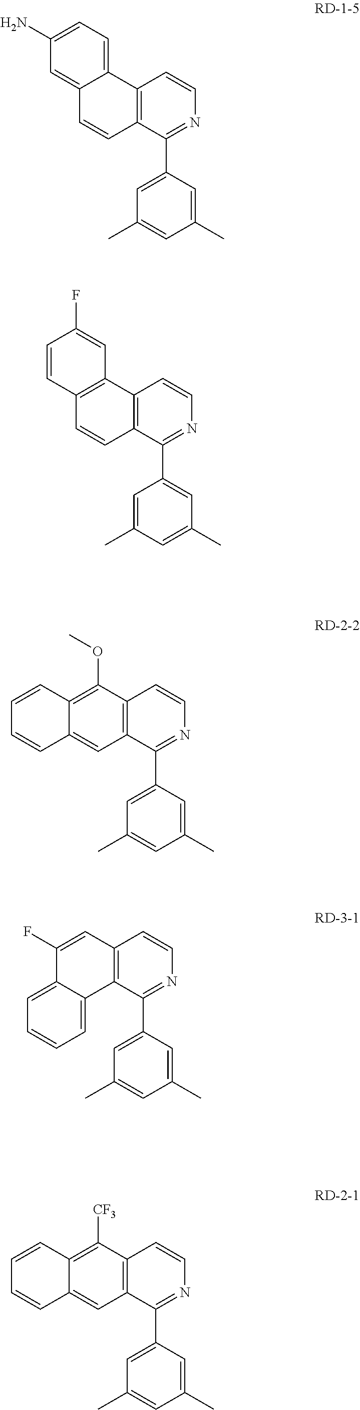

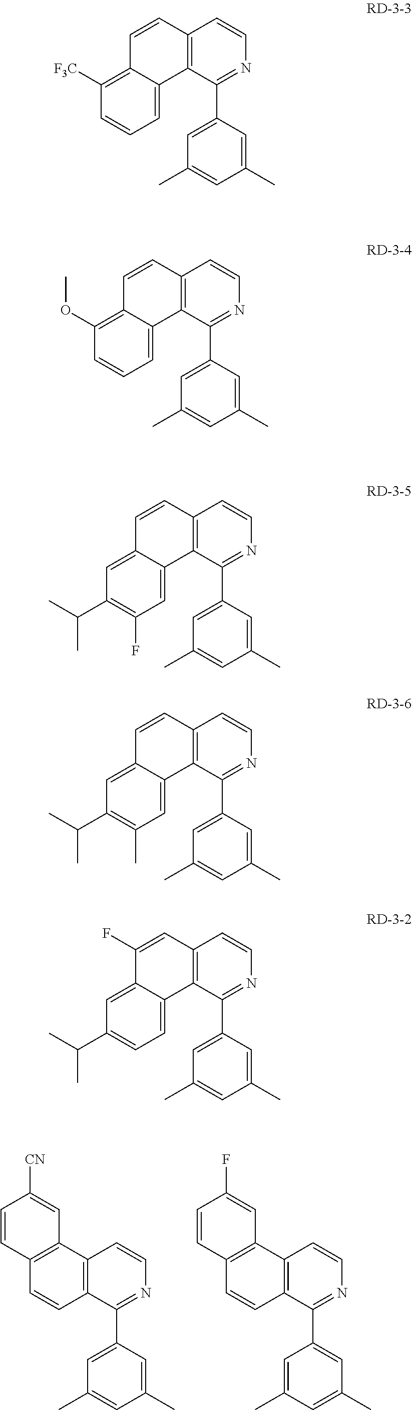

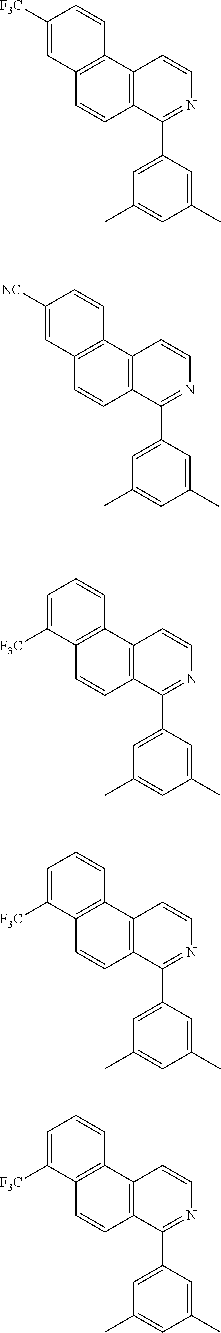

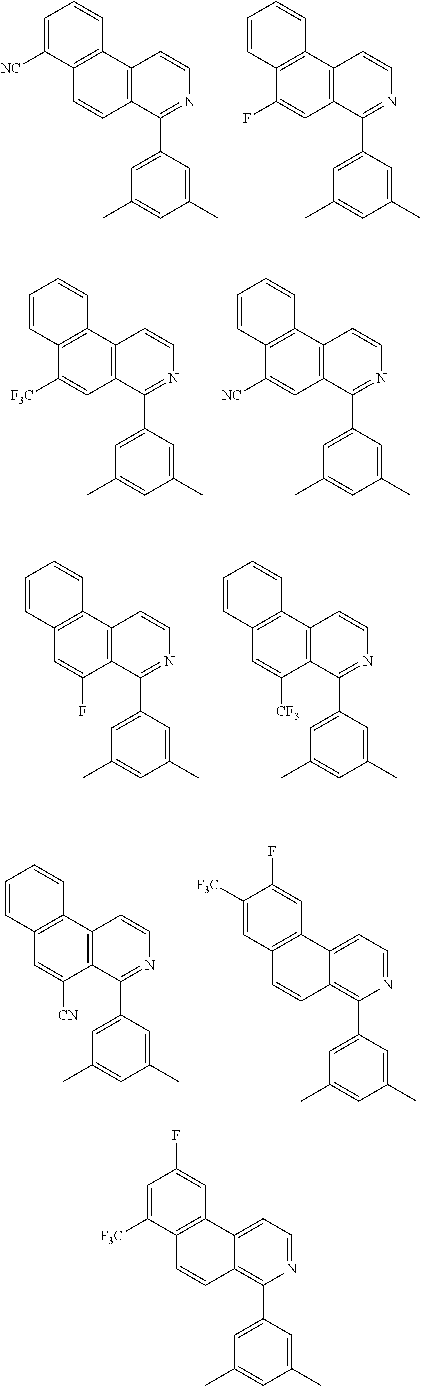

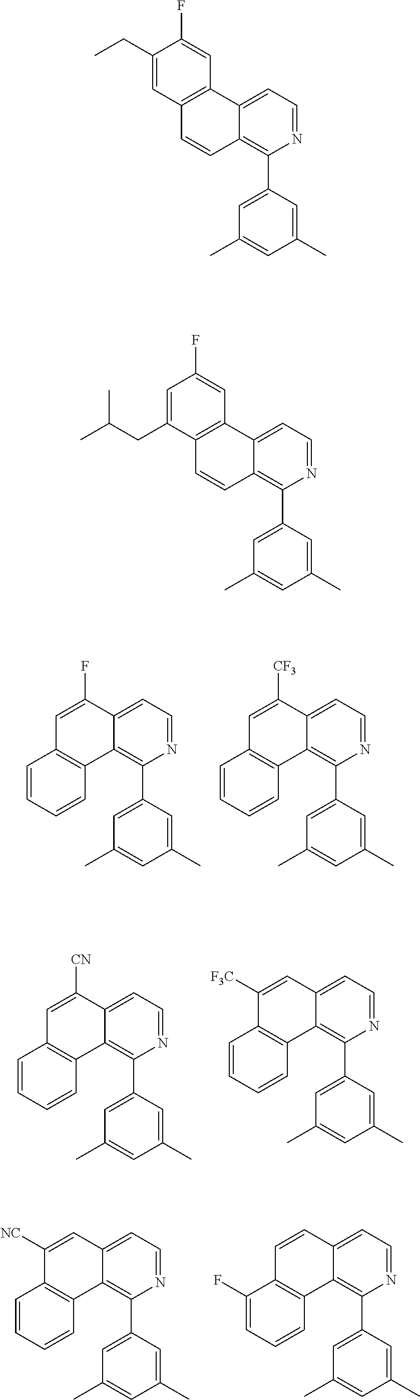

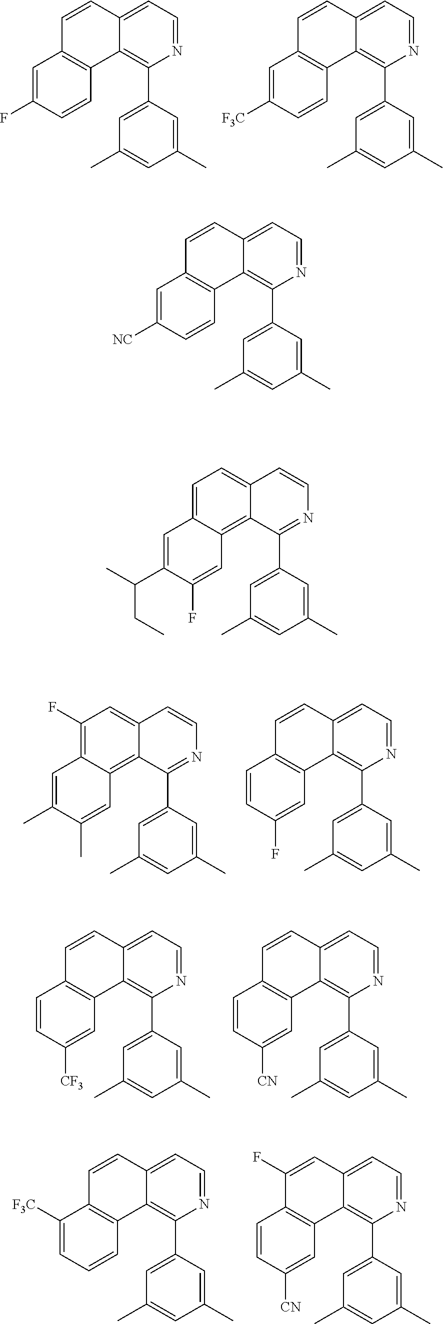

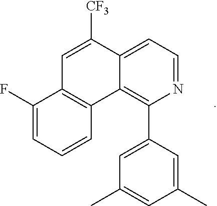

In some preferred embodiments of the present invention, the auxiliary ligand of general formula I is selected from any one of RP-1 to RP-21.

In some preferred embodiments of the present invention, the auxiliary ligand of general formula I is selected from any one of RP-9 to RP-21.

In some preferred embodiments of the present invention, the auxiliary ligand of general formula I is selected from any one of RP-9, RP-12 and RP-13 to RP-19.

In the further preferred embodiments of the present invention, the auxiliary ligand of general formula I is selected from any one of RP-13 to RP-19.

In the still further preferred embodiments of the present invention, the auxiliary ligand of general formula I is selected from any one of RP-13 and RP-19.

In some preferred embodiments of the present invention, the combination of the main ligand and the auxiliary ligand in general formula I is selected from any one of the followings: RD-1 and RP-13, RD-2 and RP-13, RD-3 and RP-13, RD-1 and RP-14, RD-2 and RP-14, RD-3 and RP-14, RD-1 and RP-16, RD-2 and RP-16, RD-3 and RP-16, RD-1 and RP-17, RD-2 and RP-17, RD-3 and RP-17, RD-1 and RP-18, RD-2 and RP-18, RD-3 and RP-18, RD-1 and RP-19, RD-2 and RP-19, or RD-3 and RP-19.

In some preferred embodiments of the present invention, general formula I is selected from any one of the structures represented by RDP-1 to RDP-52:

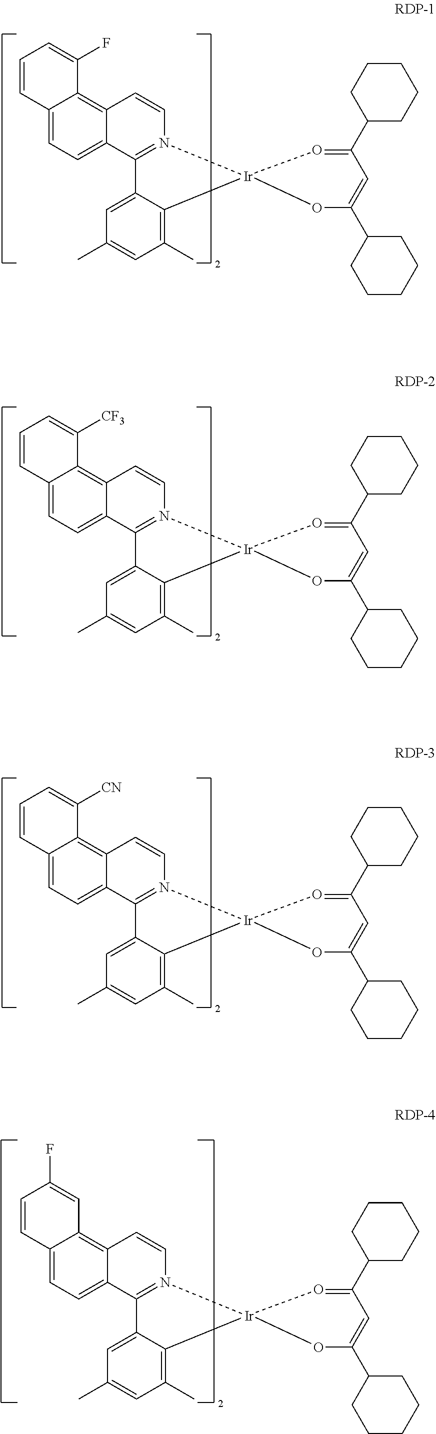

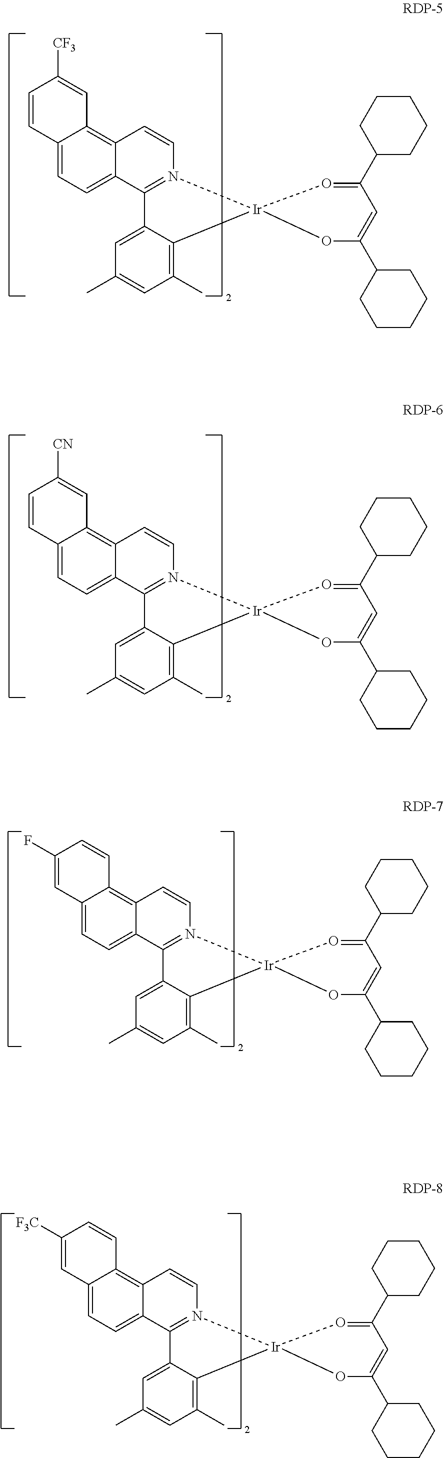

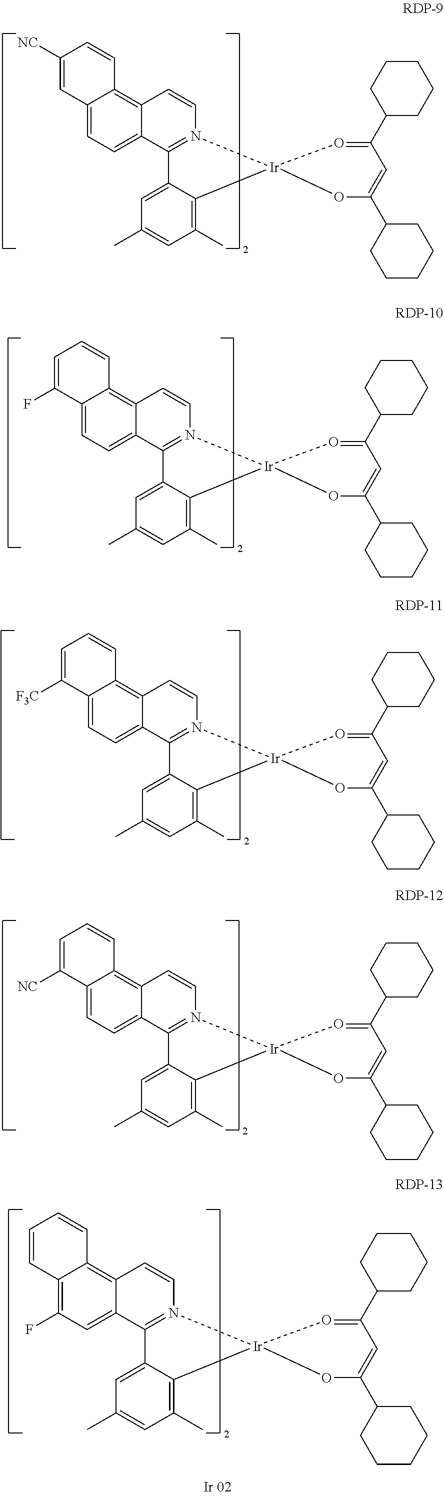

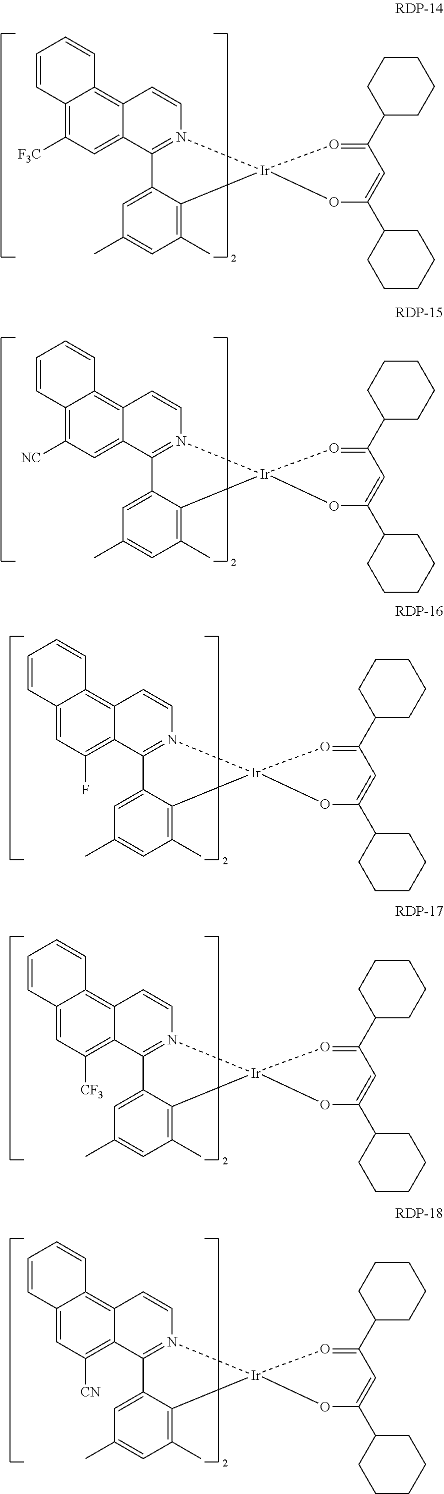

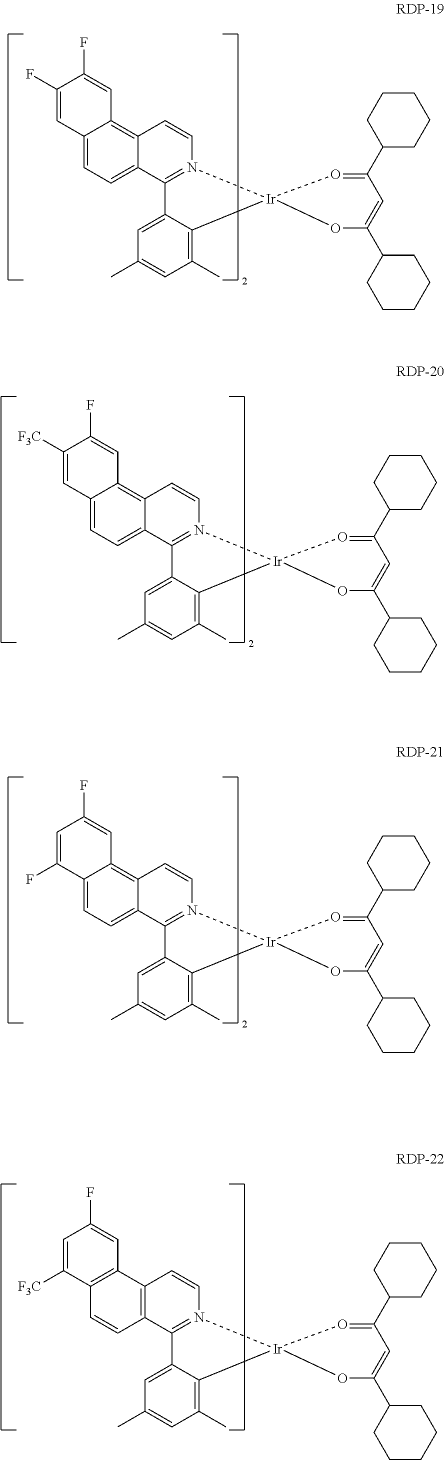

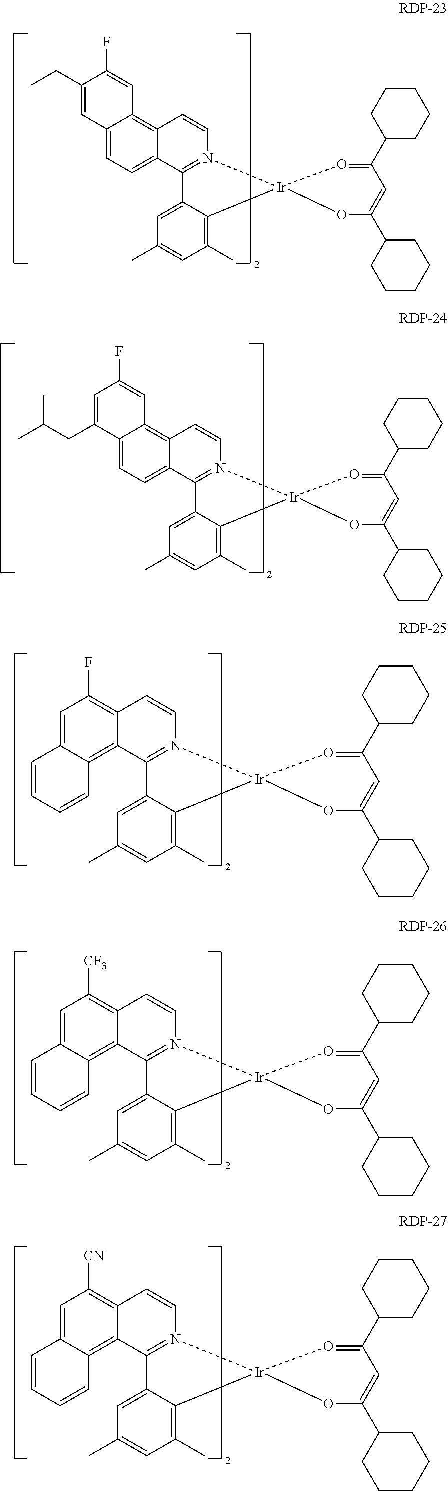

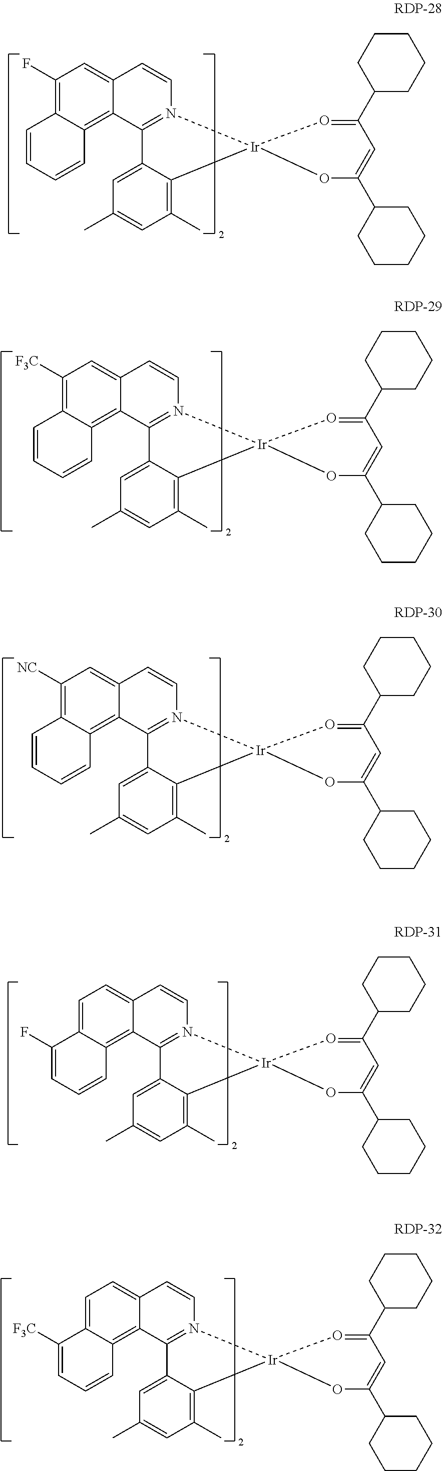

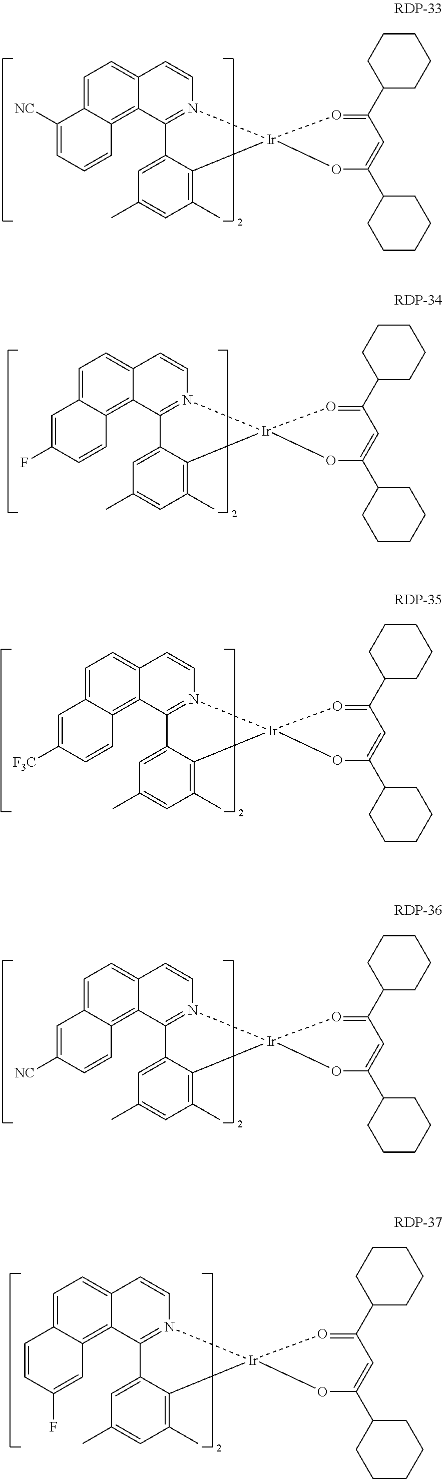

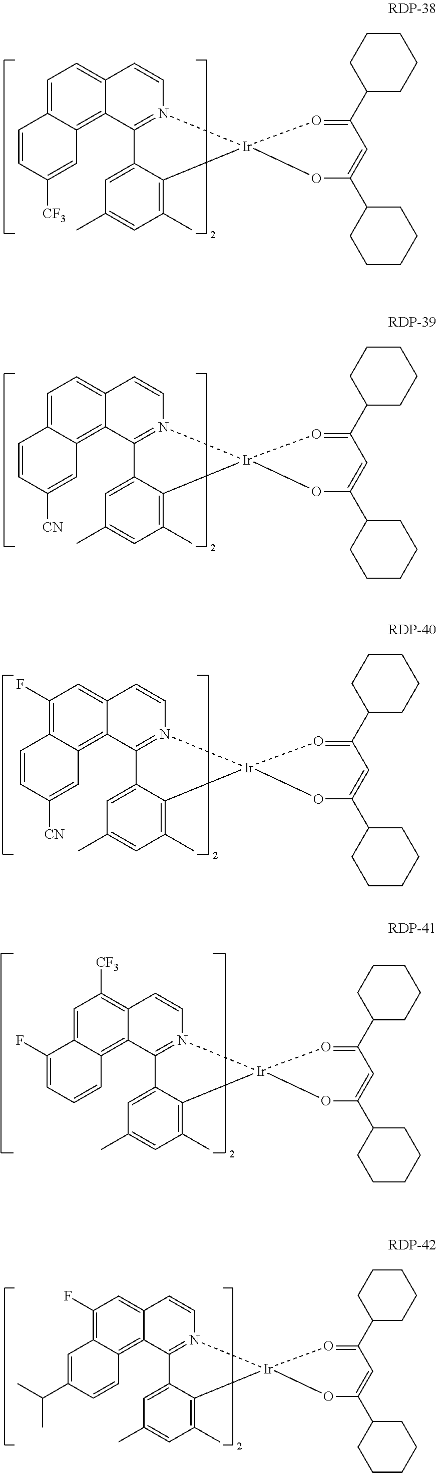

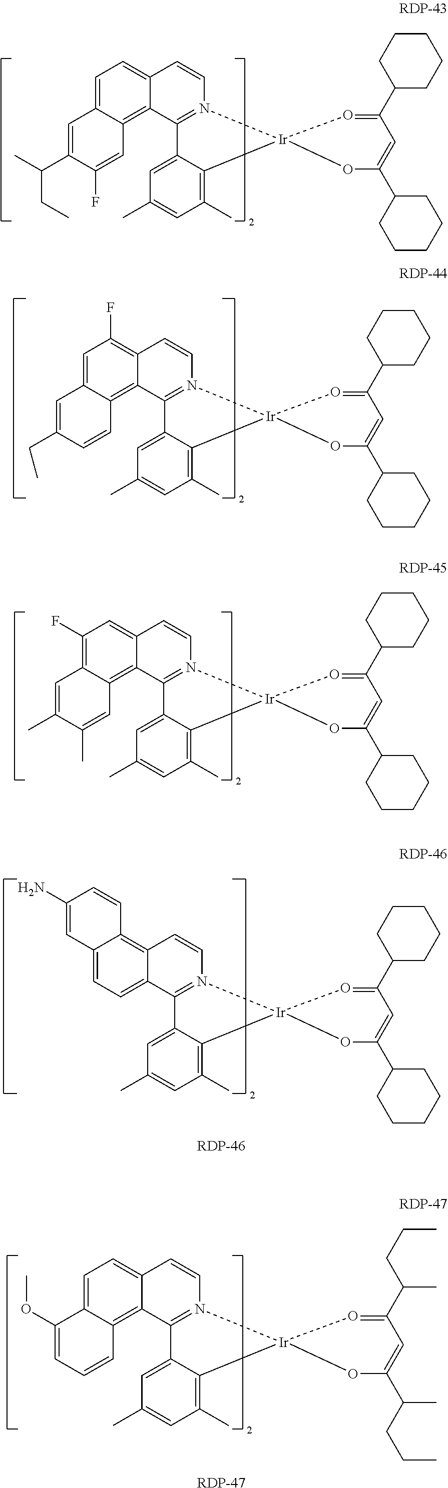

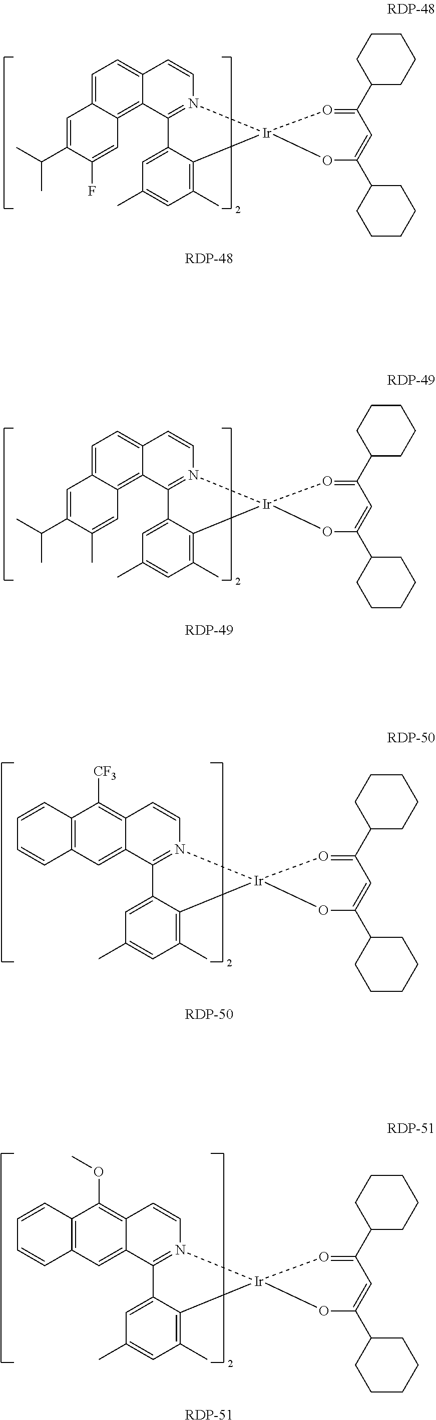

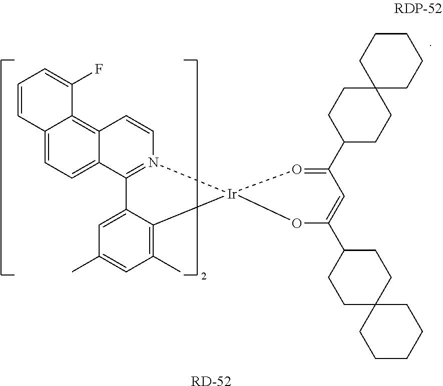

When the compound of general formula I of the present invention includes the structure of general formula RD-1, the compound of general formula I is preferably selected from the compounds represented by RDP-1 to RDP-24 and RDP-52; when the compound of general formula I of the present invention includes the structure of general formula RD-2, the compound of general formula I is preferably selected from the compounds represented by RDP-50 and RDP-51; when the compound of general formula I of the present invention includes the structure of general formula RD-3, the compound of general formula I is preferably selected from the compounds represented by RDP-25 to RDP-49; when the above compounds are used as red-light dopant material of the organic light-emitting device, the luminous efficiency can be improved while the thermal stability becomes better, such that the service life of the organic light-emitting device can be further improved.

The present invention further provides a method for preparing the iridium complex of above general formula I, the method specifically includes the following steps:
(1) reacting precursor substance with Iridium III to prepare a dimeric substance;
(2) reacting the dimeric substance with auxiliary ligand molecule and potassium carbonate or sodium carbonate in a solvent under stirring to obtain the compound of general formula I;
wherein the precursor substance is represented by the following structural formula:

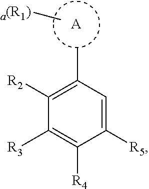

wherein the dimeric substance is represented by the following structural formula:

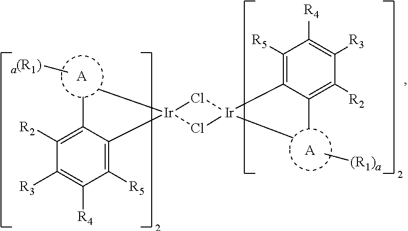

wherein the auxiliary ligand molecule is represented by the following structural formula:

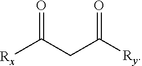

The present invention further provides an organic light-emitting device comprising the iridium complex represented by general formula I, the organic light-emitting device comprises an anode, a cathode and an organic layer; the organic layer at least includes a luminescent layer, the luminescent layer includes any one of the iridium complex represented by general formula I of the present invention, the iridium complex of general formula I is doped in the material of the luminescent layer as red-light dopant material.

In some embodiments of the present invention, the organic light-emitting device emits visible red light.

In some embodiments of the present invention, the organic layer further comprises at least one of the followings: a hole injection layer, a hole transport layer, a hole blocking layer, an electron injection layer, or an electron transport layer.

In some embodiments of the present invention, the organic layer is prepared by any one of the following methods: vacuum evaporation, molecular beam evaporation, solvent-based dip coating, spin coating, bar coating or ink-jet printing.

In some embodiments of the present invention, the anode and cathode are prepared by evaporation or sputtering method.

In some embodiments of the present invention, the organic light-emitting device can be used to prepare display or luminescent lighting sources.

Benefit effects: in the iridium complex having a structure as represented by general formula I as provided in the present invention, the structure of ring A includes more conjugated structures, which can improve color saturation, and the luminous efficiency of the device. The further combination of the auxiliary ligand and saturated aliphatic ring can further improve the thermal stability of the iridium complex, thereby improving the stability of the device and further improving the service life of the device.

### DETAILED DESCRIPTION OF THE EMBODIMENTS

The various technical features of the embodiments described below can be combined arbitrarily. To make the description concise, not all possible combinations of each technical feature in the above embodiments are described. However, as long as there is no contradiction in the combination of these technical features, they should be considered within the scope of the present description.

The following embodiments only express several embodiments of the present invention, facilitating a specific and detailed understanding of the technical solution of the present invention, but cannot be understood as a limitation on the protection scope of the invention patent. It should be pointed out that for those of ordinary skill in the art, several deformations and improvements can be made without departing from the concept of the present invention, all of which fall within the protection scope of the present invention. It should be understood that the technical solutions obtained by those skilled in the art through logical analysis, reasoning, or limited experiments based on the technical solutions provided by the present invention are within the protection scope of the claims attached to the present invention. Therefore, the protection scope of the present invention patent should be based on the content of the attached claims, and the description and accompanying drawings can be used to explain the content of the claims.

Preparation of Complex

1. Compound 1: RDP-1

Step 1: Synthesis of auxiliary ligand RP-13

To a single-mouth flask was added DMF (650 mL), then potassium tert-butanate (222.29 g) in a portion wise manner under stirring. The reaction mass was heated to 60° C., and then IP-1 (100.00 g) was added dropwise under N₂ protection, after completion of the dropwise addition, stirring was continued for 20 minutes. Then IP-2 (169.02 g) was added dropwise, after completion of the dropwise addition of IP-2, stirring was continued at 60° C. for 30 minutes and the heating was stopped. It was extracted and washed several times with water and n-hexane, the organic phase was collected and distilled to remove solvent. The organic phase was separated by column chromatography to afford a white solid (169.38 g, yield: 90.44%).

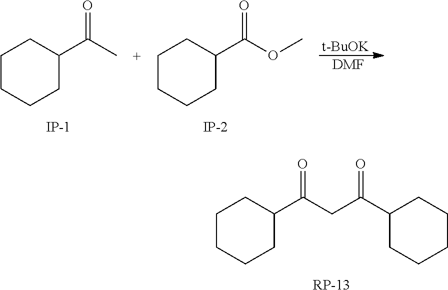

Step 2: Synthesis of intermediate IP-3

To a flask was added 2-chloro-4-iodopyridine-3-carboxaldehyde (13.00 g), 2-fluorophenylboronic acid (7.48 g) and sodium bicarbonate (8.17 g), then toluene (100 mL), ethanol (50 mL) and water (50 mL). The reaction mass was degassed with nitrogen, and added Pd(PPh₃)₄ (50 mg), and then heated to reflux, and stirred for 4 h. After completion of the reaction, the reaction was extracted with water and EtOAc. The organic phase was collected and separated by column chromatography to afford a white solid (10.92 g, yield: 95.34%).

Step 3: Synthesis of intermediate IP-4

To a flask was added (methoxymethyl)triphenylphodphonium chloride (17.46 g) and toluene (150 mL), then added potassium tert-butoxide (6.67 g) in an ice bath in a portion wise manner. After completion of the addition, stirring was continued for 1 h in the ice bath. Then a solution of intermediate IP-3 (10.00 g) in toluene (50 mL) was added dropwise. After completion of the dropwise addition, the ice bath was removed and stirring was continued for 2 h. After completion of the reaction, the reaction was quenched by addition of water and then extracted with water and EtOAc for several times. The organic phase was collected and separated by column chromatography to afford a white solid (8.41 g, yield: 75.15%).

Step 4: Synthesis of intermediate IP-5

To a flask was added intermediate IP-4 (8.00 g) and dichloromethane (80 mL). The reaction mass was degassed with nitrogen and methanesulfonic acid (23.32 g) was added dropwise under stirring. After completion of the dropwise addition, stirring was continued at room temperature for 2 h. After completion of the reaction, the reaction was quenched by addition of water and extracted with dichloromethane and water. The organic phase was collected and separated by column chromatography to afford a white solid (6.30 g, yield: 89.64%).

Step 5: Synthesis of ligand RD-1-1

To a flask was added intermediate IP-5 (6.00 g) and 3,5-dimethylphenylboronic acid (4.66 g), then toluene (50 mL), ethanol (25 mL) and water (25 mL). The reaction mass was degassed with nitrogen and stirred, to which then was added X-PHOS (200 mg) and Pd(OAc)₂ (50 mg), and heated to reflux for 2 h. When completion of the reaction was detected, the heating was stopped and the reaction was extracted with water and EtOAc. The organic phase was collected, separated by column chromatography, and then recrystallized with ethanol to afford a white solid (6.91 g, yield: 88.53%).

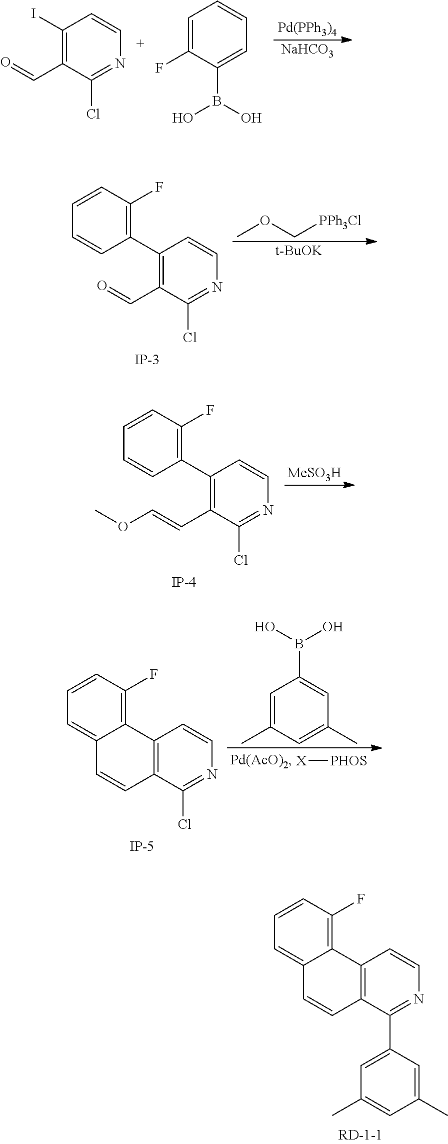

Step 6: Synthesis of Complex RDP-1

To a flask was added ligand RD-1-1 (2.05 g) and Iridium (III) chloride trihydrate (1.00 g), then 2-ethoxyethanol (30 mL) and water (10 mL). The reaction mass was degassed with nitrogen and then stirred and heated to reflux. The heating was stopped after 24 h of reaction. The reaction liquid was cooled to room temperature and filtered. The filter cake was washed with water, ethanol and MTBE for 3 times respectively, and collected. The filter cake was RD-1-1a. To a flask was added the collected filter cake and then potassium carbonate (1.96 g) and ligand RP-13 (5.36 g), and the mixture was dissolved in 30 mL dichloromethane and stirred under N₂ protection for 18 h. When completion of the reaction was detected, the reaction was stopped. The reaction was separated by column chromatography, and triturated with ethanol and n-hexane to afford a red solid (2.55 g).

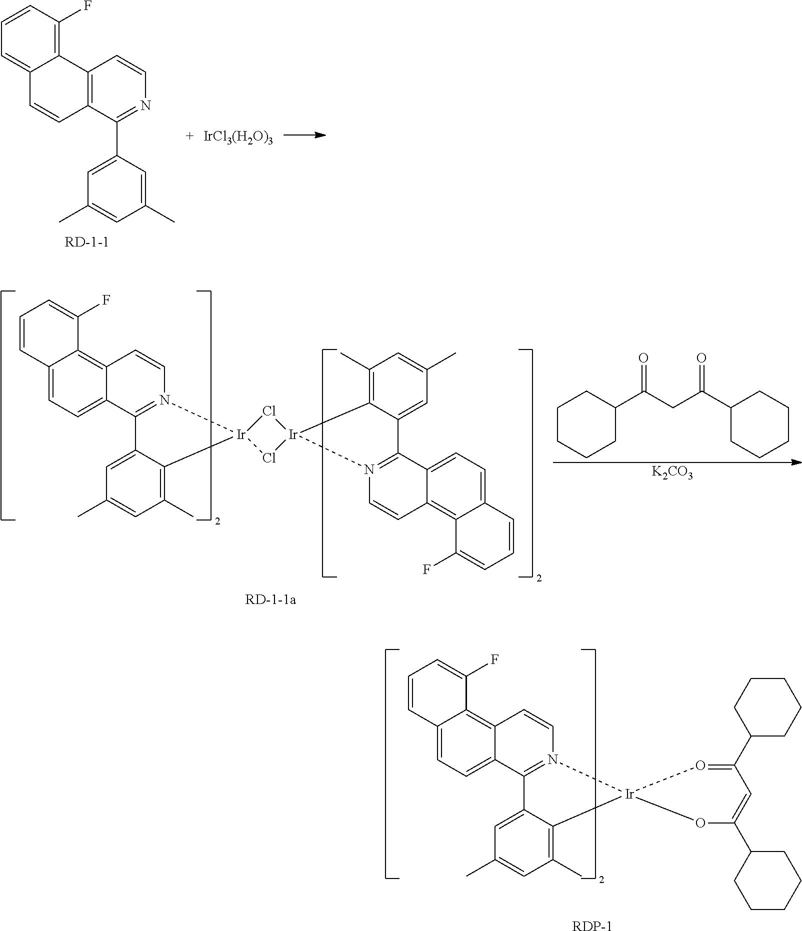

¹H NMR of Compound 1:

¹H NMR (400 MHz, chloroform-d) δ8.81 (d, J=9.8 Hz, 2H), 8.66-8.58 (m, 2H), 7.90 (d, J=8.9 Hz, 2H), 7.80-7.72 (m, 5H), 7.54-7.42 (m, 5H), 7.26 (dd, J=7.8, 1.1 Hz, 2H), 6.91-6.81 (m, 5H), 5.94 (s, 1H), 2.72 (p, J=8.3 Hz, 1H), 2.57-2.36 (m, 15H), 1.85-1.58 (m, 7H), 1.62-1.47 (m, 6H), 1.45 (dddd, J=9.8, 8.4, 4.7, 2.7 Hz, 1H).

2. Compound 2: Synthesis of RDP-7

Step 1: Synthesis of auxiliary ligand RP-13

RP-13 was synthesized according to the same method as step 1 in the synthesis of Compound 1.

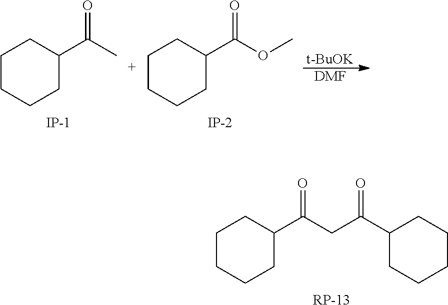

RD-1-2 was synthesized according to the same method as steps 2-5 (except that 2-fluorophenylboronic acid in step 2 was replaced with 4-fluorophenylboronic acid) in the synthesis of Compound 1, resulting in a white solid (5.28 g).

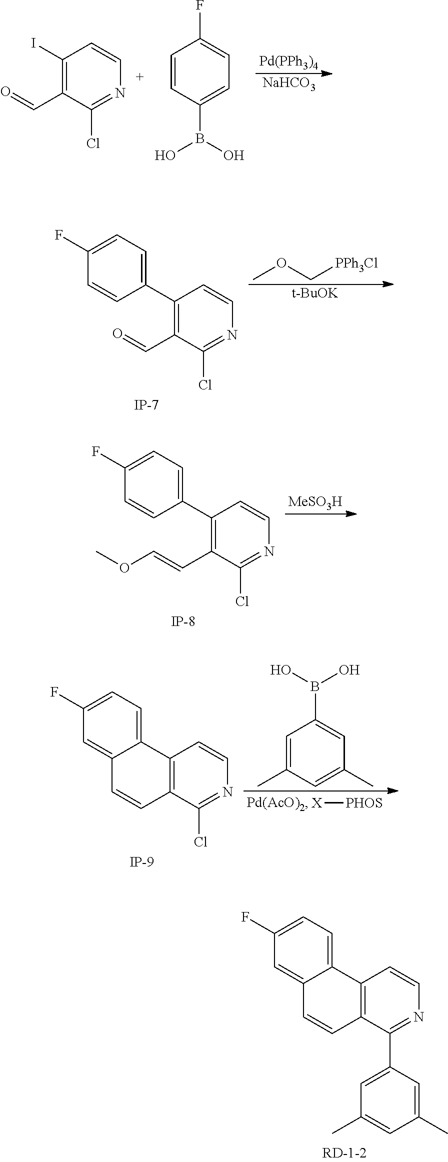

Step 6: Synthesis of Complex RDP-7

RDP-7 was synthesized according to the same method as step 6 (except that ligand RD-1-1 was replaced with ligand RD-1-2) in the synthesis of Compound 1, resulting in a red solid (2.31 g).

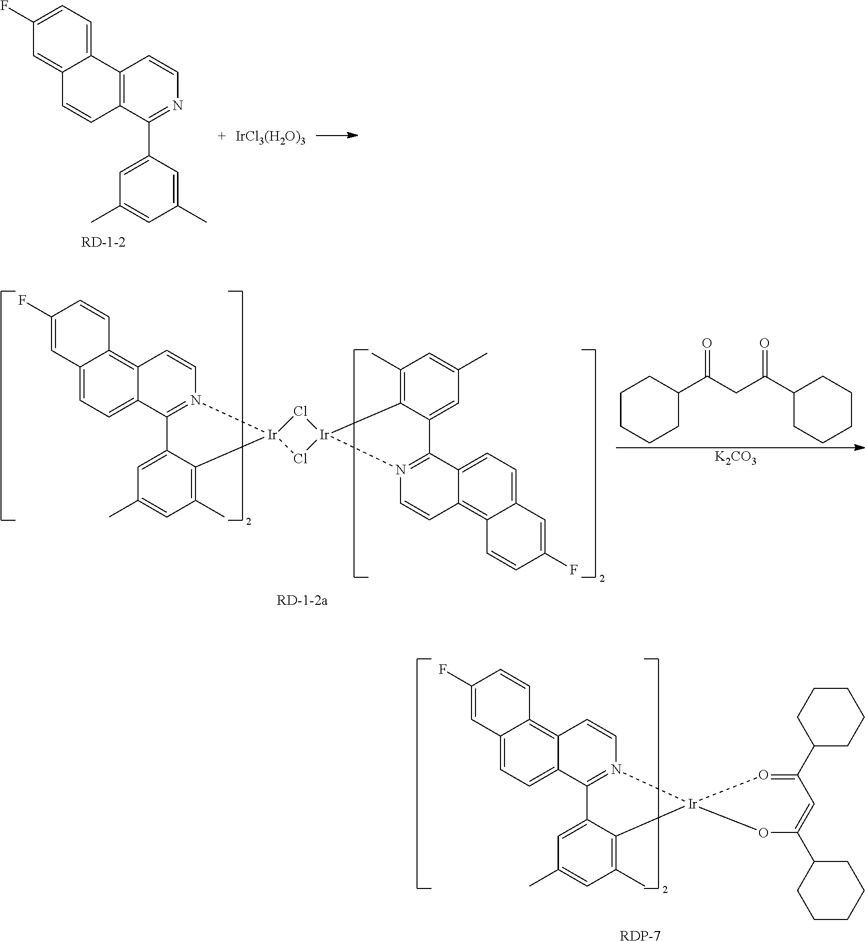

¹H NMR of Compound 2:

¹H NMR (400 MHz, Chloroform-d) δ8.81 (d, J=9.8 Hz, 2H), 8.61 (d, J=9.6 Hz, 2H), 8.36 (dd, J=9.2, 0.7 Hz, 2H), 7.99-7.88 (m, 5H), 7.50 (d, J=8.9 Hz, 2H), 7.26 (dd, J=9.1, 2.8 Hz, 2H), 6.87 (dd, J=2.2, 1.0 Hz, 2H), 6.83 (d, J=2.2 Hz, 2H), 5.94 (s, 1H), 2.72 (p, J=8.3 Hz, 1H), 2.51 (p, J=7.6 Hz, 1H), 2.42-2.35 (m, 15H), 1.85-1.40 (m, 14H).

3. Compound 3: Synthesis of RDP-19

Step 1: Synthesis of auxiliary ligand RP-13

RP-13 was synthesized according to the same method as step 1 in the synthesis of Compound 1.

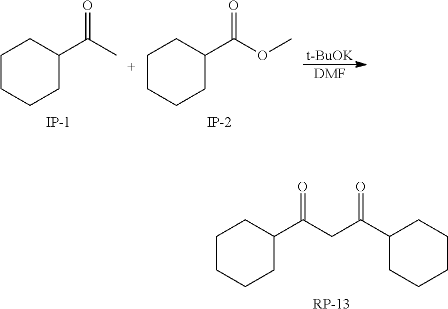

Step 2: Synthesis of intermediate 1P-10

To a flask was added 2-chloro-4-iodopyridine-3-carboxaldehyde (13.00 g), 3,4-difluorophenylboronic acid (8.44 g) and sodium bicarbonate (8.17 g), then toluene (100 mL), ethanol (50 mL) and water (50 mL). The reaction mass was degassed with nitrogen and then added Pd(PPh₃)₄ (50 mg), and then heated to reflux, and stirred for 4 h. After completion of the reaction, the reaction was extracted with water and EtOAc. The organic phase was collected and separated by column chromatography to afford a white solid (11.17 g, yield: 90.60%).

Step 3: Synthesis of intermediate IP-11

To a flask was added (methoxymethyl)triphenylphodphonium chloride (17.03 g) and toluene (150 mL), then added potassium tert-butoxide (6.50 g) in an ice bath in a portion wise manner. After completion of the addition, stirring was continued for 1 h in the ice bath. Then a solution of intermediate IP-10 (10.50 g) in toluene (50 mL) was added dropwise. After completion of the dropwise addition, the ice bath was removed and stirring was continued for 2 h. After completion of the reaction, the reaction was quenched by addition of water and then extracted with water and EtOAc for several times. The organic phase was collected and separated by column chromatography to afford a white solid (9.34 g, yield: 80.09%).

Step 4: Synthesis of intermediate IP-12

To a flask was added intermediate IP-11 (9.00 g) and dichloromethane (80 mL). The reaction mass was degassed with nitrogen and methanesulfonic acid (24.56 g) was added dropwise under stirring. After completion of the dropwise addition, stirring was continued at room temperature for 2 h. After completion of the reaction, the reaction was quenched by addition of water and extracted with dichloromethane and water. The organic phase was collected and separated by column chromatography to afford a white solid (7.21 g, yield: 90.27%).

Step 5: Synthesis of ligand RD-1-3

To a flask was added intermediate IP-12 (7.00 g) and 3,5-dimethylphenylboronic acid (5.05 g), then toluene (50 mL), ethanol (25 mL) and water (25 mL). The reaction mass was degassed with nitrogen and stirred, to which then was added X-PHOS (200 mg) and Pd(OAc)₂ (50 mg), and heated to reflux for 2 h. When completion of the reaction was detected, the heating was stopped and the reaction was extracted with water and EtOAc. The organic phase was collected, separated by column chromatography, and then recrystallized with ethanol to afford a white solid (7.99 g, yield: 89.23%).

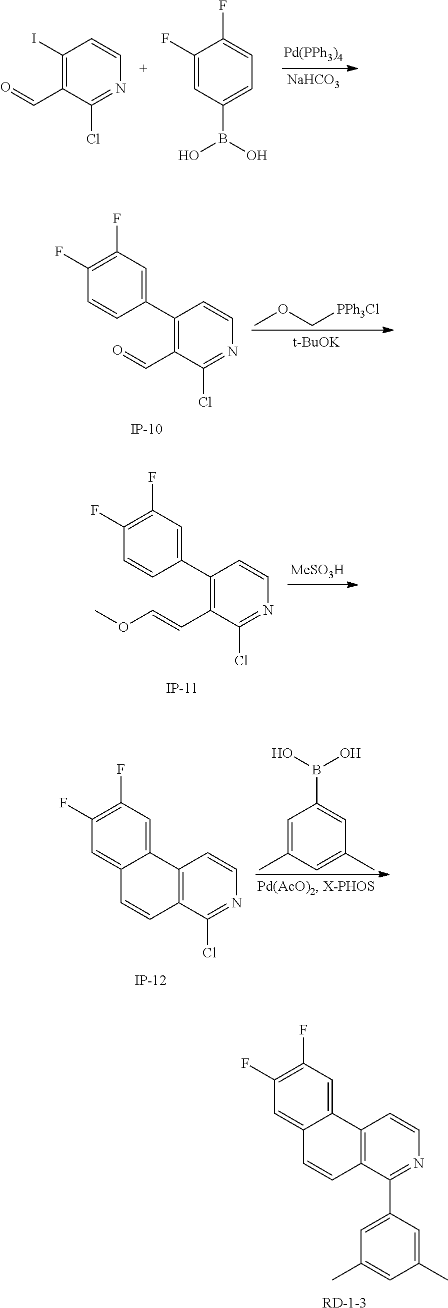

Step 6: Synthesis of Complex RDP-19

To a flask was added ligand RD-1-3 (2.17 g) and Iridium (III) chloride trihydrate (1.00 g), then 2-ethoxyethanol (30 mL) and water (10 mL). The reaction mass was degassed with nitrogen and then stirred and heated to reflux. The heating was stopped after 24 h of reaction. The reaction liquid was cooled to room temperature and filtered. The filter cake was washed with water, ethanol and MTBE for 3 times respectively, and collected. To a flask was added the collected filter cake and then potassium carbonate (1.96 g) and ligand RP-13 (5.36 g), and the mixture was dissolved in 30 mL dichloromethane and stirred under N₂ protection for 18 h. When completion of the reaction was detected, the reaction was stopped. The reaction was separated by column chromatography, and triturated with ethanol and n-hexane to afford a red solid (2.21 g).

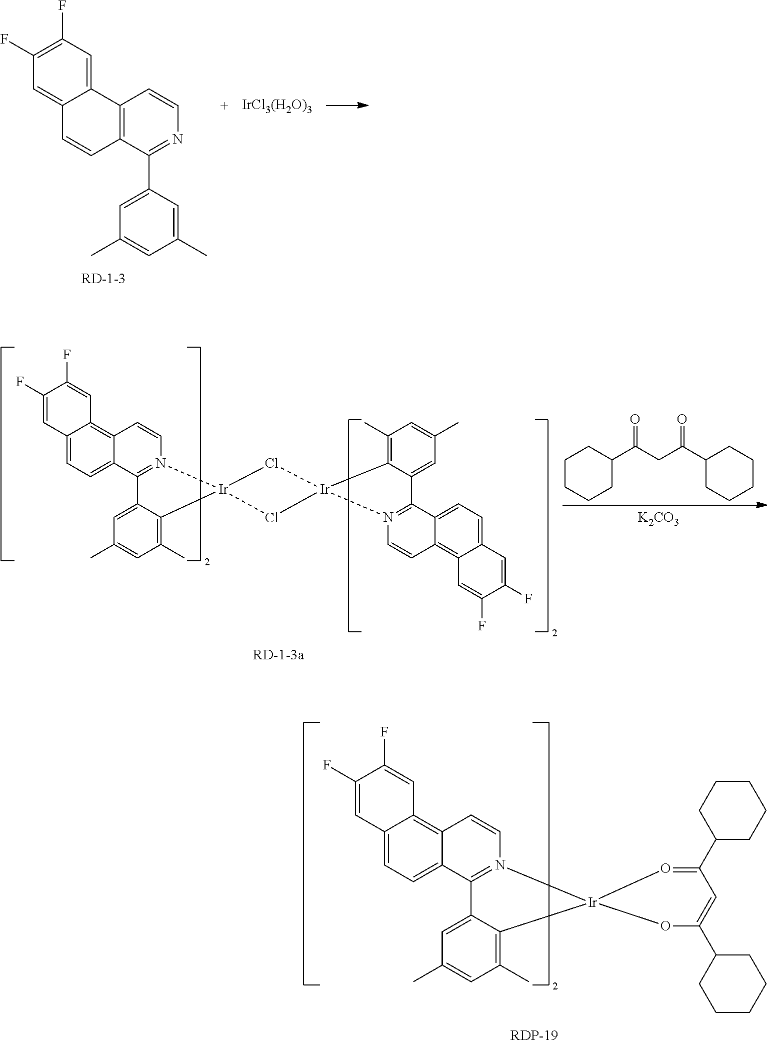

¹H NMR of Compound 3:

¹H NMR (400 MHz, Chloroform-d) δ8.84 (d, J=9.7 Hz, 2H), 8.69-8.60 (m, 2H), 8.01 (d, J=0.7 Hz, 2H), 7.93 (dd, J=8.9, 2.2 Hz, 2H), 7.90 (s, 2H), 7.75 (d, J=2.2 Hz, 2H), 7.54-7.46 (m, 2H), 6.87 (dd, J=2.1, 1.0 Hz, 2H), 6.83 (d, J=2.2 Hz, 2H), 5.94 (s, 1H), 2.72 (p, J=8.3 Hz, 1H), 2.57-2.36 (m, 14H), 1.85-1.39 (m, 15H).

4. Compound 4: Synthesis of RDP-28

Step 1: Synthesis of auxiliary ligand RP-13

RP-13 was synthesized according to the same method as step 1 in the synthesis of Compound 1.

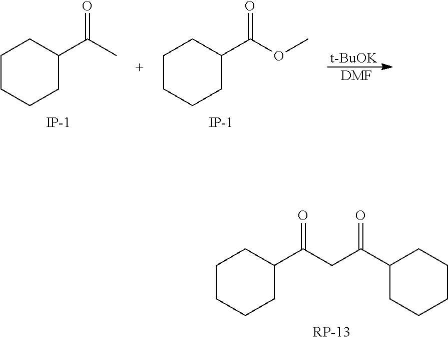

Step 2: Synthesis of intermediate IP-13

To a flask was added magnesium chips (11.34 g) and a grain of iodine. The reaction mass was degassed with nitrogen. Then a solution of 1-bromo-4-fluoronaphthalene (100.00 g) in THF (500 mL) was added dropwise in an ice bath under stifling. After completion of the dropwise addition, stirring was continued for 30 minutes in the ice bath. Then HPLC grade DMF (35.73 g) was quickly added dropwise at a controlled temperature of no more than 30° C. After completion of the dropwise addition, the ice bath was removed and stirring was continued at room temperature for 1 h. The reaction was quenched by addition of water and extracted with saturated sodium bicarbonate solution and EtOAc. The organic phase was collected and separated by column chromatography to afford a white solid (70.23 g, yield: 90.75%).

Step 3: Synthesis of intermediate IP-14

To a flask was added intermediate IP-13 (70.00 g) and aminoacetal (64.23 g). Then 5 mL concentrated HCl was added dropwise. The reaction mass was heated to 100° C. and stirred for 2 h. Then toluene was added, and the mixture was distilled repeatedly for at least 3 times. The solvent was drained to afford a brown solid, which was used directly in the next step without any treatment.

Step 4: Synthesis of intermediate IP-15

To the solid (IP-14) obtained in Step 3 was added trifluoroacetic anhydride (675.29 g). Then the reaction mass was stirred and heated to reflux, and after 12 h, the heating was stopped. To the resulted mixture was added n-hexane, and the reaction was separated by column chromatography to afford a white solid (53.81 g, yield: 67.89%).

Step 5: Synthesis of intermediate IP-16

To a flask was added intermediate IP-15 (52.00 g) and dichloromethane (400 mL). The reaction mass was degassed with nitrogen and 30% phosphorus oxychloride (161.71 g) was added dropwise under stirring in an ice bath, and then DMF (11.49 g) was added slowly in a dropwise manner. After completion of the dropwise addition, the ice bath was removed and stirring was continued at room temperature for 18 h. The reaction was extracted with saturated sodium bicarbonate solution and EtOAc. The organic phase was collected and separated by column chromatography to afford a white solid (16.80 g, yield: 27.50%).

Step 6: Synthesis of ligand RD-3-1

To a flask was added intermediate IP-16 (10.00 g) and 3,5-dimethylphenylboronic acid (7.12 g), then toluene (50 mL), ethanol (25 mL) and water (25 mL). The reaction mass was degassed with nitrogen and stirred, to which then was added X-PHOS (200 mg) and Pd(OAc)₂ (50 mg), and heated to reflux for 2 h. When completion of the reaction was detected, the heating was stopped and the reaction was extracted with water and EtOAc. The organic phase was collected, separated by column chromatography, and then recrystallized with ethanol to afford a white solid (11.93 g, yield: 91.70%).

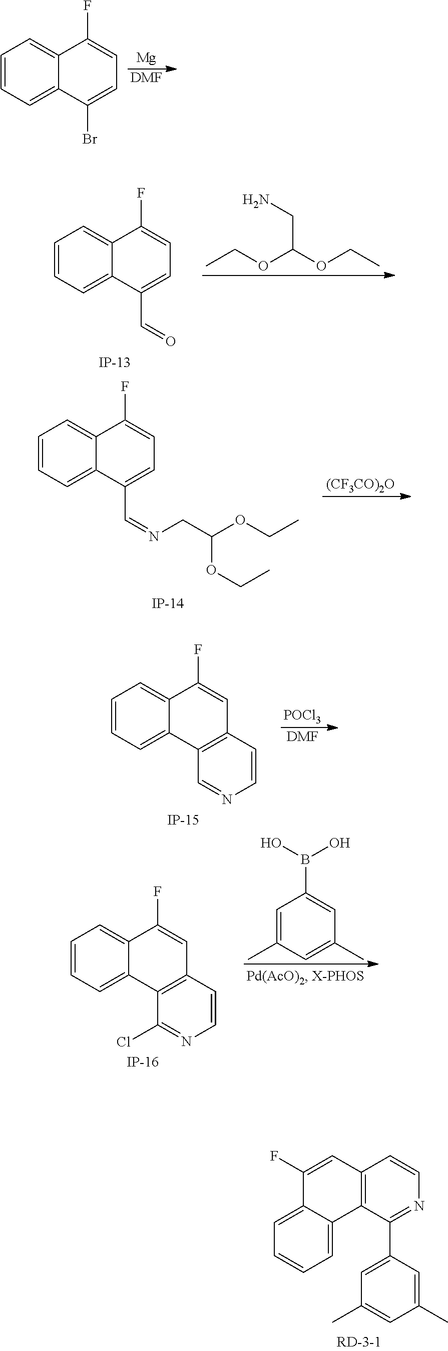

Step 7: Synthesis of Complex RDP-28

To a flask was added ligand RD-1-3 (2.17 g) and Iridium (III) chloride trihydrate (1.00 g), then 2-ethoxyethanol (30 mL) and water (10 mL). The reaction mass was degassed with nitrogen and then stirred and heated to reflux. The heating was stopped after 24 h of reaction. The reaction liquid was cooled to room temperature and filtered. The filter cake was washed with water, ethanol and MTBE for 3 times respectively, and collected. To a flask was added the collected filter cake and then potassium carbonate (1.96 g) and ligand RP-13 (5.36 g), and the mixture was dissolved in 30 mL dichloromethane and stirred under N₂ protection for 18 h. When completion of the reaction was detected, the reaction was stopped. The reaction was separated by column chromatography, and triturated with ethanol and n-hexane to afford a red solid (2.23 g).

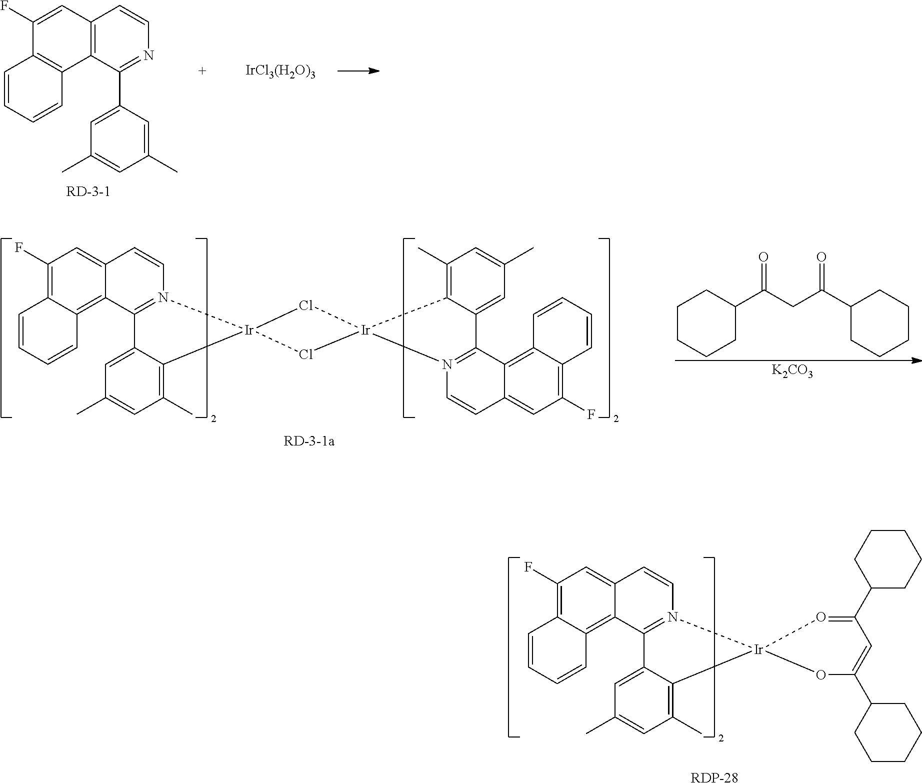

¹H NMR of Compound 4:

¹H NMR (400 MHz, Chloroform-d) δ8.75 (d, J=10.1 Hz, 2H), 8.35 (dd, J=7.2, 1.8 Hz, 2H), 7.95 (dd, J=7.6, 1.6 Hz, 2H), 7.87 (dd, J=10.2, 1.9 Hz, 2H), 7.70 (q, J=1.0 Hz, 2H), 7.59-7.44 (m, 5H), 6.89 (dd, J=2.2, 1.1 Hz, 2H), 6.83 (d, J=2.2 Hz, 2H), 5.94 (s, 1H), 2.72 (p, J=8.3 Hz, 1H), 2.51 (p, J=7.6 Hz, 1H), 2.39 (d, J=4.7 Hz, 13H), 1.85 — 1.38 (m, 16H).

5. Compound 5: Synthesis of RDP-42

Step 1: Synthesis of auxiliary ligand RP-13

RP-13 was synthesized according to the same method as step 1 in the synthesis of Compound 1.

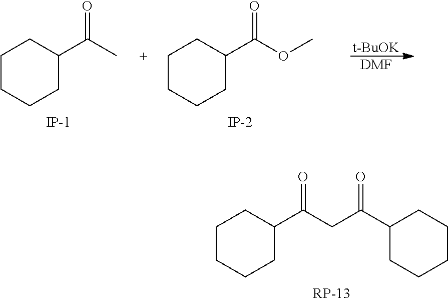

Step 2: Synthesis of intermediate IP-17

To a flask was added magnesium chips (9.55 g) and a grain of iodine. The reaction mass was degassed with nitrogen. Then a solution of 1-bromo-4-fluoro-6-isopropyl naphthalene (100.00 g) in THF (500 mL) was added dropwise in an ice bath under stifling. After completion of the dropwise addition, stirring was continued for 30 minutes in the ice bath. Then HPLC grade DMF (30.10 g) was quickly added dropwise at a controlled temperature of no more than 30° C. After completion of the dropwise addition, the ice bath was removed and stirring was continued at room temperature for 1 h. The reaction was quenched by addition of water and extracted with saturated sodium bicarbonate solution and EtOAc. The organic phase was collected and separated by column chromatography to afford a white solid (68.54 g, yield: 84.67%).

Step 3: Synthesis of intermediate IP-18

To a flask was added intermediate IP-17 (65.00 g) and aminoacetal (48.04 g). Then 5 mL concentrated HCl was added dropwise. The reaction mass was heated to 100° C. and stirred for 2 h. Then toluene was added, and the mixture was distilled repeatedly for at least 3 times. The solvent was drained to afford a brown solid, which was used directly in the next step without any treatment.

Step 4: Synthesis of intermediate IP-19

To the solid (IP-18) obtained in Step 3 was added trifluoroacetic anhydride (505.04 g). Then the reaction mass was stirred and heated to reflux, and after 12 h, the heating was stopped. To the resulted mixture was added n-hexane, and the reaction was separated by column chromatography to afford a white solid (42.99 g, yield: 72.52%).

Step 5: Synthesis of intermediate IP-20

To a flask was added intermediate IP-19 (40.00 g) and dichloromethane (400 mL). The reaction mass was degassed with nitrogen and 30% phosphorus oxychloride (161.71 g) was added dropwise under stirring in an ice bath, and then DMF (7.28 g) was added slowly in a dropwise manner. After completion of the dropwise addition, the ice bath was removed and stirring was continued at room temperature for 18 h. After completion of the reaction, the reaction was extracted with saturated sodium bicarbonate solution and EtOAc. The organic phase was collected and separated by column chromatography to afford a white solid (12.12 g, yield: 26.49%).

Step 6: Synthesis of ligand RD-3-2

To a flask was added intermediate IP-20 (10.00 g) and 3,5-dimethylphenylboronic acid (6.03 g), then toluene (50 mL), ethanol (25 mL) and water (25 mL). The reaction mass was degassed with nitrogen and stirred, to which then was added X-PHOS (200 mg) and Pd(OAc)₂ (50 mg), and heated to reflux for 2 h. When completion of the reaction was detected, the heating was stopped and the reaction was extracted with water and EtOAc. The organic phase was collected, separated by column chromatography, and then recrystallized with ethanol to afford a white solid (10.87 g, yield: 86.64%).

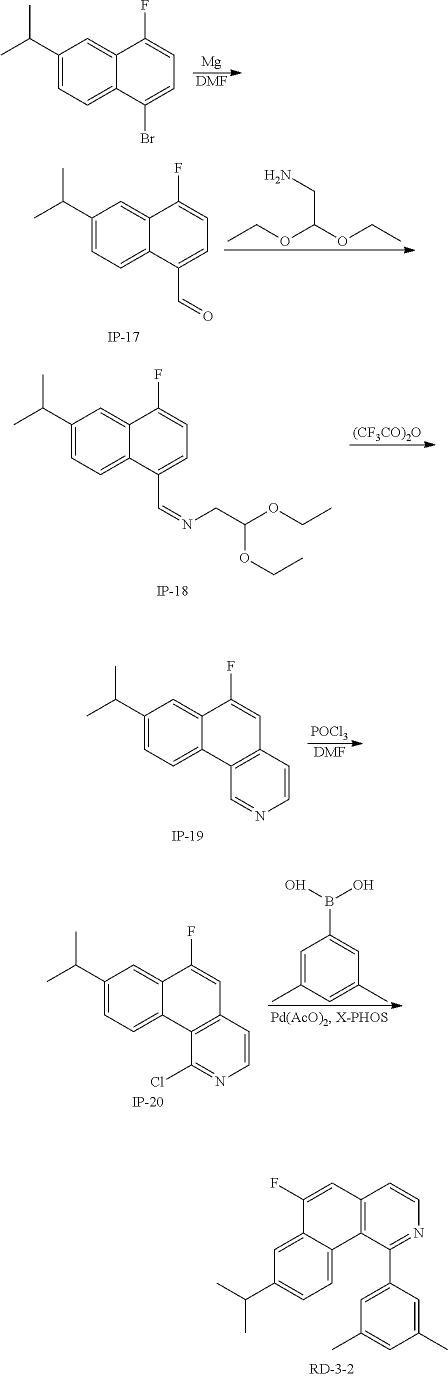

Step 7: Synthesis of Complex RDP-42

To a flask was added ligand RD-3-2 (2.34 g) and Iridium (III) chloride trihydrate (1.00 g), then 2-ethoxyethanol (30 mL) and water (10 mL). The reaction mass was degassed with nitrogen and then stirred and heated to reflux. The heating was stopped after 24 h of reaction. The reaction liquid was cooled to room temperature and filtered. The filter cake was washed with water, ethanol and MTBE for 3 times respectively, and collected. To a flask was added the collected filter cake and then potassium carbonate (1.96 g) and ligand RP-13 (5.36 g), and the mixture was dissolved in 30 mL dichloromethane and stirred under N2 protection for 18 h. When completion of the reaction was detected, the reaction was stopped. The reaction was separated by column chromatography, and triturated with ethanol and n-hexane to afford a red solid (2.06 g).

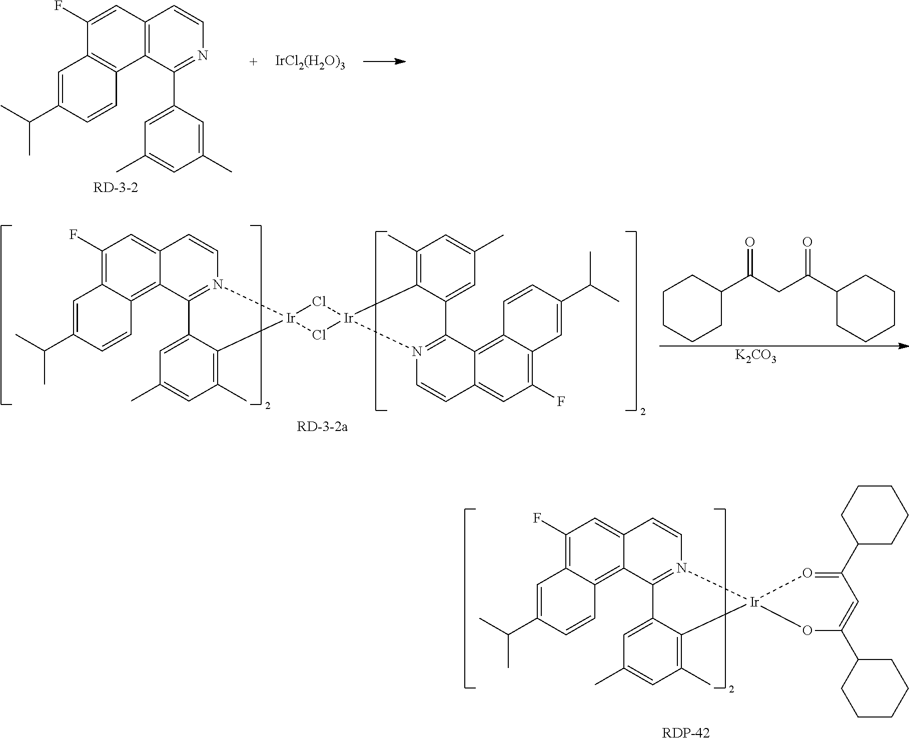

¹H NMR of Compound 5:

¹H NMR (400 MHz, Chloroform-d) δ8.75 (d, J=10.1 Hz, 2H), 8.06 (d, J=8.3 Hz, 2H), 7.88 (dd, J=10.1, 2.0 Hz, 2H), 7.71 (q, J=1.0 Hz, 2H), 7.49-7.43 (m, 2H), 7.31 (dd, J=8.4, 2.1 Hz, 2H), 6.89 (dd, J=2.2, 1.1 Hz, 2H), 6.83 (d, J=2.1 Hz, 2H), 5.94 (s, 1H), 3.01-2.89 (m, 2H), 2.72 (p, J =8.3 Hz, 1H), 2.51 (p, J=7.6 Hz, 1H), 2.39 (d, J=4.7 Hz, 13H), 1.85-1.39 (m, 17H), 1.27 (d, J=4.6 Hz, 14H).

6. Compound 6: Synthesis of RDP-21

Step 1: Synthesis of auxiliary ligand RP-13

RP-13 was synthesized according to the same method as step 1 in the synthesis of Compound 1.

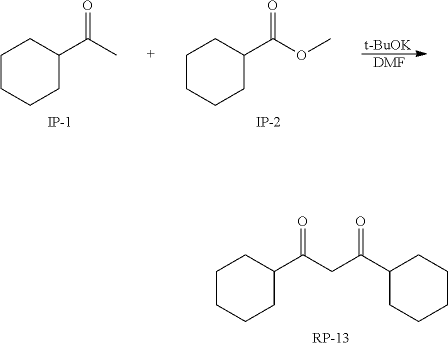

RD-1-4 was synthesized according to the same method as steps 2-5 (except that 3,4-difluorophenylboronic acid in step 2 was replaced with 2,4-difluorophenylboronic acid) in the synthesis of Compound 3, resulting in a white solid (6.32 g).

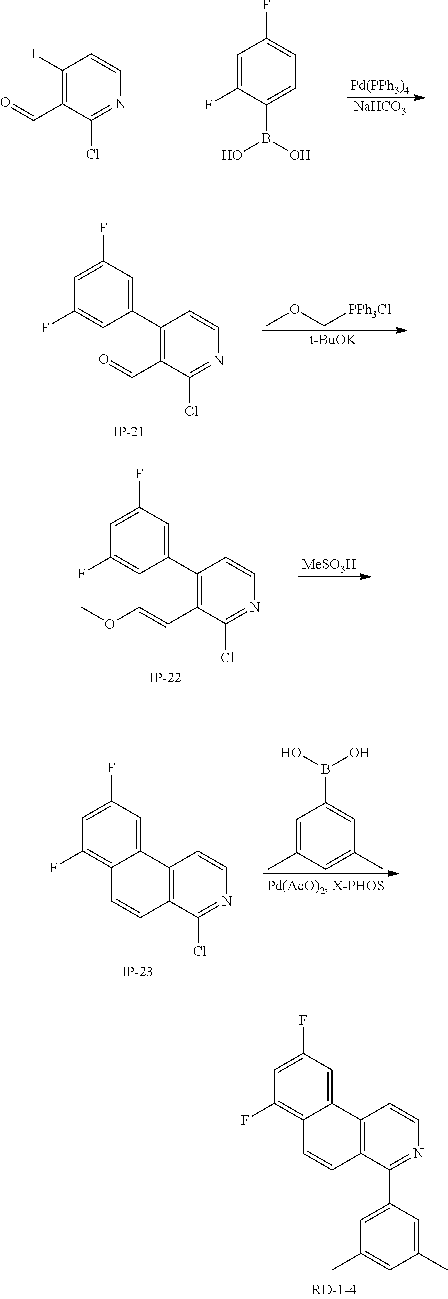

RDP-21 was synthesized according to the same method as step 6 in the synthesis of Compound 1, resulting in a red solid (2.38 g).

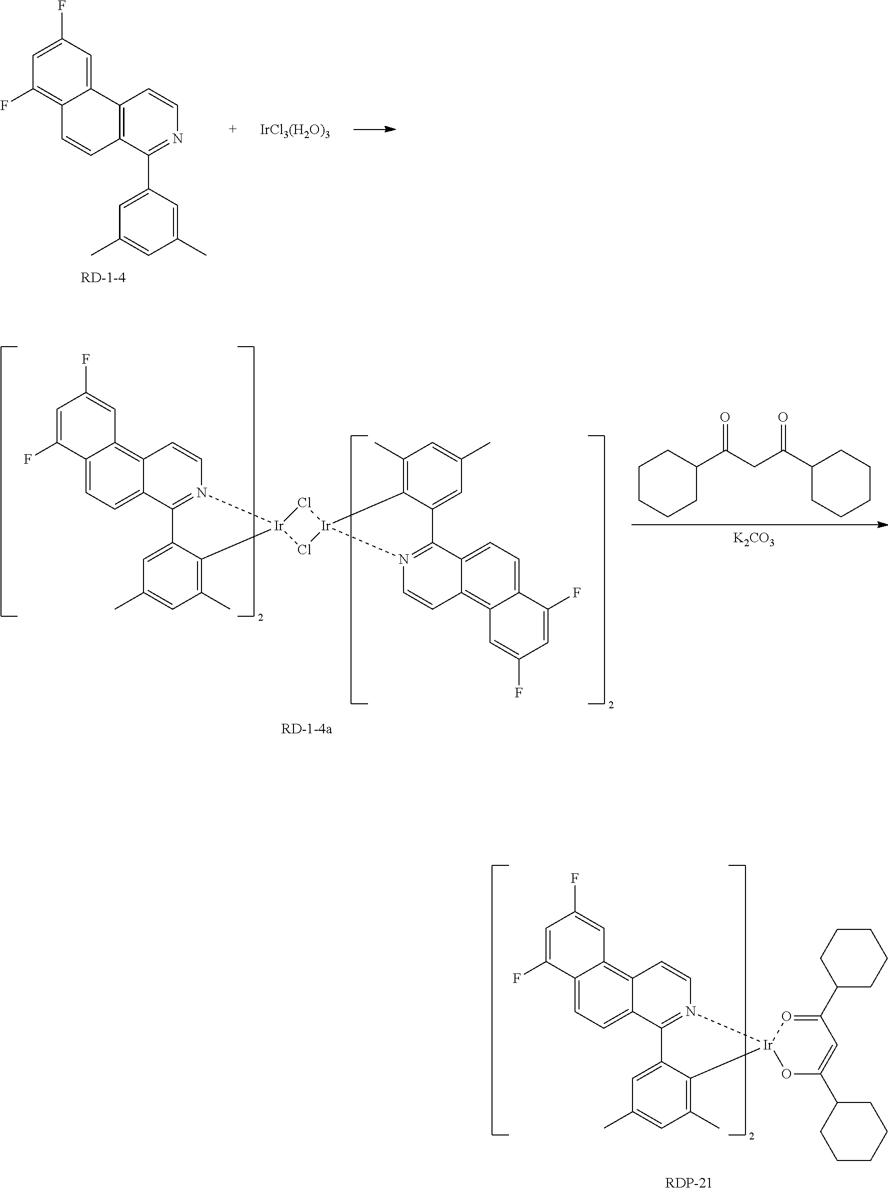

¹H NMR of Compound 6:

¹H NMR (400 MHz, Chloroform-d) δ8.83 (d, J=10.0 Hz, 2H), 8.60-8.52 (m, 2H), 7.69 (dd, J=9.1, 2.2 Hz, 2H), 7.57 (t, J=2.2 Hz, 2H), 7.50 (dd, J=9.1, 0.7 Hz, 2H), 7.14 (d, J=2.2 Hz, 2H), 6.91-6.81 (m, 5H), 5.94 (s, 1H), 2.72 (p, J=8.2 Hz, 1H), 2.51 (p, J=7.6 Hz, 1H), 2.42-2.35 (m, 15H), 1.85-1.36 (m, 14H).

7. Compound 7: Synthesis of RDP-46

Step 1: Synthesis of auxiliary ligand RP-13

RP-13 was synthesized according to the same method as step 1 in the synthesis of Compound 1.

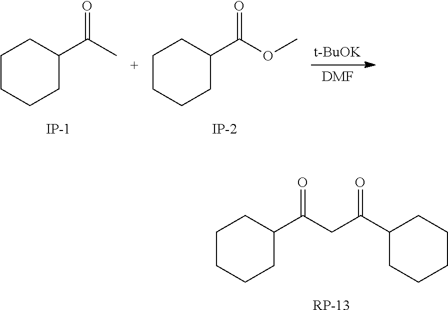

RD-1-5 was synthesized according to the same method as steps 2-5 (except that 2-fluorophenylboronic acid in step 2 was replaced with 4-aminophenylboronic acid) in the synthesis of Compound 1, resulting in a light yellow solid (3.28 g).

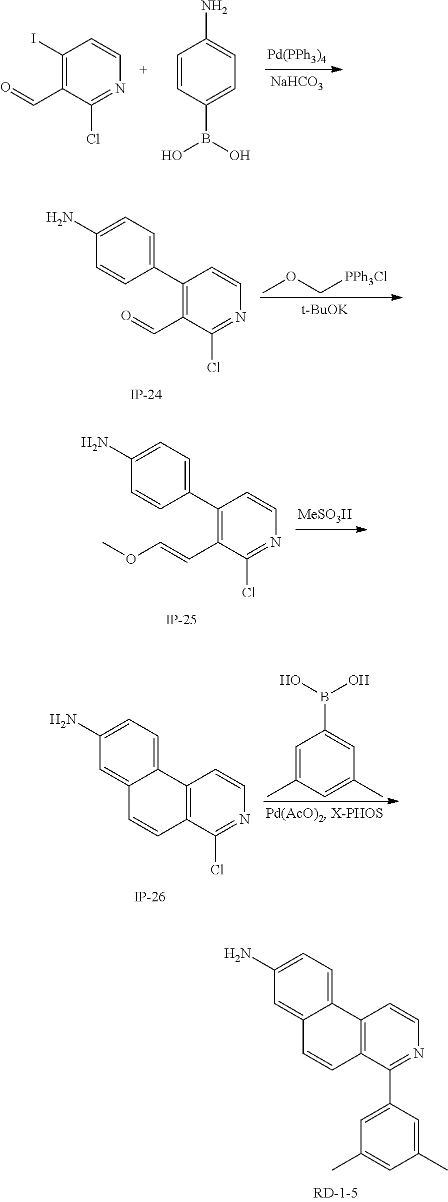

RDP-46 was synthesized according to the same method as step 6 in the synthesis of Compound 1, resulting in a red solid (0.83 g).

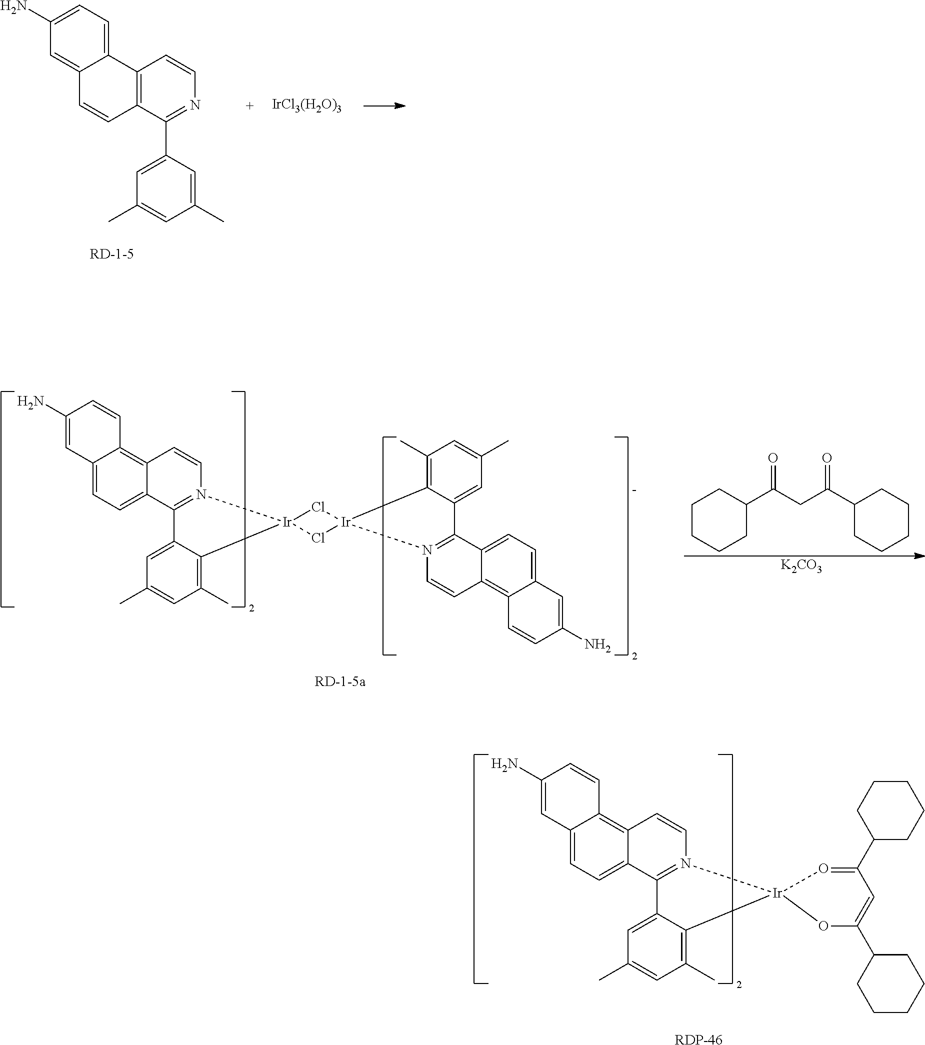

¹H NMR of Compound 7:

¹H NMR (400 MHz, Chloroform-d) δ8.81 (d, J=9.7 Hz, 2H), 8.53 (d, J=9.6 Hz, 2H), 8.00 (d, J=8.2 Hz, 2H), 7.68 (dd, J=8.9, 2.2 Hz, 2H), 7.43 (dd, J=8.9, 0.7 Hz, 2H), 7.11 (t, J=2.1 Hz, 2H), 7.00 (dd, J=8.2, 2.2 Hz, 2H), 6.87 (dd, J=2.2, 1.0 Hz, 2H), 6.83 (d, J =2.2 Hz, 2H), 5.94 (s, 1H), 4.83 (d, J=5.4 Hz, 2H), 4.72 (d, J=5.4 Hz, 2H), 2.72 (p, J =8.3 Hz, 1H), 2.51 (p, J=7.6 Hz, 1H), 2.42-2.35 (m, 14H), 1.85-1.71 (m, 2H), 1.76-1.54 (m, 4H), 1.53 (ddddd, J=8.7, 7.7, 5.9, 3.2, 1.5 Hz, 5H), 1.53-1.39 (m, 1H).

8. Compound 8: Synthesis of RDP-32

Step 1: Synthesis of auxiliary ligand RP-13

RP-13 was synthesized according to the same method as step 1 in the synthesis of Compound 1.

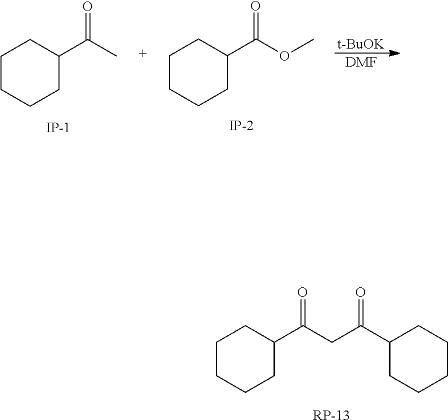

RD-3-3 was synthesized according to the same method as steps 2-6 (except that 1-bromo-4-fluoronaphthalene in step 2 was replaced with 1-bromo-5-(trifluoromethyl)naphthalene) in the synthesis of Compound 4, resulting in a white solid (10.90 g).

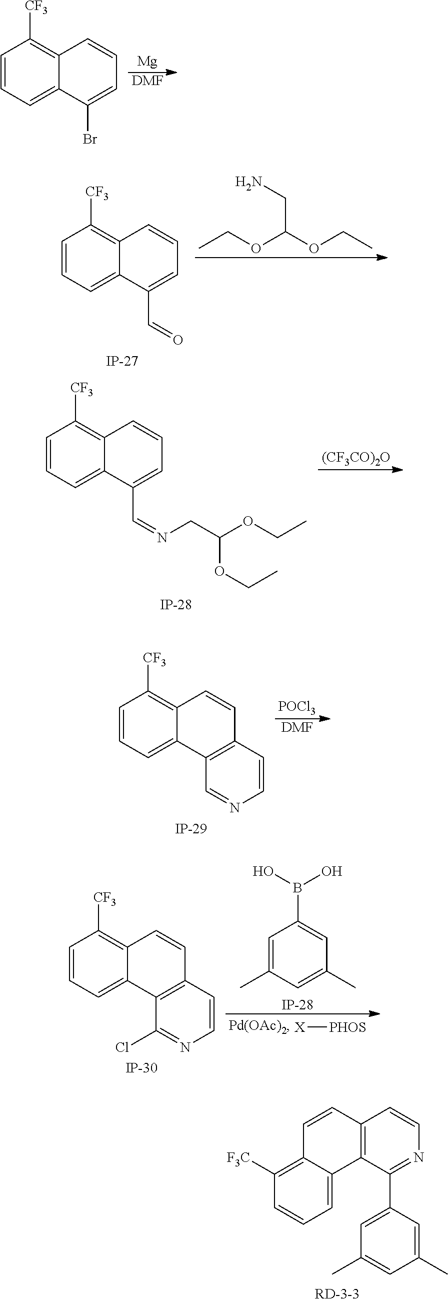

Iridium complex RDP-32 was synthesized according to the same method as step 6 in the synthesis of Compound 1, resulting in a red solid (2.71 g).

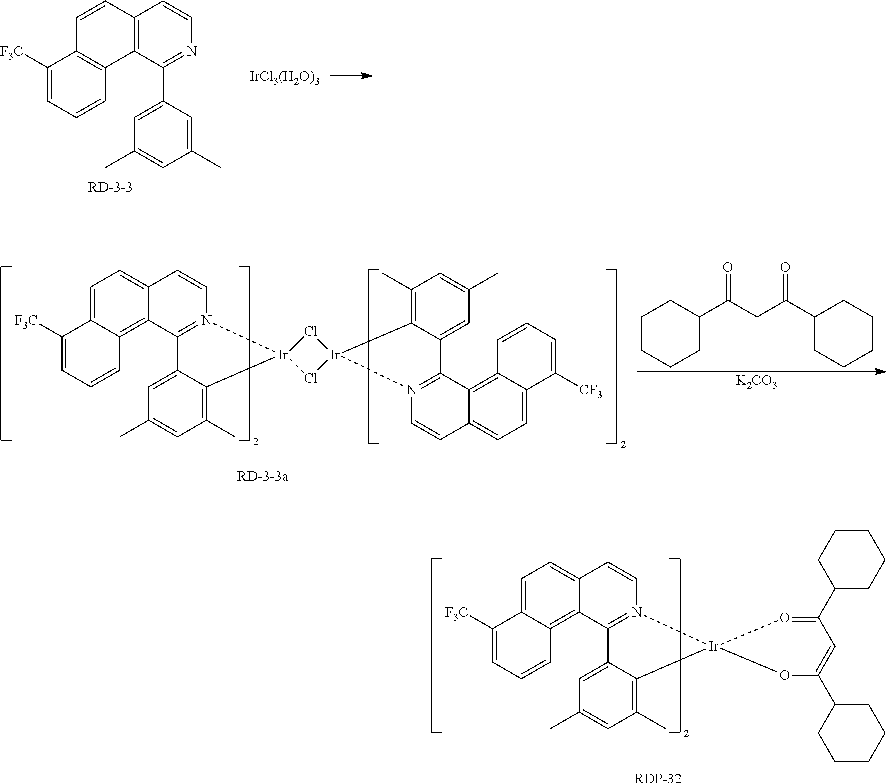

¹H NMR of Compound 8:

¹H H NMR (400 MHz, Chloroform-d) δ8.81-8.73 (m, 2H), 8.26-8.16 (m, 5H), 8.13-8.05 (m, 2H), 7.94-7.86 (m, 2H), 7.70 (dd, J=9.0, 1.5 Hz, 2H), 7.63 (dd, J=9.1, 6.9 Hz, 2H), 6.92-6.86 (m, 2H), 6.83 (d, J=2.2 Hz, 2H), 5.94 (s, 1H), 2.72 (p, J=8.2 Hz, 1H), 2.51 (p, J=7.6 Hz, 1H), 2.42-2.35 (m, 14H), 1.85-1.70 (m, 3H), 1.75-1.55 (m, 4H), 1.60-1.45 (m, 7H), 1.50-1.36 (m, 1H).

9. Compound 9: Synthesis of RDP-47

Step 1: Synthesis of auxiliary ligand RP-13

RP-13 was synthesized according to the same method as step 1 in the synthesis of Compound 1.

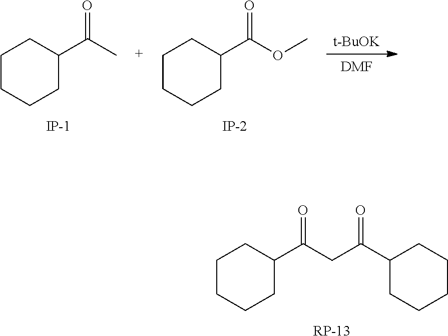

RD-3-4 was synthesized according to the same method as steps 2-6 (except that 1-bromo-4-fluoronaphthalene in step 2 was replaced with 1-bromo-5-methoxynaphthalene) in the synthesis of Compound 4, resulting in a white solid (11.05 g).

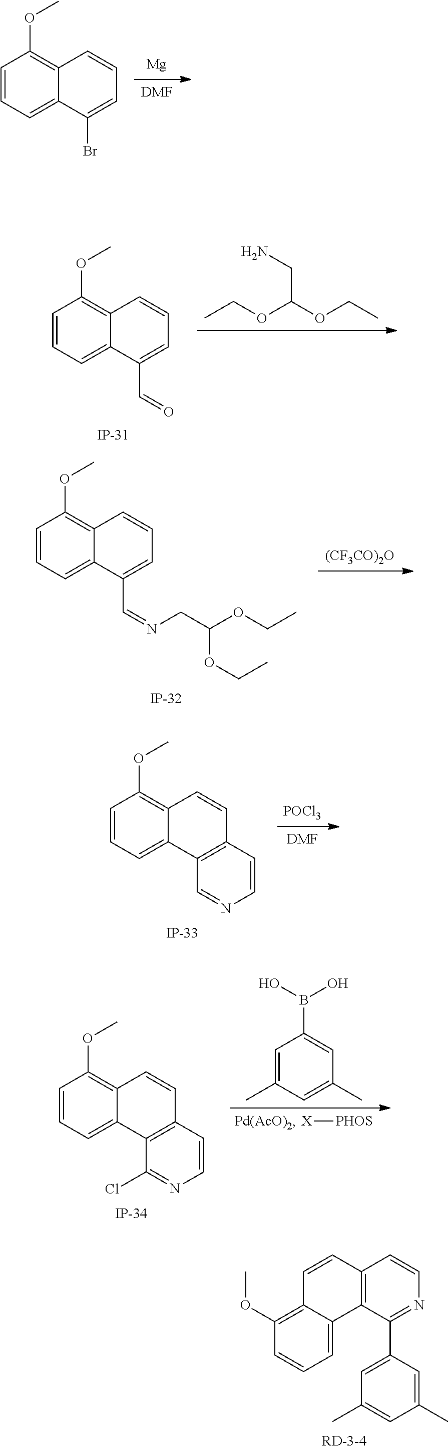

Iridium complex RDP-47 was synthesized according to the same method as step 6 in the synthesis of Compound 1, resulting in a red solid (2.04 g).

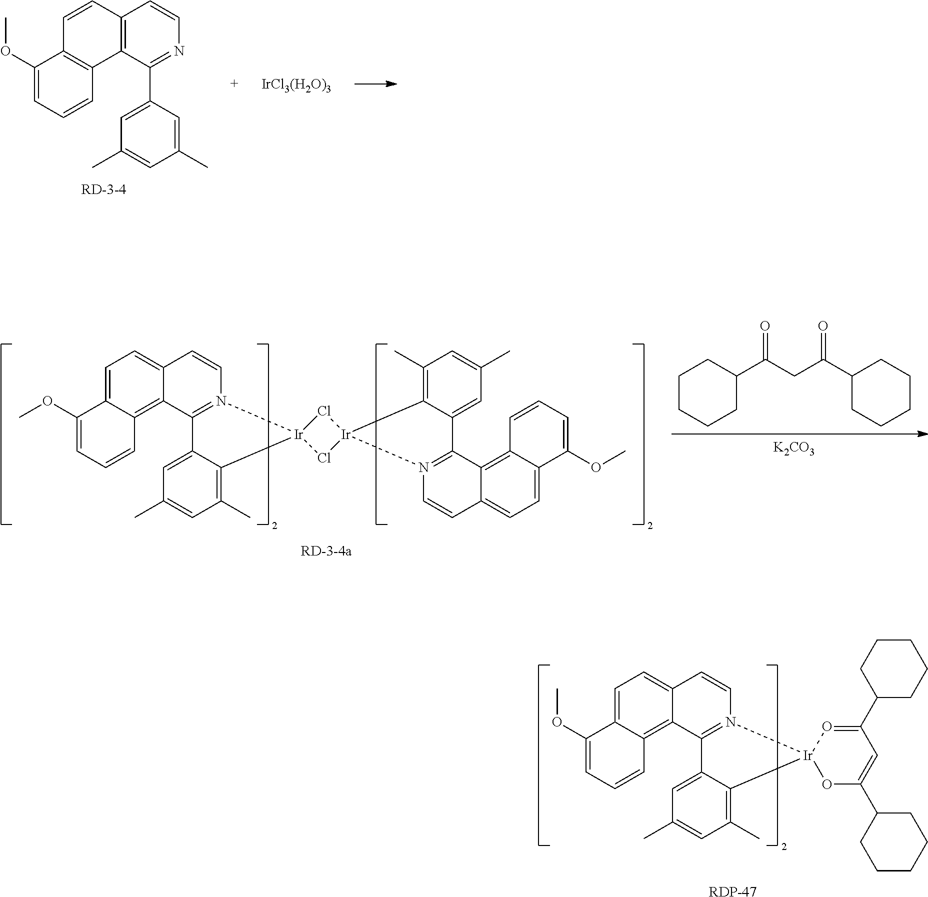

¹H NMR of Compound 9:

¹H NMR (400 MHz, Chloroform-d) δ8.77 (dd, J=10.0, 0.6 Hz, 2H), 8.21 (dd, J=8.0, 1.2 Hz, 2H), 8.16-8.08 (m, 2H), 8.08-8.00 (m, 2H), 7.83-7.76 (m, 2H), 7.40 (t, J=7.8 Hz, 2H), 7.02-6.95 (m, 2H), 6.92-6.85 (m, 2H), 6.83 (d, J=2.2 Hz, 2H), 5.94 (s, 1H), 3.90 (s, 6H), 2.71 (q, J=8.3 Hz, 1H), 2.50 (q, J=7.6 Hz, 1H), 2.42-2.35 (m, 14H), 1.85-1.64 (m, 5H), 1.66 (s, 0H), 1.68-1.60 (m, 1H), 1.64-1.55 (m, 1H), 1.60-1.49 (m, 6H), 1.54-1.48 (m, 1H), 1.53-1.36 (m, 1H).

10. Compound 10: Synthesis of RDP-48

Step 1: Synthesis of auxiliary ligand RP-13

RP-13 was synthesized according to the same method as step 1 in the synthesis of Compound 1.

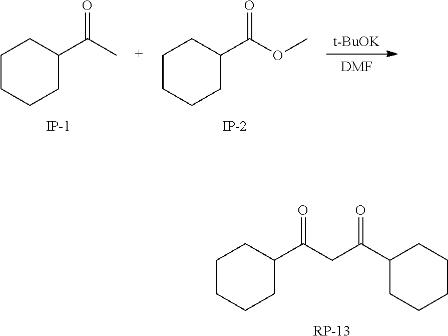

RD-3-5 was synthesized according to the same method as steps 2-6 (except that 1-bromo-4-fluoro-6-isopropyl naphthalene in step 2 was replaced with 1-bromo-6-isopropyl-7-fluoro naphthalene) in the synthesis of Compound 5, resulting in a white solid (11.74 g).

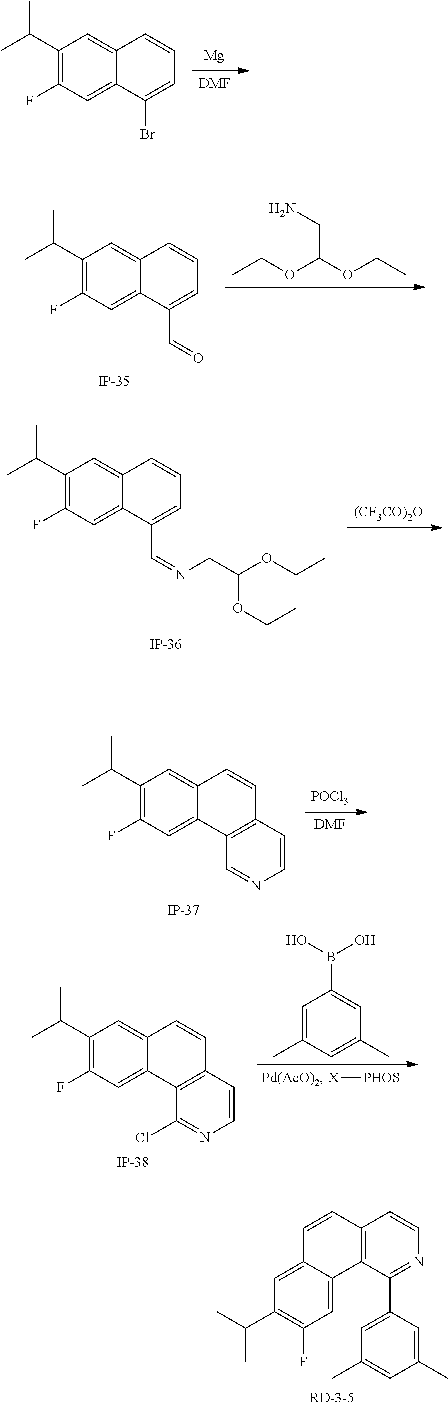

Iridium complex RDP-48 was synthesized according to the same method as step 6 in the synthesis of Compound 1, resulting in a red solid (2.82 g).

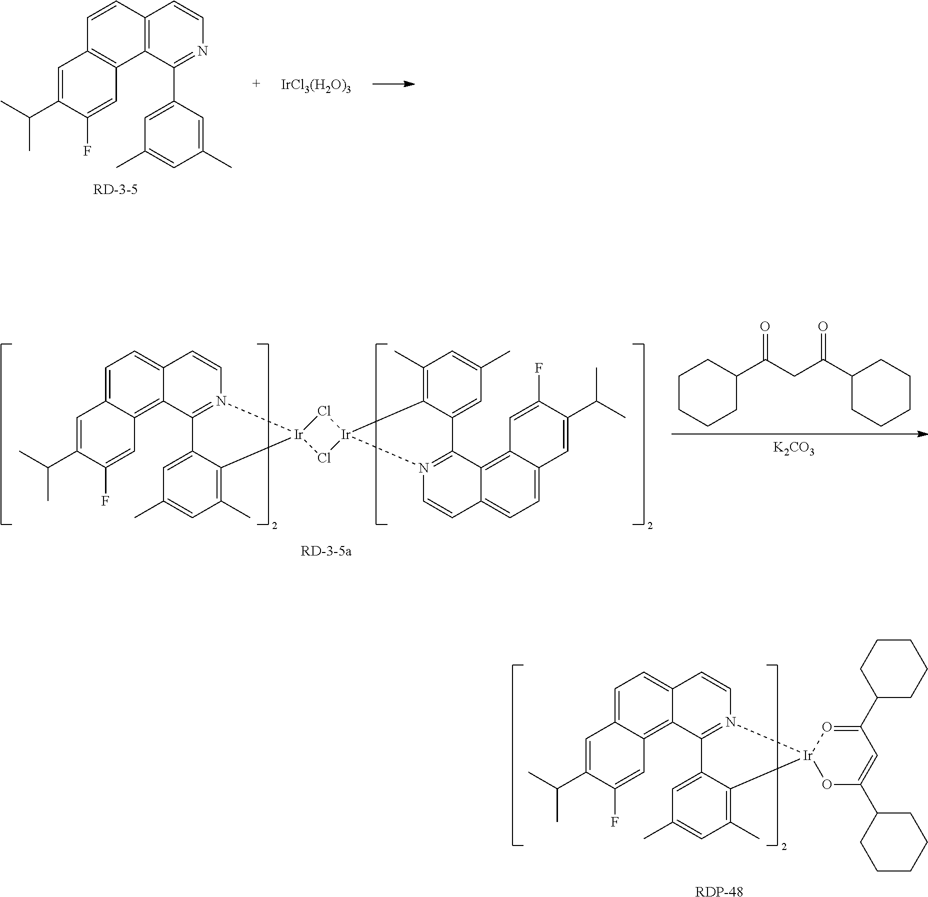

¹H NMR of Compound 10:

¹H NMR (400 MHz, Chloroform-d) δ8.77 (d, J=10.0 Hz, 2H), 8.28-8.20 (m, 2H), 8.09 (s, 2H), 7.88-7.76 (m, 5H), 7.42-7.35 (m, 2H), 6.92-6.85 (m, 2H), 6.83 (d, J=2.3 Hz, 2H), 5.94 (s, 1H), 3.40 (heptd, J=4.5, 0.7 Hz, 2H), 2.71 (q, J=8.3 Hz, 1H), 2.50 (q, J=7.6 Hz, 1H), 2.42-2.35 (m, 13H), 1.85-1.40 (m, 15H), 1.33 (d, J=4.5 Hz, 14H).

11. Compound 11: Synthesis of RDP-49

Step 1: Synthesis of auxiliary ligand RP-13

RP-13 was synthesized according to the same method as step 1 in the synthesis of Compound 1.

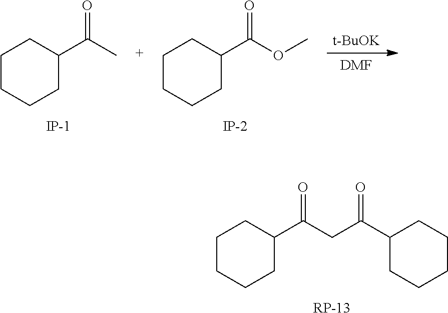

RD-3-6 was synthesized according to the same method as steps 2-6 (except that 1-bromo-6-isopropyl-7-fluoro naphthalene in step 2 was replaced with 1-bromo-6-isopropyl-7-methyl naphthalene) in the synthesis of Compound 10, resulting in a white solid (10.36 g).

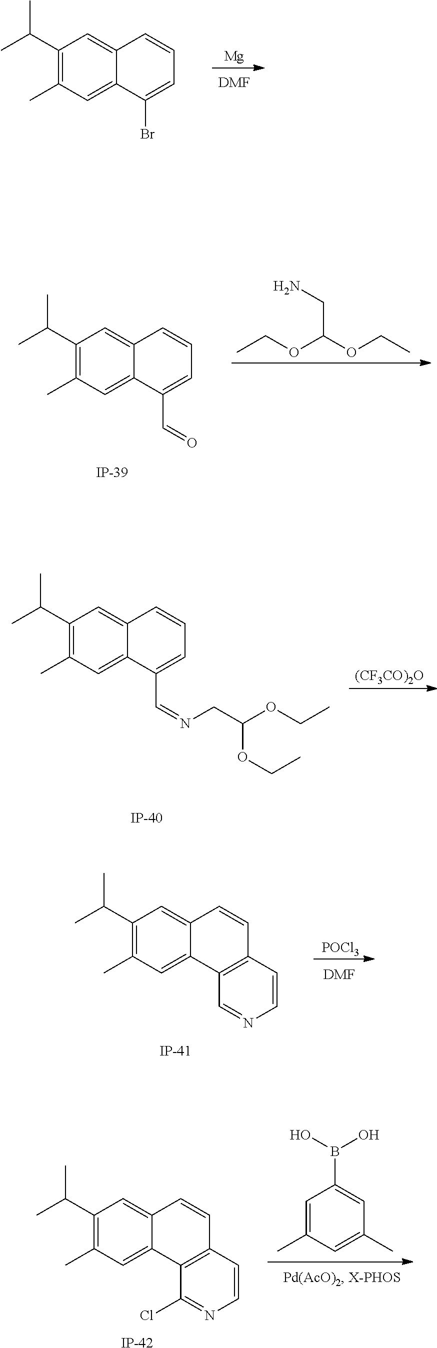

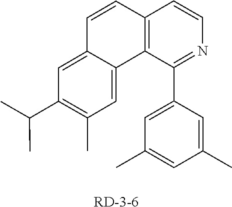

Iridium complex RDP-49 was synthesized according to the same method as step 6 in the synthesis of Compound 1, resulting in a red solid (2.67 g).

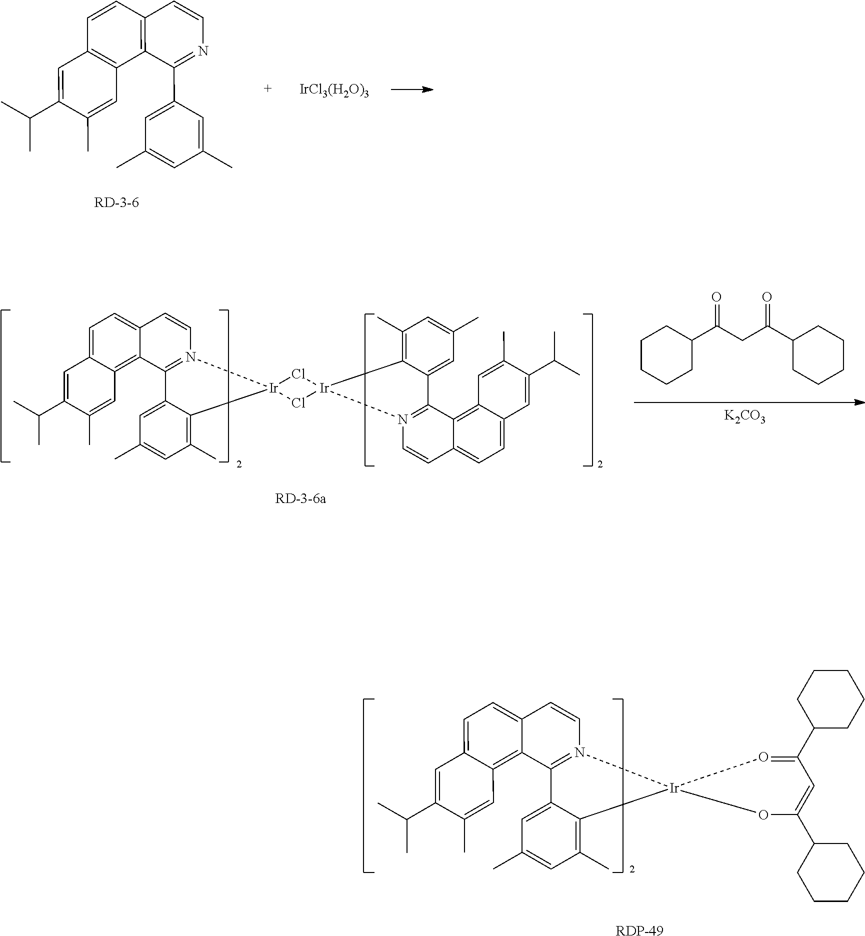

¹H NMR of Compound 11:

¹H NMR (400 MHz, Chloroform-d) δ8.81-8.73 (m, 2H), 8.17 (d, J=1.0 Hz, 2H), 8.14-8.06 (m, 2H), 7.81-7.72 (m, 2H), 7.70-7.62 (m, 2H), 7.27 (dd, J=2.2, 0.7 Hz, 2H), 6.88 (dt, J=1.9, 1.0 Hz, 2H), 6.83 (d, J=2.2 Hz, 2H), 5.94 (s, 1H), 3.36 (heptd, J=4.2, 0.7 Hz, 2H), 2.71 (q, J=8.3 Hz, 1H), 2.51 (p, J=7.6 Hz, 1H), 2.43-2.35 (m, 19H), 1.85-1.40 (m, 13H), 1.51 (s, 4H), 1.29 (d, J=4.1 Hz, 13H).

12. Compound 12: Synthesis of RDP-50

Step 1: Synthesis of auxiliary ligand RP-13

RP-13 was synthesized according to the same method as step 1 in the synthesis of Compound 1.

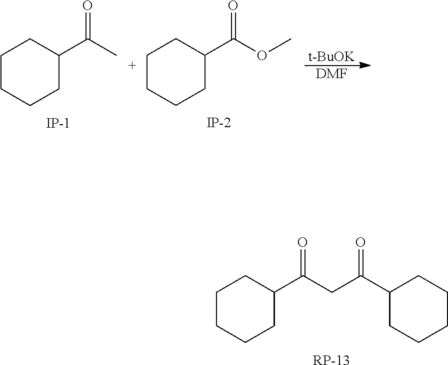

RD-2-1 was synthesized according to the same method as steps 2-6 (except that 1-bromo-4-fluoronaphthalene in step 2 was replaced with 2-bromo-4-(trifluoromethyl)naphthene) in the synthesis of Compound 4, resulting in a light yellow solid (5.91 g).

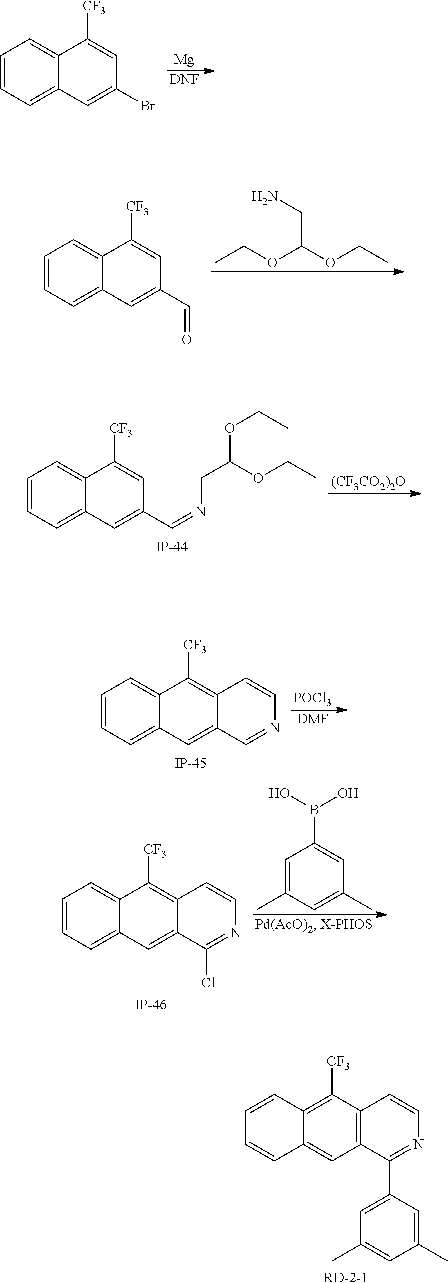

Iridium complex RDP-50 was synthesized according to the same method as step 6 in the synthesis of Compound 1, resulting in a red solid (2.07 g).

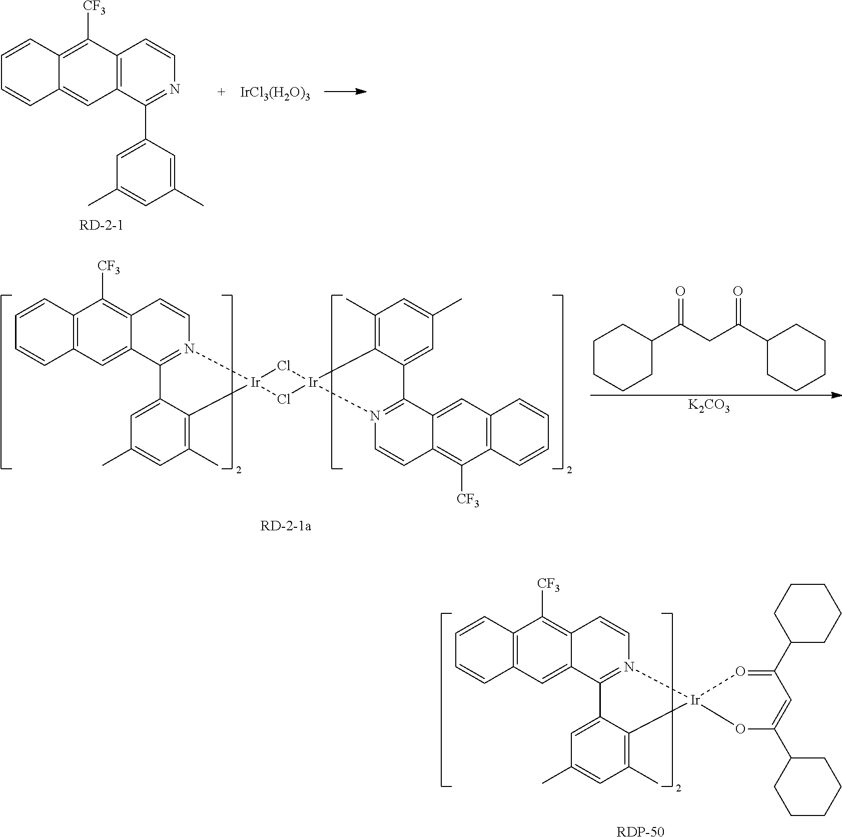

¹H NMR of Compound 12:

¹H NMR (400 MHz, Chloroform-d) δ8.74 (s, 5H), 8.70-8.62 (m, 2H), 7.91 (dt, J=7.7, 1.6 Hz, 2H), 7.75 (d, J=1.9 Hz, 2H), 7.47-7.31 (m, 5H), 6.94 (d, J=2.2 Hz, 2H), 6.90-6.84 (m, 2H), 5.94 (s, 1H), 2.72 (p, J=8.2 Hz, 1H), 2.51 (p, J=7.6 Hz, 1H), 2.42-2.35 (m, 14H), 1.85-1.36 (m, 14H).

13. Compound 13: Synthesis of RDP-51

Step 1: Synthesis of auxiliary ligand RP-13

RP-13 was synthesized according to the same method as step 1 in the synthesis of Compound 1.

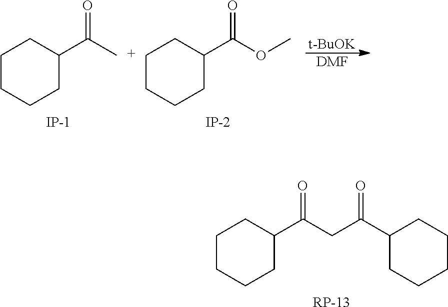

RD-2-2 was synthesized according to the same method as steps 2-6 (except that 1-bromo-4-fluoronaphthalene in step 2 was replaced with 1-bromo-4-methoxynaphthalene) in the synthesis of Compound 4, resulting in a light yellow solid (4.56 g).

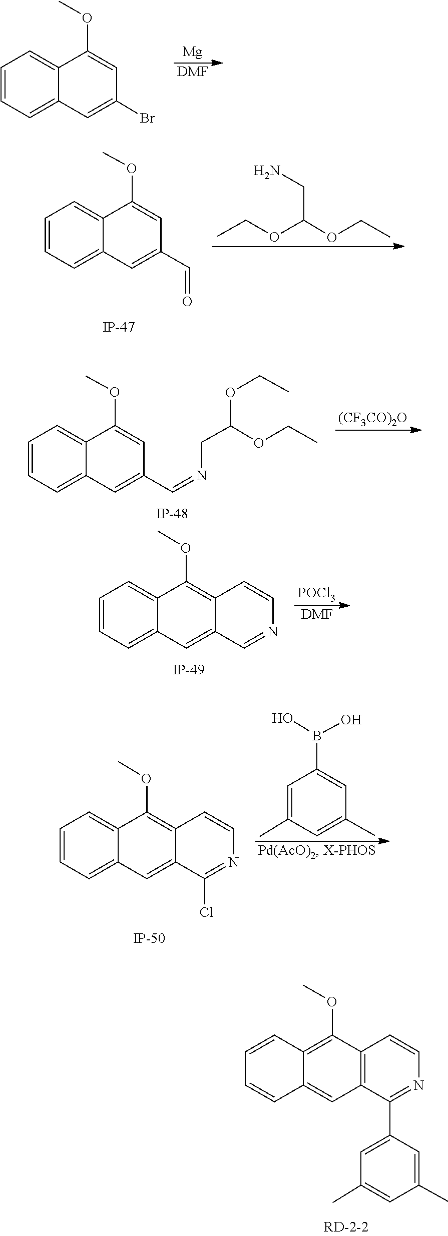

Iridium complex RDP-51 was synthesized according to the same method as step 6 in the synthesis of Compound 1, resulting in a red solid (2.54 g).

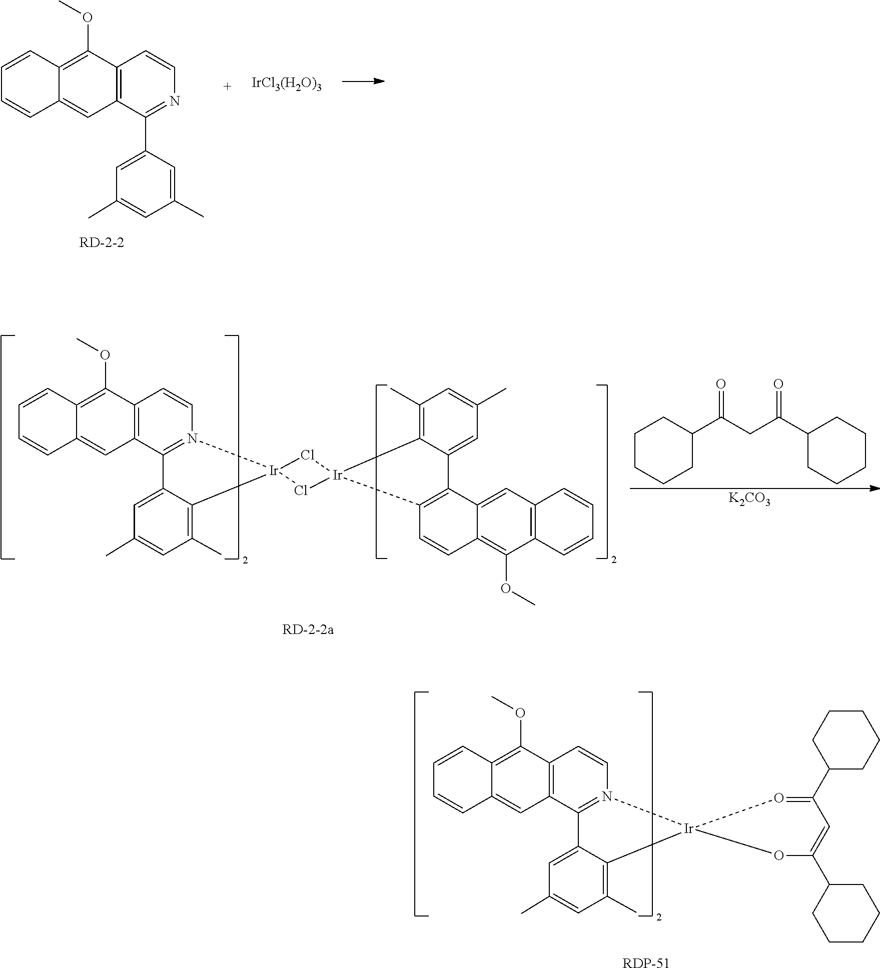

¹H NMR of Compound 13:

¹H NMR (400 MHz, Chloroform-d) δ8.61 (d, J=9.8 Hz, 2H), 8.40-8.32 (m, 2H), 7.96-7.85 (m, 2H), 7.69-7.59 (m, 2H), 7.59-7.53 (m, 2H), 7.48-7.37 (m, 5H), 6.91-6.84 (m, 2H), 6.76-6.70 (m, 2H), 5.94 (s, 1H), 4.13 (s, 6H), 2.71 (q, J=8.3 Hz, 1H), 2.50 (q, J=7.6 Hz, 1H), 2.42-2.35 (m, 14H), 1.85-1.74 (m, 1H), 1.79-1.60 (m, 5H), 1.64 - 1.55 (m, 1H), 1.54 (ddddd, J=10.6, 8.8, 5.0, 2.0, 1.0 Hz, 7H), 1.53-1.36 (m, 1H).

14. Compound 14: Synthesis of RDP-52

Step 1: Synthesis of intermediate IP-52

Intermediate IP-51 (20.00 g) was dissolved in THF (50 mL). The solution was degassed with nitrogen and then lithium methide (1.60 mol/L, 178.30 mL) was added dropwise. After completion of dropwise addition, the reaction was warmed to 30° C., continued to stir for 12 h, and then stopped. The reaction was extracted with water and n-hexane, and the solvent was evaporated to afford a light yellow oily liquid (15.20 g, yield: 82.26%).

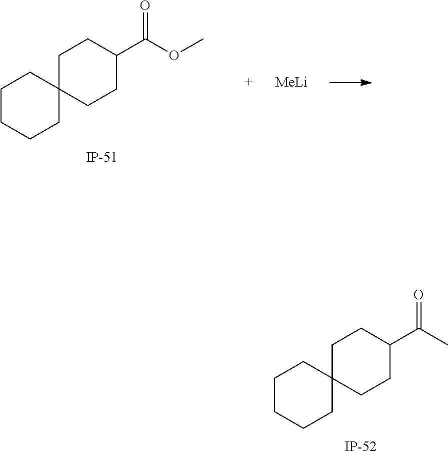

Step 2: Synthesis of auxiliary ligand RP-19

To a flask was added DMF (100 mL), and then potassium tert-butoxide (21.66 g) in a portion wise manner under stirring. The reaction mass was heated to 60° C., and then IP-52 (15.00 g) was added dropwise under N₂ protection. After completion of dropwise addition, stirring was continued for 20 min, followed by the addition of IP-51 (24.35 g, dropwise). After completion of the dropwise addition of IP-51, stirring was continued for 30 minutes at 60° C. and the heating was stopped. The reaction was extracted and washed several times with water and n-hexane, the organic phase was collected and distilled to remove solvent. The organic phase was separated by column chromatography to afford a white solid (25.43 g, yield: 88.42%).

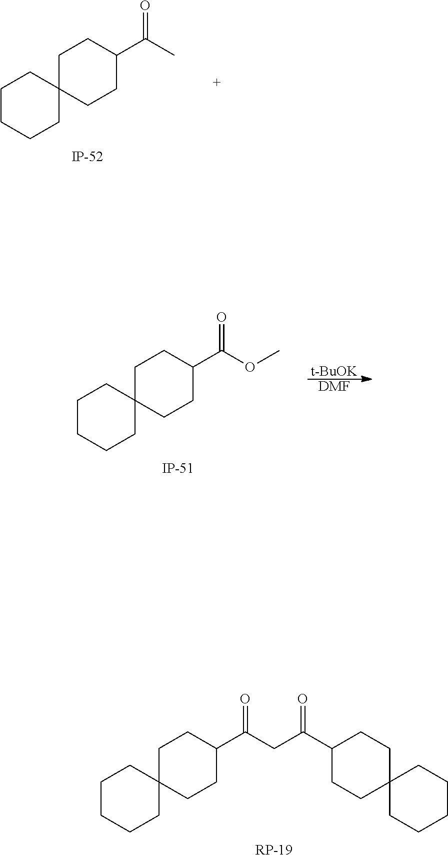

RD-1-1 was synthesized according to the same method as steps 2-5 in the synthesis of Compound 1, resulting in a white solid (10.92 g).

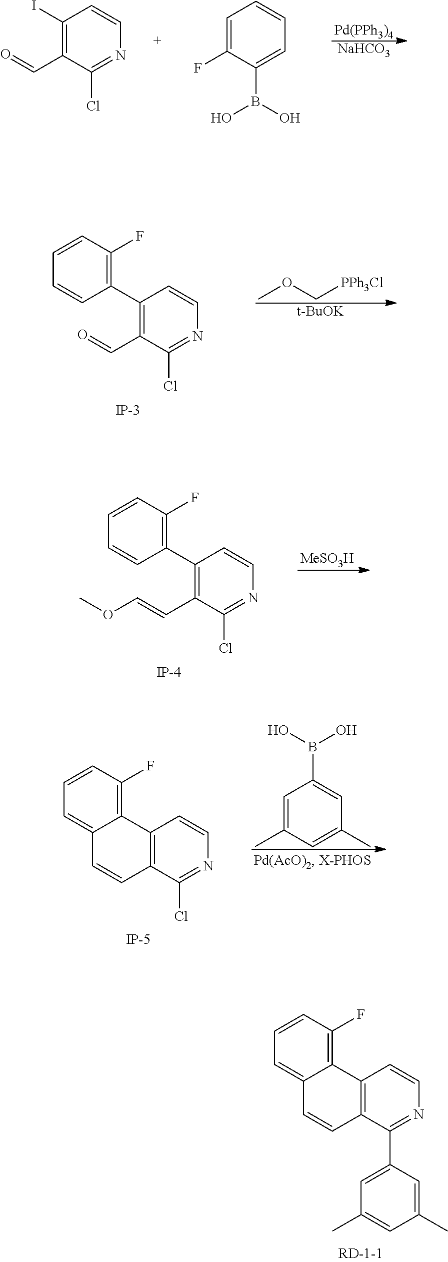

Iridium complex RDP-52 was synthesized according to the same method as step 6 in the synthesis of Compound 1, resulting in a red solid (3.02 g).

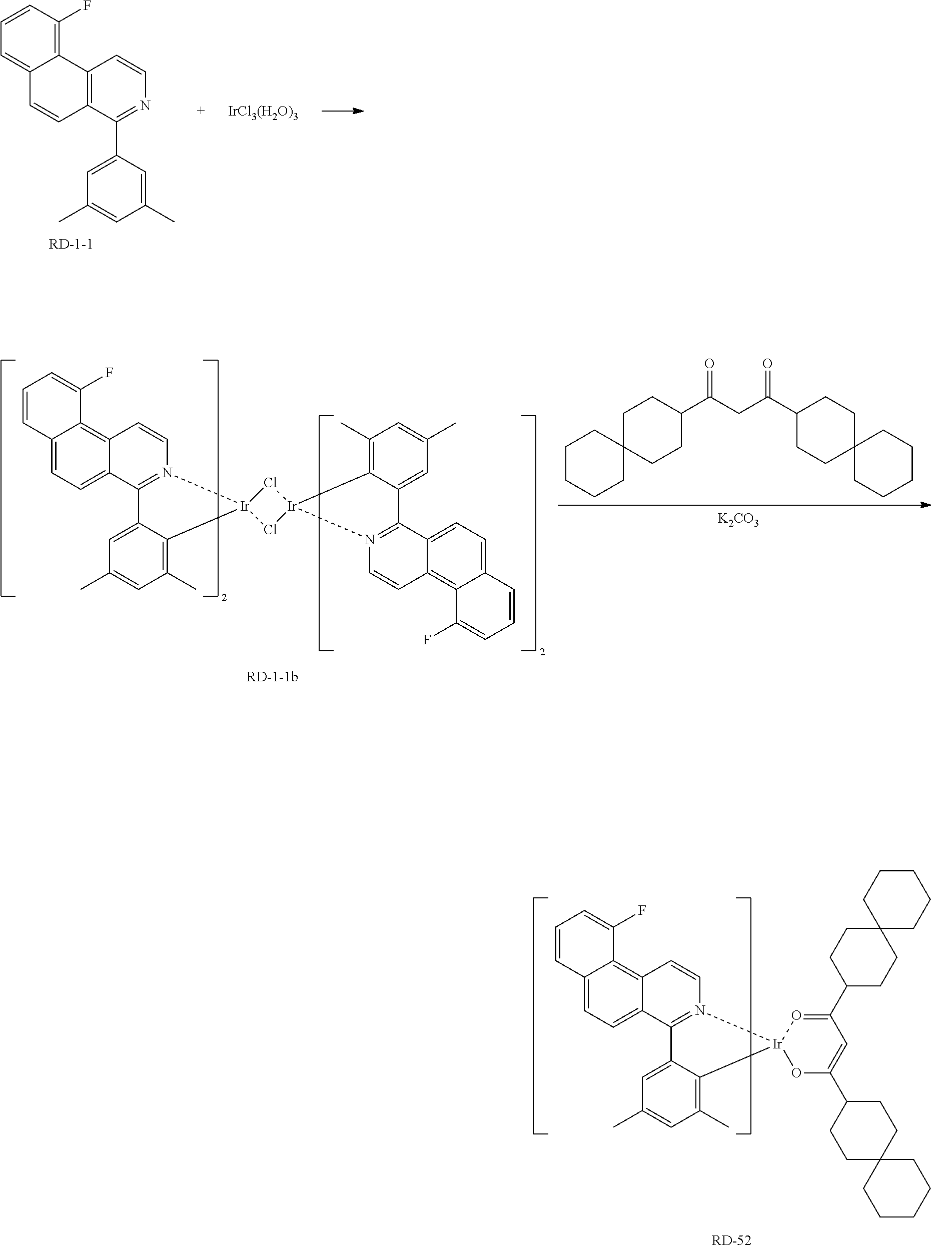

¹H NMR of Compound 14:

¹H NMR (400 MHz, Chloroform-d) δ8.81 (d, J=10.0 Hz, 2H), 8.62-8.54 (m, 2H), 7.90 (d, J=8.9 Hz, 2H), 7.80-7.72 (m, 2H), 7.54-7.43 (m, 4H), 7.26 (dd, J=7.8, 1.1 Hz, 2H), 6.91-6.81 (m, 4H), 5.93 (s, 1H), 2.80-2.66 (m, 1H), 2.56-2.44 (m, 1H), 2.42-2.35 (m, 12H), 1.86-1.37 (m, 37H).

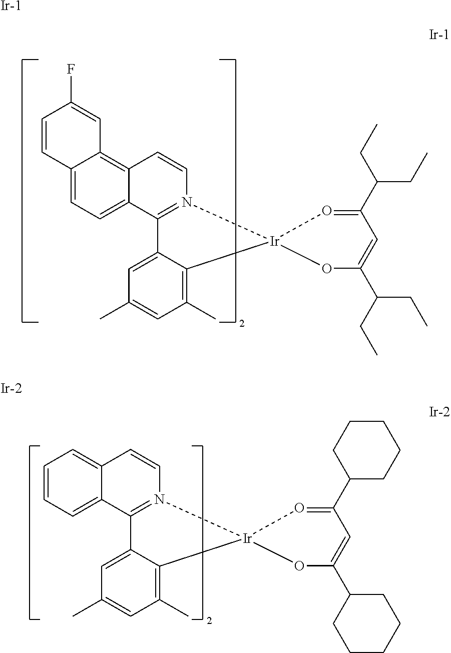

Example: OLED devices were prepared using compound 1 to compound 14, corresponding to Example 1 to Example 14. The preparation steps of the devices are as follows:

(1) Translucent conductive ITO glass substrate 110 (with anode 120 on top) (China Southern Glass Group Co., Ltd.) is ultrasonically treated in a commercial cleaning agent, rinsed in deionized water, and then washed with ethanol, acetone, and deionized water in sequence. It is baked in a clean environment until the moisture is completely removed, cleaned with ultraviolet light and ozone, and then treated with oxygen plasma for 30 seconds;

(2) Place the glass substrate with an anode in a vacuum chamber, vacuum it, and evaporate HIL (10 nm) as a hole injection layer 130 on the ITO glass substrate, with a evaporation rate of 0.1 nm/s;

(3) Compound HT is evaporated onto the hole injection layer to form a 100 nm thick hole transport layer 140, with a evaporation rate of 0.1 nm/s. EB is evaporated to form a 50 nm thick electron barrier layer 150. The evaporation rate is 0.1 nm/s;

(4) A luminescent layer 160 with a thickness of 35 nm is evaporated on the electron barrier layer, where RH is the main luminescent material, and iridium complex of 5% by weight is used as the phosphorescent doped guest material, with a evaporation rate of 0.1 nm/s;

(5) 35 nm thick compound ET: LiQ (weight ratio: 50:50) is evaporated on the luminescent layer as the electron transport layer 170. The evaporation rate is 0.1 nm/s, and 1 nm LiQ is evaporated as the electron injection layer 180 and 100 nm Al is evaporated as the device cathode 190.

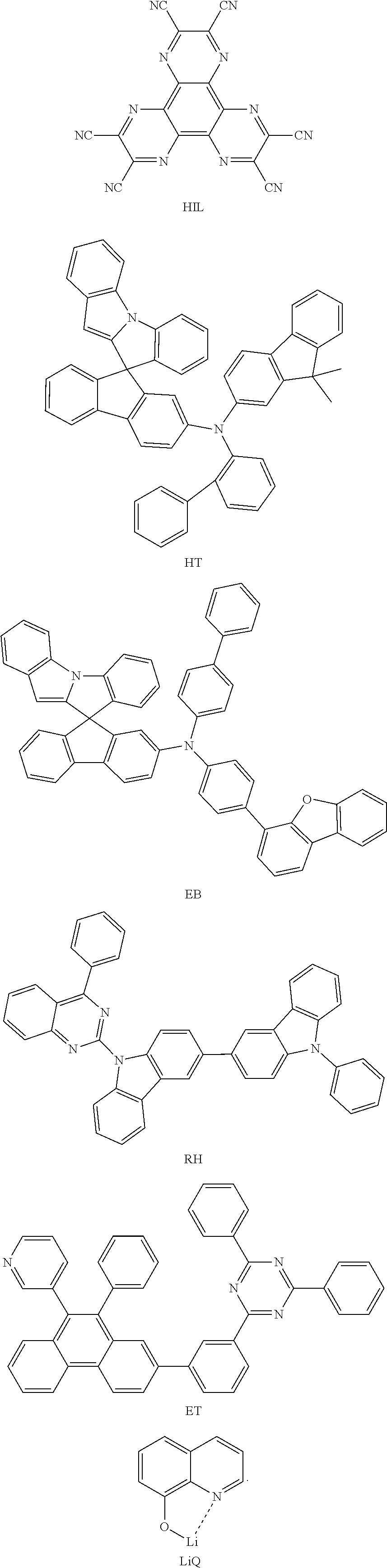

Comparative Example 1: the difference as compared to Example 1 is only that compound 1 is replaced with Ir-1 when preparing the device.

Comparative Example 2: the difference as compared to Example 1 is only that compound 1 is replaced with Ir-2 when preparing the device.

The working voltage, current efficiency, CIE coordinates at a current density of 10 mA/cm², and the attenuation ratio of brightness after working 150 hours at a current density of 50 mA/cm² to initial brightness (LT (150) value) of the prepared device are measured using the Photo Research PR650 spectrometer to characterize the stability of the device.

TABLE 1

| | | | Cur- | | Emis- | |
|---|---|---|---|---|---|---|
| | | | rent | | sion | |
| | | Volt- | effi- | | wave- | |
| | Com- | age | ciency | CIE | length | LT |
| | pound | (V) | (cd/A) | (x, y) | (nm) | (150) |
| Example 1 | RDP-1 | 3.41 | 21.62 | 0.670, | 624 | 95.79 |
| | | | | 0.329 | | |
| Example 2 | RDP-7 | 3.34 | 24.21 | 0.665, | 623 | 97.23 |
| | | | | 0.331 | | |
| Example 3 | RDP-19 | 3.45 | 23.16 | 0.662, | 621 | 93.34 |
| | | | | 0.324 | | |
| Example 4 | RDP-28 | 3.39 | 22.25 | 0.673, | 624 | 96.32 |
| | | | | 0.331 | | |
| Example 5 | RDP-42 | 3.40 | 21.88 | 0.677, | 626 | 92.38 |
| | | | | 0.311 | | |
| Example 6 | RDP-21 | 3.39 | 23.27 | 0.664, | 622 | 95.15 |
| | | | | 0.331 | | |
| Example 7 | RDP-46 | 3.45 | 20.58 | 0.675, | 626 | 93.35 |
| | | | | 0.326 | | |
| Example 8 | RDP-32 | 3.38 | 23.28 | 0.668, | 622 | 96.63 |
| | | | | 0.334 | | |
| Example 9 | RDP-47 | 3.44 | 21.03 | 0.673, | 625 | 90.1 |
| | | | | 0.326 | | |
| Example 10 | RDP-48 | 3.48 | 22.21 | 0.681, | 627 | 91.67 |
| | | | | 0.323 | | |
| Example 11 | RDP-49 | 3.37 | 24.04 | 0.676, | 625 | 94.76 |
| | | | | 0.327 | | |
| Example 12 | RDP-50 | 3.38 | 22.97 | 0.695, | 633 | 96.12 |
| | | | | 0.318 | | |
| Example 13 | RDP-51 | 3.45 | 20.19 | 0.704, | 636 | 88.45 |
| | | | | 0.312 | | |
| Example 14 | RDP-52 | 3.48 | 21.34 | 0.672, | 625 | 91.28 |
| | | | | 0.332 | | |
| Comparative | Ir-1 | 3.55 | 17.67 | 0.675, | 623 | 75.65 |
| Example 1 | | | | 0.324 | | |
| Comparative | Ir-2 | 3.64 | 15.73 | 0.682, | 620 | 81.90 |
| Example 2 | | | | 0.318 | | |

By comparing the working voltage, current efficiency, CIE coordinates, luminescence wavelength, and LT (150) value data of Examples 1-14 and Comparative Examples 1-2, it can be seen that isoquinoline is further fused with the aromatic ring and combines with auxiliary ligands containing cycloalkanes. At a current density of 10 mA/cm², the working voltage can be reduced to below 3.5 V, and the luminescence efficiency can be increased to over 20 cd/A, with a certain red shift in the luminescence wavelength, and the LT (150) value can reach above 88, improving the stability of the device and extending its service life.

1. An iridium complex having a structure represented by general formula I: 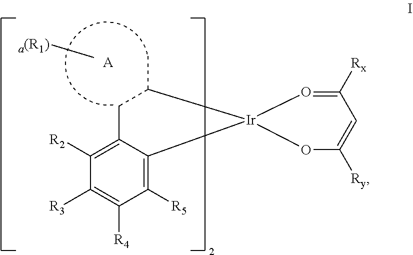
wherein,
ring A is selected from C₁₂-C₃₀ polycyclic groups formed by fusing three or more monocyclic groups with each other, and the precondition is that the C₁₂-C₃₀ polycyclic groups represented by the ring A at least comprise the structure of general formula II: 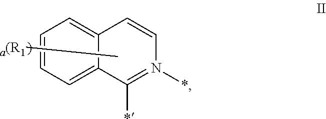
wherein, * represents a binding site of general formula II to iridium (Ir), *′ represents a binding site of general formula II to benzene ring in general formula I;
a is selected from an integer of 0 to 20, when a represents an integer that is ≥2, R₁ may be the same or different and the positions of R₁ may be the same or different;
R₁, R₂, R₃, R₄ and R₅ are the same or different, and each independently is H, deuterium, halogen, —CF₃, CN, amino, substituted or unsubstituted C₁-C₁₀ alkoxyl, or substituted or unsubstituted C₁-C₃₀ alkyl, hydrogens on the alkyl chain of the C₁-C₁₀ alkoxyl and C₁-C₃₀ alkyl may each be independently substituted by deuterium, halogen, —CF₃ or CN, wherein the halogen is selected from fluorine, chlorine, bromine or iodine; and
Rₓ and R_{y} are the same or different, and each independently includes saturated aliphatic ring structure.

2. The iridium complex according to claim 1, wherein the ring A is a group formed by fusing the general formula II with 1 to 3 five-membered rings or six-membered rings.

3. The iridium complex according to claim 2, wherein the structure of the ring A is selected from any one of general formulae RD-1 to RD-3: 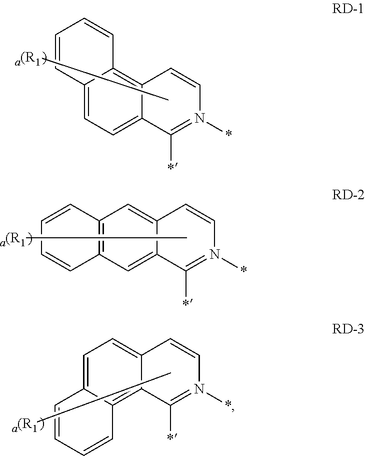
wherein, a represents any integer of 0 to 8.

4. The iridium complex according to claim 3, wherein the general formula RD-1 includes 8 substitutable sites, and the substituents on the 8 substitutable sites are represented by T₁₁, T₁₂, T₁₃, T₁₄, T₁₅, T₁₆, T₁₇ and T₁₈, respectively: 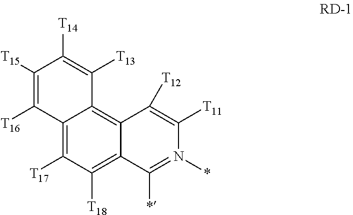
wherein, at least one of T₁₁-T₁₈ is not hydrogen and at most three of T₁₁-T₁₈ are not hydrogen,
any non-hydrogen substituent of T₁₁-T₁₈ is selected from deuterium, halogen, —CF₃, CN, amino, substituted or unsubstituted C₁-C₁₀ alkoxyl, or substituted or unsubstituted C₁-C₄ alkyl, hydrogens on the alkyl chain of the C₁-C₁₀ alkoxyl and C₁-C₄ alkyl may each be independently substituted by deuterium, halogen, —CF₃ or CN;
the general formula RD-2 includes 8 substitutable sites, and the substituents on the 8 substitutable sites are represented by T₂₁, T₂₂, T₂₃, T₂₄, T₂₅, T₂₆, T₂₇ and T₂₈, respectively, 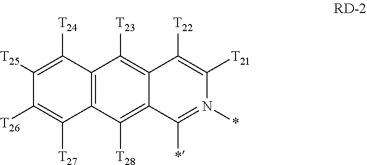
wherein, at least one of T₂₁-T₂₈ is not hydrogen and at most three of T₂₁-T₂₈ are not hydrogen,
any non-hydrogen substituent of T₂₁-T₂₈ is selected from deuterium, halogen, —CF₃, CN, amino, substituted or unsubstituted C₁-C₁₀ alkoxyl, or substituted or unsubstituted C₁-C₄ alkyl, hydrogens on the alkyl chain of the C₁-C₁₀ alkoxyl and C₁-C₄ alkyl may each be independently substituted by deuterium, halogen, —CF₃ or CN; and
the general formula RD-3 includes 8 substitutable sites, and the substituents on the 8 substitutable sites are represented by T₃₁, T₃₂, T₃₃, T₃₄, T₃₅, T₃₆, T₃₇ and T₃₈, respectively, 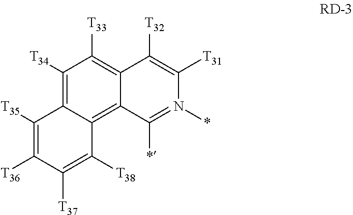
wherein, at least one of T₃₁-T₃₈ is not hydrogen and at most three of T₃₁-T₃₈ are not hydrogen,
any non-hydrogen substituent of T₃₁-T₃₈ is selected from deuterium, halogen, —CF₃, CN, amino, substituted or unsubstituted C₁-C₁₀ alkoxyl, or substituted or unsubstituted C₁-C₄ alkyl, hydrogens on the alkyl chain of the C₁-C₁₀ alkoxyl and C₁-C₄ alkyl may each be independently substituted by deuterium, halogen, —CF₃ or CN.

5. The iridium complex according to claim 2, the structure of the ring A is selected from any one of the following structures:

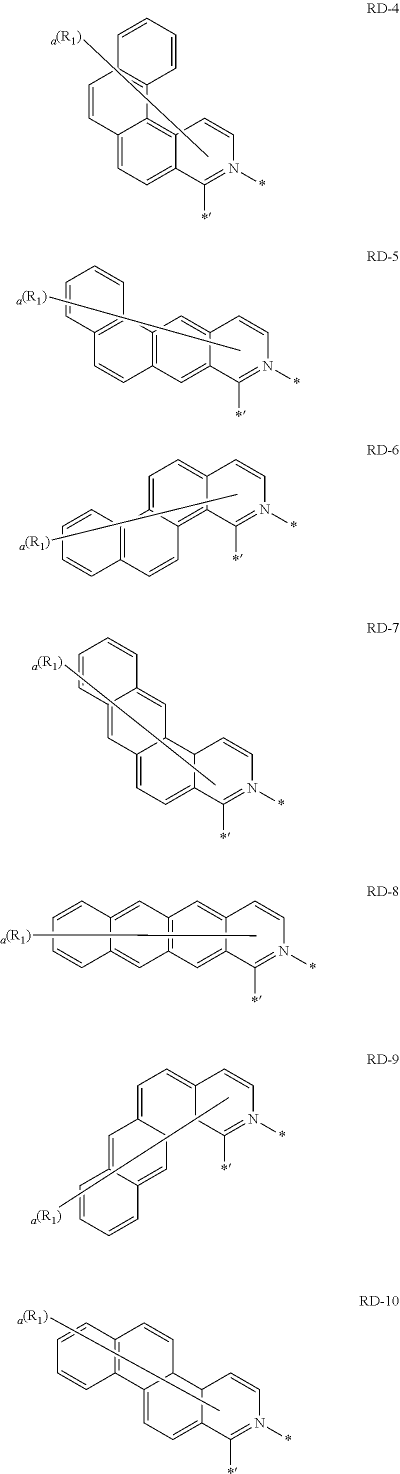

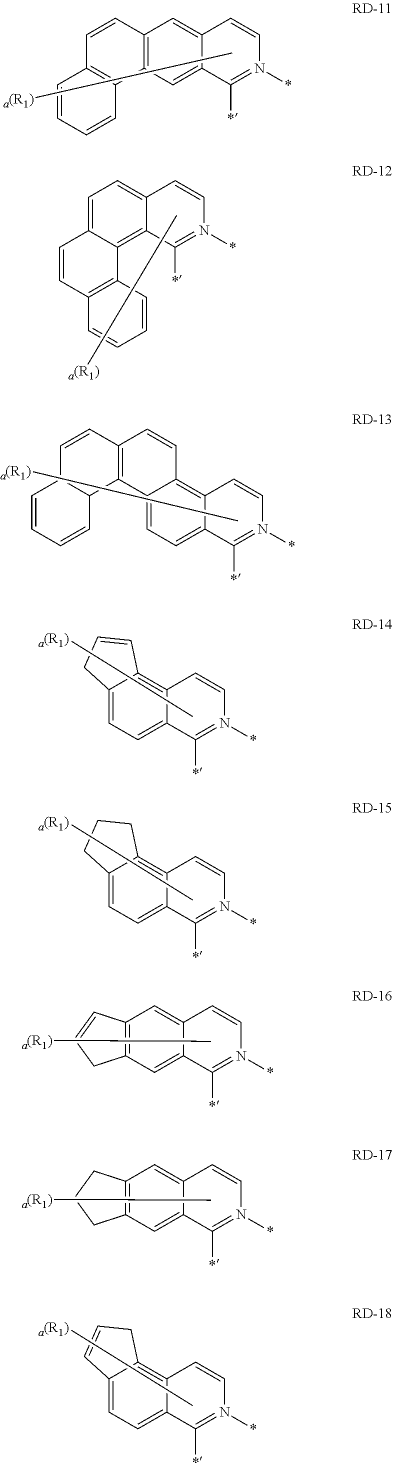

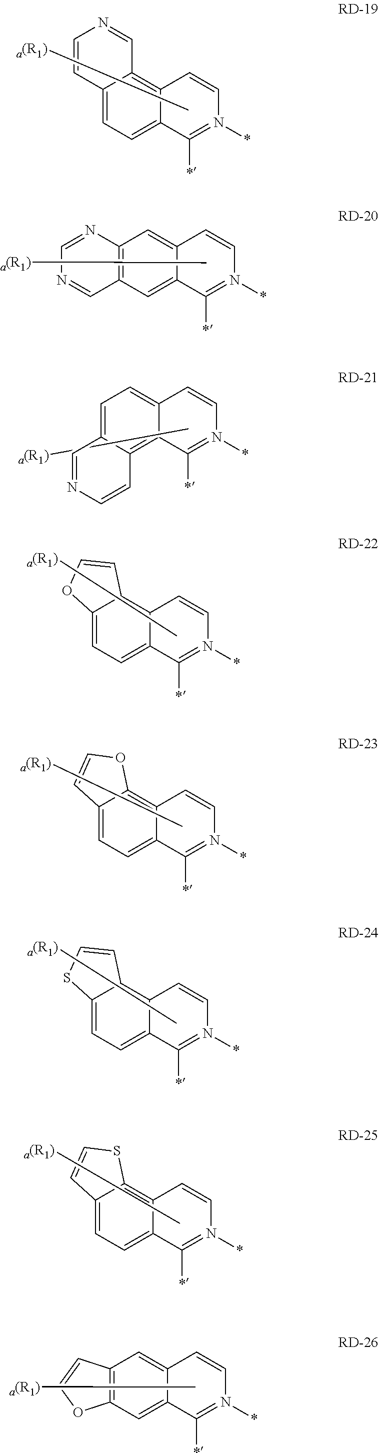

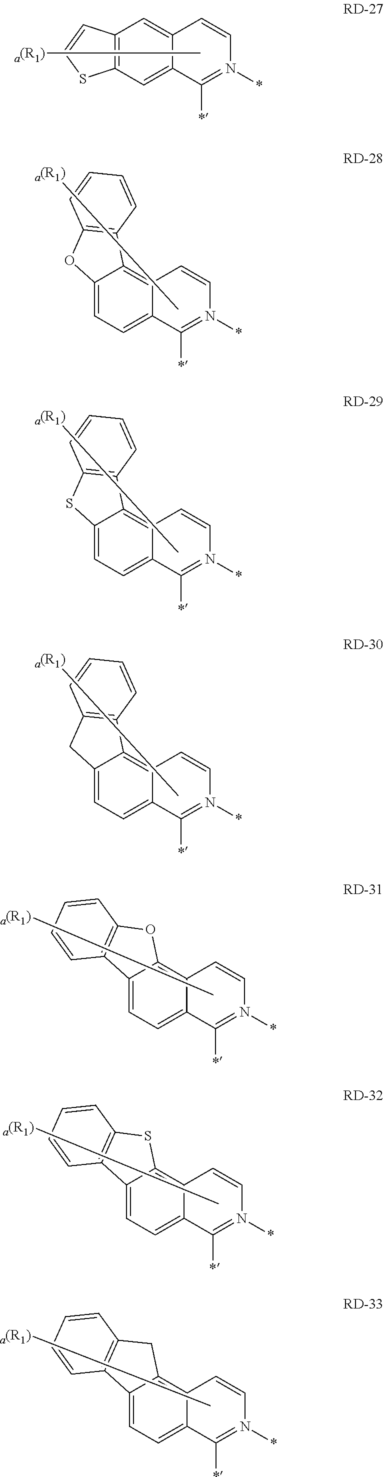

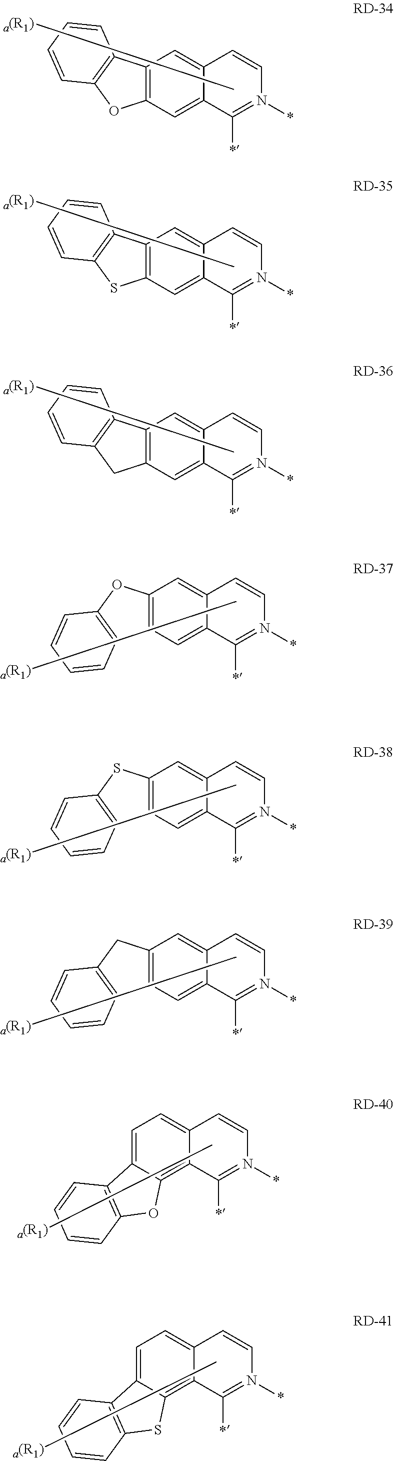

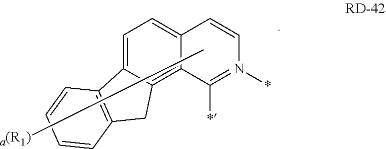

6. The iridium complex according to claim 1, wherein R₂, R₃, R₄ and R₅ are the same or different, and each is independently selected from H or C₁-C₁₀alkyl; the C₁-C₁₀ alkyl is selected from methyl, ethyl, propyl, isopropyl, n-butyl, sec-butyl, isobutyl, tert-butyl, n-pentyl, n-hexyl, n-heptyl, n-octyl, n-nonyl, or n-decyl.

7. The iridium complex according to claim 1, wherein Rₓ and R_{y} are the same or different, and each independently includes saturated C₃-C₈ monocyclic, C₇-C₁₅ spiro or bridged cyclic structure.

8. The iridium complex according to claim 7, wherein Rₓ and R_{y} are the same or different, and each independently includes the combination of saturated C₃-C₈ monocyclic ring with saturated C₇-C₁₅ spiro or bridged cyclic ring, and the saturated C₃-C₈ monocyclic ring is connected to the saturated C₇-C₁₅ spiro or bridged cyclic ring via a single bond.

9. The iridium complex according to claim 1, wherein one or more hydrogens on the saturated aliphatic ring structure included in Rₓ and R_{y} may each be independently substituted by substituents, and the substituents may be the same or different and each is independently selected from deuterium, halogen, —CF₃, —CN and C₁-C₄ alkyl.

10. The iridium complex according to claim 1, wherein auxiliary ligand is selected from any one of the following structures:

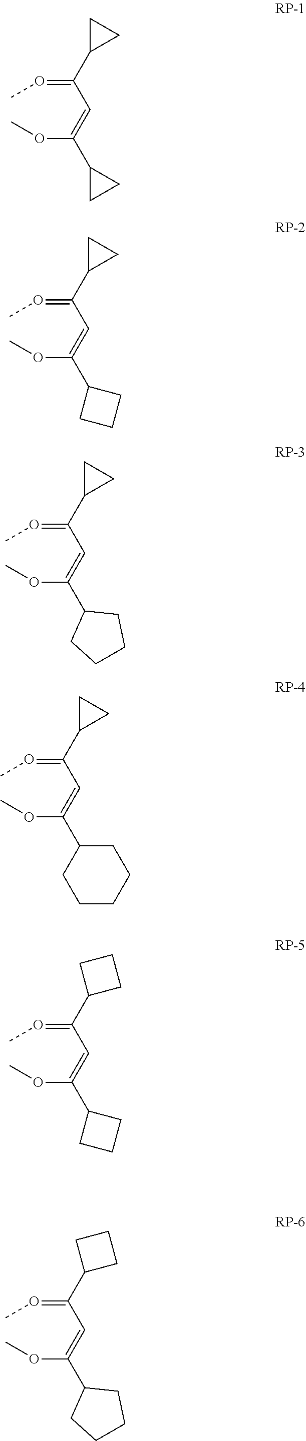

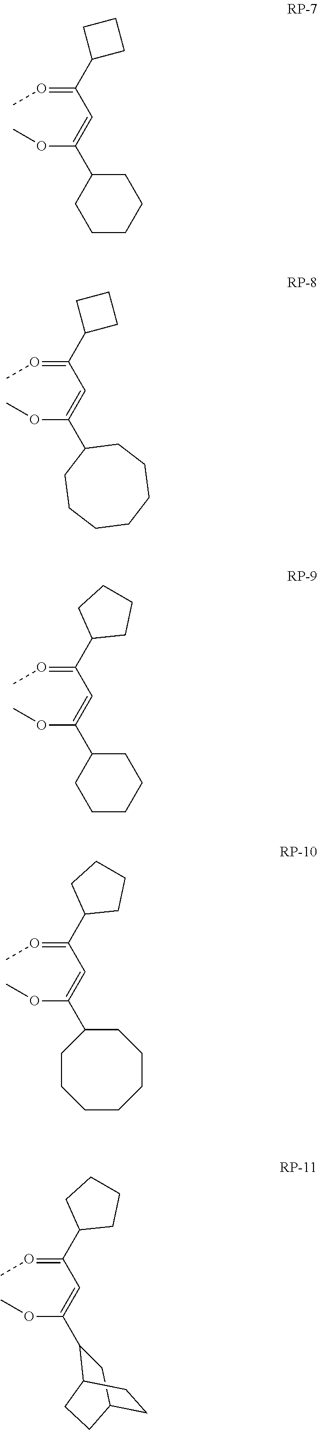

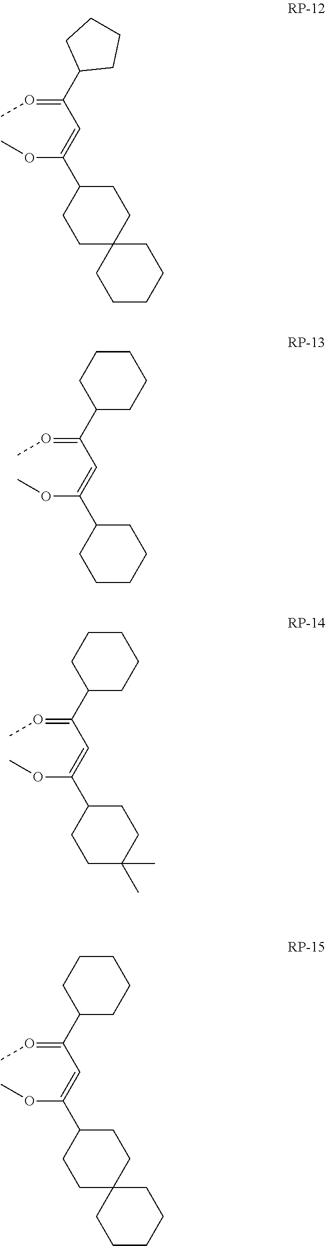

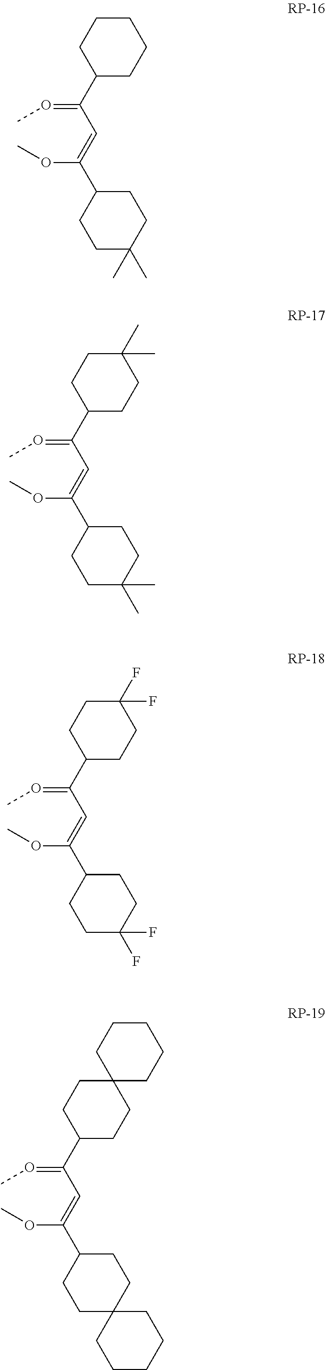

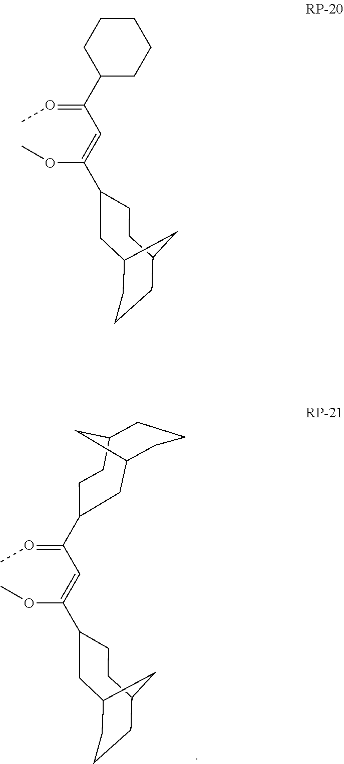

11. A method of preparing the iridium complex of claim 1, the method comprises the following steps:
1) reacting precursor substance with Iridium III to prepare a dimeric substance;
2) reacting the dimeric substance with auxiliary ligand molecule and potassium carbonate or sodium carbonate in a solvent under stirring to obtain the compound of general formula I;
wherein the precursor substance is represented by the following structural formula: 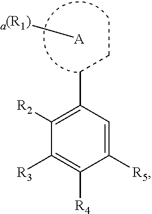
wherein the dimeric substance is represented by the following structural formula: 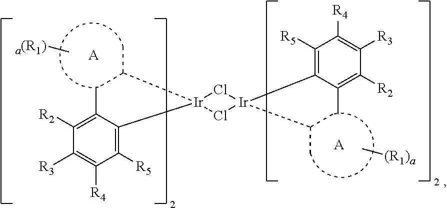
and
wherein the auxiliary ligand compound is represented by the following structural formula:

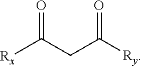

12. An organic light-emitting device comprising an iridium complex of claim 1, the organic light-emitting device comprises an anode, a cathode and an organic layer; the organic layer at least includes a luminescent layer, the luminescent layer includes the iridium complex, and the iridium complex is doped in the material of the luminescent layer as light-emitting material.
